(19) United States
(12) Patent Application Publication
(10) Pub. No.: US 2019/0237514 A1
(43) Pub. Date: Aug. 1, 2019

(54) DISPLAY DEVICE MANUFACTURING METHOD, AND DISPLAY DEVICE

(71) Applicant: Sharp Kabushiki Kaisha, Sakai City, Osaka (JP)

(72) Inventors: Yuto TSUKAMOTO, Sakai City (JP); Seiichi MITSUI, Sakai City (JP); Shinichi KAWATO, Sakai City (JP); Satoshi INOUE, Sakai City (JP); Yuhki KOBAYASHI, Sakai City (JP); Takashi OCHI, Sakai City (JP)

(21) Appl. No.: 16/319,841

(22) PCT Filed: Jul. 21, 2017
(86) PCT No.: PCT/JP2017/026403

§ 371 Date: Jan. 23, 2019

(30) Foreign Application Priority Data
Jul. 28, 2016 (JP) 2016-148902

(51) Int. Cl. H01L 27/32; H01L 51/56; H01L 51/50; H01L 51/52; H01L 27/12

(52) U.S. Cl. CPC H01L 27/322; H01L 27/3211; H01L 27/1259; H01L 51/5012; H01L 51/5262; H01L 51/56

(57) ABSTRACT

In this manufacturing method, in a blue fluorescent light-emitting layer formation step, a blue fluorescent light-emitting layer is formed in both a subpixel and a subpixel; in a green fluorescent light-emitting layer formation step, a green fluorescent light-emitting layer is formed in both the subpixel and a subpixel; and in a red light-emitting layer formation step, a red light-emitting layer is formed in both the subpixel and a subpixel. In at least two of the abovementioned steps, linear vapor deposition is performed using a slitted mask having an opening that is provided so as to extend across a plurality of pixels.

### TECHNICAL FIELD

The disclosure relates to a display device manufacturing method and to a display device.

### BACKGROUND ART

In recent years, a self-luminous display device using a light emitting element (EL element) employing an electroluminescence (hereinafter referred to as “EL”) phenomenon has been developed as a display device instead of a liquid crystal display device.

A display device including an EL element can emit light at low voltages. The EL element is a self-luminous element, and therefore has a wide viewing angle and high viewability. Further, the EL element is a thin film-form completely solid element, and is thus garnering attention from the viewpoint of saving space, portability, and the like.

The EL element has a configuration in which a light-emitting layer containing a luminescent material is interposed between a cathode electrode and an anode electrode. The EL element emits light by using the release of light during the deactivation of excitons that are generated by injecting electrons and holes into the light-emitting layer and causing recombination.

The light-emitting layer of an EL element is mainly formed using vapor deposition techniques, such as vacuum vapor deposition. Techniques for forming of a full-color organic EL display device using such vapor deposition can be broadly divided into a white CF (color filter) technique and a separate-patterning technique.

The white CF technique is a technique in which a white light-emitting EL element and a CF layer are combined, and a luminescent color is selected at the subpixel level.

The separate-patterning technique is a technique where separately patterning vapor deposition is carried out for each luminescent color using vapor deposition masks. Generally, subpixels constituted by red (R), green (G), and blue (B) EL elements, arranged on a substrate, are selectively caused to emit light at desired brightnesses using TFTs, and an image is displayed as a result. Banks (partitions) defining light emitting regions in the subpixels are provided between EL elements, and the light-emitting layers of the EL elements are formed in openings of the banks using a vapor deposition mask.

### CITATION LIST

### Patent Literature

PTL 1: JP 2015-216113 A (published Dec. 3, 2015)

### SUMMARY

### Technical Problem

The white CF technique has an advantage in that a high-resolution display device can be achieved without requiring a high-resolution vapor deposition mask.

However, with the white CF technique, using a color filter results in energy loss, which is problematic in that a drive voltage is used and more power is consumed. Additionally, this kind of white light-emitting EL element has many layers and requires a color filter, which is a disadvantage in that manufacturing costs are extremely high.

On the other hand, while the separate-patterning technique does provide good light emission efficiency, low voltage driving, and the like, such high-precision patterning is difficult. For example, there is a problem in that colors may bleed to neighboring pixels depending on the precision of the openings in the vapor deposition mask and the distance relationship between the vapor deposition source and the film formed substrate. Furthermore, shadow, where the vapor deposition film ends up thinner than the intended film thickness, can arise depending on the thickness of the vapor deposition mask, the deposition angle, and the like. Thus, with a display device using the separate-patterning technique, there is a problem in that the display quality drops due to color bleeding, shadow, and the like caused by deposited materials infiltrating from the direction of neighboring pixels. Particularly, when another color of dopant is deposited on a neighboring pixel, even if only an extremely small amount of the other color of dopant is deposited, that dopant will, depending on the device structure, have a major influence on the EL light-emission spectrum. This can cause the colors to change.

Thus, to achieve a high-resolution display device using the separate-patterning technique, it is necessary to distance the vapor deposition source from the film formed substrate to achieve an acute deposition angle, which means it is necessary to raise the height of the vacuum chamber to accommodate this distancing.

However, manufacturing a vacuum chamber having a raised height is very expensive, and also has a poor material utilization efficiency, which leads to an increase in material costs as well.

Recent years have seen the practical use of pixel arrangements aside from the RGB stripe arrangement, such as the S-Stripe arrangement and the PenTile arrangement, for the purpose of improving the perceived resolution.

However, regardless of the pixel arrangement, it has been necessary in the past to secure a bank width of at least approximately several tens of μm between subpixels, and the resolution of known display devices using the separate-patterning technique effectively peaks at 500 pixels per inch.

With the aim of providing a light-emitting apparatus having productivity and reduced power consumption, PTL 1 discloses a light-emitting apparatus including at least an R subpixel, which includes a light-emitting element that emits red light and an optical element that transmits the red light, a G subpixel, which includes a light-emitting element that emits green light and an optical element that transmits the green light, and a B subpixel, which includes a light-emitting element that emits blue light and an optical element that transmits the blue light. In each light emitting element, a first light-emitting layer containing a first luminescent material having a spectral peak in a wavelength range from 540 nm to 580 nm, or a second light-emitting layer containing a second luminescent material having a light-emission peak in a wavelength range from 420 nm to 480 nm, is used in common.

The light-emitting apparatus may further include a Y subpixel which includes a light-emitting element that emits yellow (Y) light and an optical element that transmits the yellow light. The first light-emitting layer is a light-emitting layer constituted by a luminescent material that emits yellow-green, yellow, or orange light, and the second light-emitting layer is a light-emitting layer constituted by a luminescent material that emits purple, blue, or blue-green light.

In PTL 1, the light-emitting elements are used along with optical elements such as color filters, band-pass filters, multilayer film filters, and the like. The resulting optical interference effect and cutting of mixed color light by the optical elements improves the color purity.

However, in PTL 1, a common layer having a luminance peak at an intermediate color in the spectrum between two subpixels is provided as a common layer for the two subpixels. For example, a light-emitting layer having a luminescent color of yellow or orange is provided as the common layer for the G subpixel and the R subpixel. Accordingly, attempting to enhance a desired color using the optical interference effect can nevertheless result in color shifts and lead to a drop in efficiency, and it is difficult to improve the color reproduction of single colors.

In PTL 1, improving the color using an optical element provided on a counter substrate (a sealing substrate) can be considered. However, there is a tradeoff between color and light emitting efficiency. Therefore, like the white CF technique, there is a problem in that both high color purity and low power consumption cannot be achieved at the same time.

Furthermore, there is a gap between the light emitting element and the optical element, which can produce color mixing in light emitted in oblique directions. The light-emitting apparatus of PTL 1 therefore has a problem in terms of light distribution properties as well.

Having been conceived in light of the above-described problems in the related art, an object of the disclosure is to provide a display device manufacturing method, and a display device, that can reduce a deposition margin for preventing color mixing by making color mixing less likely than in display devices using the known separate-patterning technique, thereby achieving higher resolutions more easily, and that can achieve both high color levels and low power consumption.

### Solution to Problem

To solve the above-described problem, a manufacturing method for a display device according to one aspect of the disclosure is a manufacturing method for a display device, the display device including: a substrate having a display region in which a plurality of pixels are arranged, each pixel including a first subpixel, a second subpixel, a third subpixel, and a fourth subpixel, wherein the first subpixel and the second subpixel are arranged in an alternating manner in a first direction; the third subpixel and the fourth subpixel are arranged in an alternating manner in the first direction; a column constituted by the first subpixel and the second subpixel, and a column constituted by the third subpixel and the fourth subpixel, are arranged in an alternating manner in a second direction orthogonal to the first direction; in the first subpixel, a first fluorescent luminescent material emits light, and the light emitted from the first fluorescent luminescent material is emitted to the exterior; in the second subpixel and the third subpixel, a second fluorescent luminescent material emits light, and the light emitted from the second fluorescent luminescent material is emitted to the exterior; in the fourth subpixel, a third luminescent material emits light, and the light emitted from the third luminescent material is emitted to the exterior; the first fluorescent luminescent material emits light having a first peak wavelength; the second fluorescent luminescent material emits light having a second peak wavelength longer than the first peak wavelength; the third luminescent material emits light having a third peak wavelength longer than the second peak wavelength; and an energy level of the second fluorescent luminescent material in a minimum excited singlet state is lower than an energy level of the first fluorescent luminescent material in a minimum excited singlet state and higher than an energy level of the third luminescent material in a minimum excited singlet state, the method including: a function layer formation step of forming a plurality of function layers constituted by vapor deposition particles on the substrate by vapor-depositing vapor deposition particles corresponding to the respective function layers on the substrate through vapor deposition masks in which are formed a plurality of mask openings having predetermined opening patterns corresponding to the respective function layers, wherein the function layer formation step includes: a first light-emitting layer formation step of forming a first light-emitting layer containing the first fluorescent luminescent material in common for the first subpixel and the second subpixel; a second light-emitting layer formation step of forming a second light-emitting layer containing the second fluorescent luminescent material in common for the second subpixel and the third subpixel; a third light-emitting layer formation step of forming a third light-emitting layer containing the third luminescent material in common for the second subpixel and the fourth subpixel; and a separation layer formation step of forming a separation layer in the second subpixel so that in the second subpixel, the separation layer, which inhibits Förster-type energy transfer, is layered between the third light-emitting layer and the light-emitting layer, of the first light-emitting layer and the second light-emitting layer, that is located closer to the third light-emitting layer, and in the function layer formation step: the first light-emitting layer and the second light-emitting layer are formed so that in the second subpixel, a distance between opposing surfaces of the first light-emitting layer and the second light-emitting layer is less than or equal to the Förster radius; and in at least two light-emitting layer formation steps among the first light-emitting layer formation step, the second light-emitting layer formation step, and the third light-emitting layer formation step, the vapor deposition particles are linearly deposited on the substrate using, as the vapor deposition mask, a slitted mask including slit-shaped mask openings provided so that the mask openings span a plurality of the pixels.

To solve the above-described problem, a display device according to one aspect of the disclosure includes: a substrate having a display region in which a plurality of pixels are arranged, each pixel including a first subpixel, a second subpixel, a third subpixel, and a fourth subpixel, wherein the first subpixel and the second subpixel are arranged in an alternating manner in a first direction; the third subpixel and the fourth subpixel are arranged in an alternating manner in the first direction; a column constituted by the first subpixel and the second subpixel, and a column constituted by the third subpixel and the fourth subpixel, are arranged in an alternating manner in a second direction orthogonal to the first direction; a first light-emitting layer containing a first fluorescent luminescent material is provided in common for the first subpixel and the second subpixel; a second light-emitting layer containing a second fluorescent luminescent material is provided in common for the second subpixel and the third subpixel; a third light-emitting layer containing a third luminescent material is provided in common for the second subpixel and the fourth subpixel; at least two light-emitting layers among the first light-emitting layer, the second light-emitting layer, and the third light-emitting layer include a light-emitting layer provided spanning a plurality of pixels; an energy level of the second fluorescent luminescent material in a minimum excited singlet state is lower than an energy level of the first fluorescent luminescent material in a minimum excited singlet state and higher than an energy level of the third luminescent material in a minimum excited singlet state; in the second subpixel, a distance between opposing surfaces of the first light-emitting layer and the second light-emitting layer is less than or equal to a Förster radius, and a separation layer that inhibits Förster-type energy transfer is layered between the third light-emitting layer and the light-emitting layer, of the first light-emitting layer and the second light-emitting layer, that is located closer to the third light-emitting layer; in the first subpixel, the first fluorescent luminescent material emits light, and the light emitted from the first fluorescent luminescent material is emitted to the exterior; in the second subpixel and the third subpixel, the second fluorescent luminescent material emits light, and the light emitted from the second fluorescent luminescent material is emitted to the exterior; in the fourth subpixel, the third luminescent material emits light, and the light emitted from the third luminescent material is emitted to the exterior; the first fluorescent luminescent material emits light having a first peak wavelength; the second fluorescent luminescent material emits light having a second peak wavelength longer than the first peak wavelength; and the third luminescent material emits light having a third peak wavelength longer than the second peak wavelength.

### Advantageous Effects of Disclosure

According to the above-described aspects of the disclosure, light-emitting layers of a plurality of colors can be linearly-deposited, which has not been possible with known display devices having an S-Stripe arrangement or a PenTile arrangement.

Additionally, by using a slitted mask having slit-shaped mask openings provided spanning a plurality of pixels in the aforementioned linear deposition, non-opening patterns between adjacent subpixels within each pixel and non-opening patterns between adjacent pixels can be eliminated from the vapor deposition mask. Accordingly, in a known vapor deposition mask for forming light-emitting layers, non-opening patterns between adjacent subpixels vapor-deposited at the same time can be reduced; furthermore, shadow dependent on the thicknesses of the non-opening patterns between adjacent subpixels and the non-opening patterns between adjacent pixels can be eliminated, and variations in film thickness within subpixels can be reduced.

According to the above-described aspects of the disclosure, in the second subpixel, the first light-emitting layer, the second light-emitting layer, and the third light-emitting layer are layered. Although Förster-type energy transfer occurs from the first light-emitting layer to the second light-emitting layer, no Förster-type energy transfer occurs from the first light-emitting layer and the second light-emitting layer to the third light-emitting layer, and thus only the second fluorescent luminescent material emits light.

In other words, the second fluorescent luminescent material, which is the luminescent material of the second light-emitting layer, has a lower energy level in the minimum excited singlet state than the first fluorescent luminescent material, which is the luminescent material of the first light-emitting layer. Additionally, the distance between opposing surfaces of the first light-emitting layer and the second light-emitting layer is less than or equal to the Förster radius. Accordingly, even if, for example, holes and electrons have recombined in the first light-emitting layer, Förster-type energy transfer enables the second fluorescent luminescent material to emit light at substantially 100%. Additionally, the separation layer is provided between the third light-emitting layer, and the light-emitting layer, of the first light-emitting layer and the second light-emitting layer, that is located on the third light-emitting layer side. Accordingly, energy transfer from the first light-emitting layer and the second light-emitting layer to the third light-emitting layer is inhibited. Color mixing can therefore be suppressed even if the first light-emitting layer, the second light-emitting layer, and the third light-emitting layer are layered in the second subpixel.

Additionally, according to the above-described aspects of the disclosure, light-emitting layers of a plurality of colors can be linearly-deposited as described above, and because color mixing does not occur easily in the second subpixel despite a plurality of light-emitting layers being layered as described above, a deposition margin for preventing color mixing can be made lower than in display devices using a known separate-patterning technique. This makes it possible to realize a higher resolution more easily than in display devices using a known separate-patterning technique.

Additionally, the display device does not require a CF layer or an optical interference effect as with the white CF technique or PTL 1, despite having the above-described layered structure for the light-emitting layers. This makes it possible to avoid a situation where more power is consumed, the light distribution properties worsen, and the like. Therefore, a high color level and low power consumption can be achieved at the same time.

Thus according to the above-described aspects of the disclosure, it is possible to provide a display device that can reduce the deposition margin for preventing color mixing by making color mixing less likely than in display devices using a known separate-patterning technique, thereby achieving higher resolutions more easily, and that can achieve both high color levels and low power consumption.

Thus according to the above-described aspects of the disclosure, it is possible to provide a display device that can reduce the deposition margin for preventing color mixing by making color mixing less likely than in display devices using a known separate-patterning technique, thereby achieving higher resolutions more easily, and that can achieve both high color levels and low power consumption.

### BRIEF DESCRIPTION OF DRAWINGS

FIG. 1 is a diagram schematically illustrating the principle of light emission by a light-emitting layer unit of an organic EL display device according to a first embodiment of the disclosure.

FIG. 2 is a diagram schematically illustrating a layered structure in the light-emitting layer unit of the organic EL display device according to the first embodiment of the disclosure.

FIG. 3 is a diagram schematically illustrating a pixel arrangement in the organic EL display device according to the first embodiment of the disclosure.

FIG. 4 is a cross-sectional view illustrating an example of the overall configuration of the organic EL display device according to the first embodiment of the disclosure.

FIG. 5 is a diagram illustrating a relationship between energy levels of a blue fluorescent luminescent material, a green fluorescent luminescent material, and a red luminescent material, in minimum excited singlet states.

FIG. 6 is a graph illustrating an example of a photoluminescence emission spectrum of the blue fluorescent luminescent material, and an absorption spectrum of the green fluorescent luminescent material, used in the first embodiment of the disclosure.

FIG. 7 is a graph illustrating an example of an absorption spectrum of a material of a separation layer, a photoluminescence emission spectrum of the green fluorescent luminescent material, and a photoluminescence emission spectrum of the blue fluorescent luminescent material, used in Embodiment 1 of the disclosure.

FIG. 8 is a graph illustrating an example of the photoluminescence emission spectrum of the blue fluorescent luminescent material, the photoluminescence emission spectrum of the green fluorescent luminescent material, and a photoluminescence emission spectrum of the red luminescent material.

FIGS. 9A to 9C are plan views illustrating processes for producing the light-emitting layer unit in the organic EL display device according to the first embodiment of the disclosure, in the order of those processes.

FIG. 10 is a flowchart illustrating the flow of processes for producing main portions of the organic EL display device according to the first embodiment of the disclosure.

FIG. 11 is a plan view illustrating the layered state of each color of light-emitting layer and the separation layer in the organic EL display device according to Embodiment 1 of the disclosure.

FIG. 12 is a diagram schematically illustrating a pixel arrangement in an organic EL display device according to Embodiment 2 of the disclosure.

FIGS. 13A to 13C are plan views illustrating processes for producing the light-emitting layer unit in the organic EL display device according to Embodiment 2 of the disclosure, in the order of those processes.

FIG. 14 is a plan view illustrating the layered state of each color of light-emitting layer and the separation layer in the organic EL display device according to Embodiment 2 of the disclosure.

FIG. 15A is a perspective view illustrating the overall configuration of the main portions of a vapor deposition apparatus used to manufacture an organic EL display device according to Embodiment 3 of the disclosure, and FIG. 15B is a plan view illustrating a state in which a film formed substrate has been rotated by 45 degrees relative to a vapor deposition mask in the vapor deposition apparatus.

FIG. 16 is a diagram schematically illustrating a layered structure in the light-emitting layer unit of an organic EL display device according to Example 1 defining layering order of function layers in a light-emitting layer unit in Embodiment 4 of the disclosure.

FIG. 17 is a diagram schematically illustrating a layered structure in the light-emitting layer unit of an organic EL display device according to Example 2 defining layering order of function layers in a light-emitting layer unit in Embodiment 4 of the disclosure.

FIG. 18 is a diagram schematically illustrating a layered structure in the light-emitting layer unit of an organic EL display device according to Example 3 defining layering order of function layers in a light-emitting layer unit in Embodiment 4 of the disclosure.

### DESCRIPTION OF EMBODIMENTS

Hereinafter, embodiments of the disclosure will be described in detail.

### First Embodiment

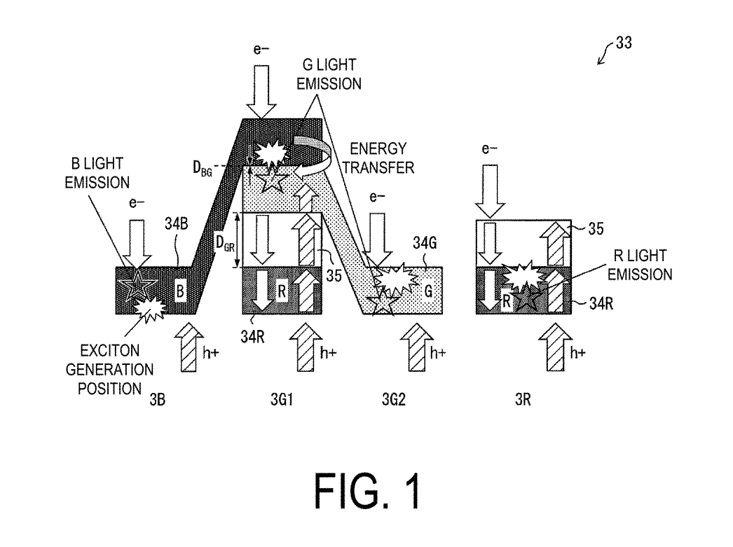

A description follows regarding one aspect of the disclosure, on the basis of FIGS. 1 to 11.

The following describes an organic EL display device as an example of a display device according to the present embodiment.

### Overall Configuration of Organic EL Display Device

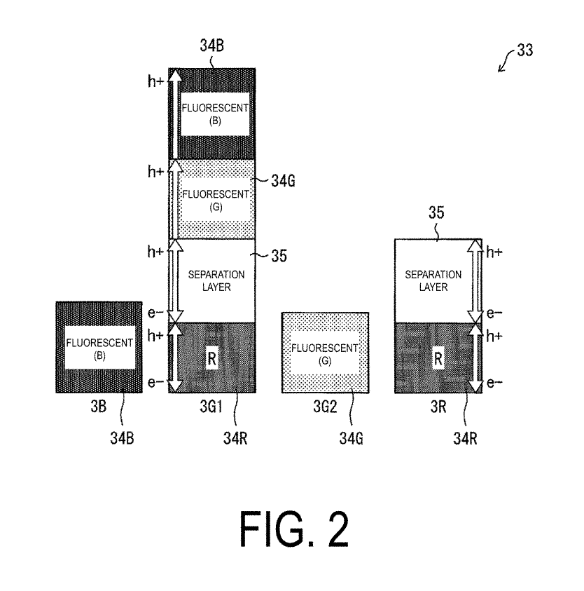

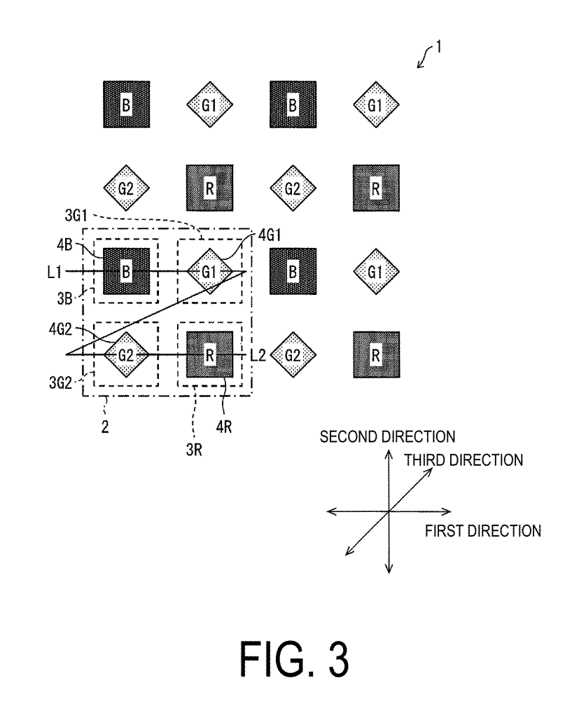

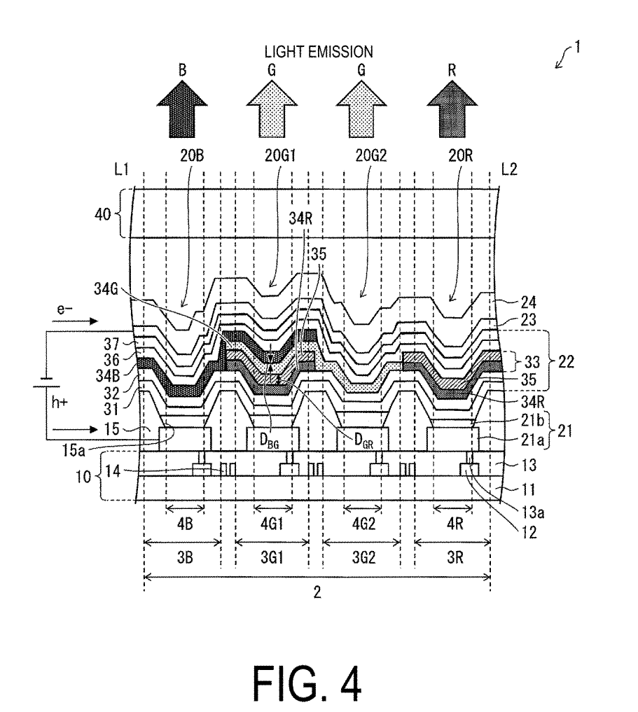

FIG. 1 is a diagram schematically illustrating the principle of light emission by a light-emitting layer unit 33 of an organic EL display device 1 according to the present embodiment. FIG. 2 is a diagram schematically illustrating the layered structure of the light-emitting layer unit 33 of the organic EL display device 1 according to the present embodiment. FIG. 3 is a diagram schematically illustrating a pixel arrangement in the organic EL display device 1 according to the present embodiment. FIG. 4 is a cross-sectional view illustrating an example of the overall configuration of the organic EL display device 1 according to the present embodiment. Note that FIG. 4 illustrates an example of the overall configuration of a single pixel area, enclosed within the single dot-single dash line in FIG. 3, and corresponds to a cross-section of the organic EL display device 1 taken along the line L1-L2 indicated in FIG. 3.

As illustrated in FIG. 4, the organic EL display device 1 has a configuration in which, for example, a Thin Film Transistor (TFT) substrate 10 (a substrate) and a sealing substrate 40 are affixed to each other by a sealing member (not illustrated). A plurality of organic EL elements 20 that emit different colors of light are provided on the TFT substrate 10. Accordingly, the organic EL elements 20 are sealed between the pair of substrates, i.e., the TFT substrate 10 and the sealing substrate 40. A filler layer (not illustrated), for example, is provided between the TFT substrate 10, on which the organic EL elements 20 are layered, and the sealing substrate 40. The following describes an example in which the TFT substrate 10 is rectangular in shape.

The organic EL display device 1 according to the present embodiment is a top-emitting display device that emits light from the sealing substrate 40 side. This will be described in more detail below.

### Configuration of TFT Substrate 10

The TFT substrate 10 is a circuit substrate in which a TFT circuit, which includes TFTs 12, wiring lines 14, and the like, is formed. The TFT substrate 10 includes an insulating substrate 11 (not illustrated) as a support substrate.

The insulating substrate 11 is not particularly limited as long as it has insulating properties. For example, various types of known insulating substrates, including an inorganic substrate such as a glass substrate or a silica substrate, a plastic substrate formed from polyethylene terephthalate or polyimide resin, or the like, can be used as the insulating substrate 11.

The present embodiment will later describe, as an example, a case where a transparent glass substrate (a transparent substrate) is used as the insulating substrate 11. However, the insulating substrate 11 need not be transparent for the top-emitting organic EL elements 20. Therefore, when the organic EL display device 1 is a top-emitting organic EL display device as in the present embodiment, an insulating substrate that is not transparent (a non-transparent substrate) and including a semiconductor substrate such as a silicon wafer, a substrate in which a surface of a metal substrate formed from aluminum (Al) or iron (Fe) is coated with an insulating material such as silicon oxide or an organic insulating material, a substrate in which a surface of a metal substrate formed from Al is subjected to an insulation treatment through an anode oxidation method, or the like, may be used as the insulating substrate 11.

A plurality of the wiring lines 14 are provided on the insulating substrate 11, the wiring lines 14 being constituted by a plurality of gate lines extending in the horizontal direction and a plurality of signal lines extending in the vertical direction and intersecting with the gate lines. The wiring lines 14 and the TFTs 12 are covered by an interlayer insulating film 13. A gate line drive circuit (not illustrated), which drives the gate lines, is connected to the gate lines, and a signal line drive circuit (not illustrated), which drives the signal lines, is connected to the signal lines.

Light emitting regions 4 of the organic EL elements 20, which emit red (R), green (G), and blue (B) light, respectively, are provided on the TFT substrate 10, in regions surrounded by the wiring lines 14.

In other words, the region surrounded by the wiring lines 14 is a single subpixel 3 (a dot), and R, G, and B light emitting regions 4 are defined for each subpixel 3.

As illustrated in FIGS. 3 and 4, each of pixels 2 (i.e., each pixel) is constituted by four subpixels, namely subpixels 3B, 3G1, 3G2, and 3R. Organic EL elements 20B, 20G1, 20G2, and 20R, which have corresponding luminescent colors, are provided as the organic EL elements 20 for the subpixels 3B, 3G1, 3G2, and 3R, respectively.

The subpixel 3B (a first subpixel; a blue subpixel), which displays blue serving as a first color, is constituted by the organic EL element 20B, which has a luminescent color of blue, and transmits blue light. The subpixel 3G1 (a second subpixel; a first green subpixel), which displays green serving as a second color, is constituted by the organic EL element 20G1, which has a luminescent color of green, and transmits green light. Likewise, the subpixel 3G2 (a third subpixel; a second green subpixel), which displays green serving as the second color, is constituted by the organic EL element 20G2, which has a luminescent color of green, and transmits green light. The subpixel 3R (a fourth subpixel; a red subpixel), which displays red serving as a third color, is constituted by the organic EL element 20R, which has a luminescent color of red, and transmits red light.

In the present embodiment, the subpixels 3B, 3G1, 3G2, and 3R will be collectively referred to simply as “subpixels 3” where there is no need to distinguish between the subpixels 3B, 3G1, 3G2, and 3R. Likewise, in the present embodiment, the organic EL elements 20B, 20G1, 20G2, and 20R will be collectively referred to simply as “organic EL elements 20” where there is no need to distinguish between the organic EL elements 20B, 20G1, 20G2, and 20R. Furthermore, light emitting regions 4B, 4G1, 4G2, and 4R will be collectively referred to simply as “light emitting regions 4” where there is no need to distinguish between the light emitting regions 4B, 4G1, 4G2, and 4R.

A plurality of the TFTs 12, including a TFT serving as a drive transistor supplying drive current to the organic EL element 20, are provided for each of the subpixels 3. The light emission intensity of each subpixel 3 is determined by scanning and selection by the wiring line 14 and the TFT 12. As described above, the organic EL display device 1 selectively causes each organic EL element 20 to emit light at the desired luminance using the TFT 12, thereby displaying an image.

### Configuration of Organic EL Element 20

As illustrated in FIG. 4, each organic EL element 20 includes a first electrode 21, an organic EL layer 22, and a second electrode 23. The organic EL layer 22 is interposed between the first electrode 21 and the second electrode 23. In the present embodiment, the layers provided between the first electrode 21 and the second electrode 23 are collectively referred to as the organic EL layer 22. The organic EL layer 22 is an organic layer constituted by at least one function layer, and includes the light-emitting layer unit 33, which in turn includes at least one of a blue fluorescent light-emitting layer 34B, a green fluorescent light-emitting layer 34G, and a red light-emitting layer 34R (the blue fluorescent light-emitting layer 34B, the green fluorescent light-emitting layer 34G, and the red light-emitting layer 34R will collectively be referred to simply as “light-emitting layers 34” hereinafter when there is no need to distinguish between the blue fluorescent light-emitting layer 34B, the green fluorescent light-emitting layer 34G, and the red light-emitting layer 34R).

The first electrode 21, the organic EL layer 22, and the second electrode 23 are layered in that order from the TFT substrate 10 side.

The first electrode 21 is formed in an island-like pattern for each subpixel 3, and an end portion of the first electrode 21 is covered by a bank 15 (a partition; an edge cover). The first electrode 21 is connected to the TFT 12 via a contact hole 13a provided in the interlayer insulating film 13.

The bank 15 is an insulating layer, and is constituted by a photosensitive resin, for example. The bank 15 prevents short-circuiting with the second electrode 23 due to increased electrode density, the organic EL layer 22 being thinner, or the like at the end portion of the first electrode 21. The bank 15 also functions as a pixel separation film to prevent current from leaking to adjacent subpixels 3.

An opening 15a is provided in the bank 15, for each subpixel 3. As illustrated in FIG. 4, parts of the first electrode 21 and the organic EL layer 22 exposed by the opening 15a correspond to the light emitting region 4 of each subpixel 3, and the other regions are non-emissive regions.

On the other hand, the second electrode 23 is a common electrode provided in common for the subpixels 3. However, the present embodiment is not limited thereto, and the second electrode 23 may be provided for each subpixel 3 individually.

A protection layer 24 is provided on the second electrode 23 to cover the second electrode 23. The protection layer 24 protects the second electrode 23, which serves as an upper electrode, and prevents outside oxygen and moisture from infiltrating into each organic EL element 20. Note that the protection layer 24 may be provided in common for all of the organic EL elements 20 so as to cover the second electrode 23 in all of the organic EL elements 20. In the present embodiment, the first electrode 21, the organic EL layer 22, and the second electrode 23, which are formed for each subpixel 3, as well as the protection layer 24 formed as necessary, are collectively referred to as the organic EL element 20.

### First Electrode 21 and Second Electrode 23

The first electrode 21 and the second electrode 23 serve as a pair of electrodes, with one functioning as an anode electrode and the other functioning as a cathode electrode.

The anode electrode may function as an electrode for injecting holes (h⁺) into the light-emitting layer unit 33. The cathode electrode may function as an electrode for injecting electrons (e⁻) into the light-emitting layer unit 33.

The shape, structure, size, or the like of the anode electrode and the cathode electrode are not particularly limited and can be appropriately selected according to the application and purpose of the organic EL element 20.

The present embodiment will describe an example in which the first electrode 21 is the anode electrode and the second electrode 23 is the cathode electrode, as illustrated in FIG. 4. However, the present embodiment is not limited thereto, and the first electrode 21 may be a cathode electrode and the second electrode 23 may be an anode electrode. The order in which the function layers constituting the light-emitting layer unit 33 are layered, or the carrier transport properties (hole transport properties and electron transport properties), are inverted depending on whether the first electrode 21 is an anode electrode and the second electrode 23 is a cathode electrode, or the first electrode 21 is a cathode electrode and the second electrode 23 is an anode electrode. Likewise, the materials constituting the first electrode 21 and the second electrode 23 are inverted as well.

Electrode materials that can be used as the anode electrode and the cathode electrode are not particularly limited. For example, known electrode materials can be used.

As the anode electrode, for example, metals such as gold (Au), platinum (Pt), and nickel (Ni), transparent electrode materials such as indium tin oxide (ITO), tin oxide (SnO₂), indium zinc oxide (IZO), and gallium-added zinc oxide (GZO), or the like can be used.

On the other hand, it is preferable that a material having a small work function be used for the cathode electrode to inject electrons into the light-emitting layer 34. As the cathode electrode, for example, metals such as lithium (Li), calcium (Ca), cerium (Ce), barium (Ba), and aluminum (Al), or alloys such as Ag (silver)-Mg (magnesium) alloy and Al—Li alloy containing these metals, can be used.

The thicknesses of the anode electrode and cathode electrode are not particularly limited, and can be set to the same thicknesses as employed in the past.

Light emitted by the light-emitting layer unit 33 is light emitted from the side on which one of the electrodes, out of the first electrode 21 and the second electrode 23, is located. Preferably, a transparent or semitransparent light-transmissive electrode (a transparent electrode, a semitransparent electrode) employing a light-transmissive electrode material is used as the electrode on the side where light is emitted, and a reflective electrode employing a reflective electrode material, or an electrode having a reflective layer which serves as a reflective electrode, is used as the electrode on the side where light is not emitted.

In other words, a variety of conductive materials can be used for the first electrode 21 and the second electrode 23. However, when the organic EL display device 1 is a top-emitting organic EL display device as described above, it is preferable that the first electrode 21 on the side of the TFT substrate 10, which serves as a support body supporting the organic EL elements 20, be formed from a reflective electrode material, and that the second electrode 23, which is located on the side opposite from the first electrode 21 with the organic EL elements 20 interposed therebetween, be formed from a transparent or semitransparent light-transmissive electrode material.

The first electrode 21 and the second electrode 23 may each have a single layer structure formed from one electrode material, or may each have a layered structure formed from a plurality of electrode materials.

Accordingly, when the organic EL elements 20 are top-emitting organic EL elements as described above, the first electrode 21 may have a layered structure including a reflective electrode 21a (a reflective layer) and a light-transmissive electrode 21b, as illustrated in FIG. 2. In the present embodiment, the first electrode 21 has a configuration in which the reflective electrode 21a and the light-transmissive electrode 21b are layered in that order from the TFT substrate 10 side.

Examples of reflective electrode materials include a black electrode material such as tantalum (Ta) or carbon (C), and a reflective metal electrode material such as Al, Ag, gold (Au), Al—Li alloy, Al-neodymium (Nd) alloy, or Al-silicon (Si) alloy.

A transparent electrode material such as those described above, or a semitransparent electrode material such as a thin film of Ag, may be used as the light-transmissive electrode material, for example.

### Organic EL Layer 22

As illustrated in FIG. 4, the organic EL layer 22 according to the present embodiment has a configuration in which a hole injection layer 31, a hole transport layer 32, the light-emitting layer unit 33 including the light-emitting layer 34, an electron transport layer 36, and an electron injection layer 37, serving as function layers, are layered in that order from the first electrode 21 side. The hole injection layer 31, the hole transport layer 32, the electron transport layer 36, and the electron injection layer 37 are provided in common for the subpixels 3 in all of the pixels 2.

However, the function layers aside from the light-emitting layer unit 33 are not layers necessary for the organic EL layer 22, and may be formed as appropriate according to required properties of the organic EL element 20. Each of the above-described function layers will be described next.

### Light-Emitting Layer Unit 33

As described above, the organic EL layer 22 in each organic EL element 20 is an organic layer constituted by at least one function layer. The light-emitting layer unit 33 in each organic EL element 20 includes at least one light-emitting layer 34, as illustrated in FIGS. 1, 2, and 4.

Of the organic EL elements 20, the organic EL element 20B includes, as the light-emitting layer 34, a blue fluorescent light-emitting layer 34B containing a blue fluorescent luminescent material that emits blue light. The organic EL element 20R includes, as the light-emitting layer 34, a red light-emitting layer 34R containing a red luminescent material that emits red light. The organic EL element 20G2 includes, as the light-emitting layer 34, a green fluorescent light-emitting layer 34G containing a green fluorescent luminescent material that emits green light. The organic EL element 20G2 includes, as the light-emitting layers 34, the red light-emitting layer 34R, the green fluorescent light-emitting layer 34G, and the blue fluorescent light-emitting layer 34B. In other words, while each of the organic EL elements 20B, 20G2, and 20R is provided with only one light-emitting layer 34, the organic EL element 20G1 is provided with each of the light-emitting layers 34 provided in the organic EL elements 20B, 20G2, and 20R (in other words, the R, G, and B light-emitting layers 34).

The blue fluorescent light-emitting layer 34B is provided in common for the subpixel 3B and the subpixel 3G1. The green fluorescent light-emitting layer 34G is provided in common for the subpixel 3G1 and the subpixel 3G2. The red light-emitting layer 34R is provided in common for the subpixel 3G1 and the subpixel 3R.

As such, in each pixel 2, a plurality of function layers including at least the blue fluorescent light-emitting layer 34B, the green fluorescent light-emitting layer 34G, and the red light-emitting layer 34R are formed between the first electrode 21 and the second electrode, as illustrated in FIG. 4. In each subpixel 3, at least one function layer including at least one of the light-emitting layers 34 among the blue fluorescent light-emitting layer 34B, the green fluorescent light-emitting layer 34G, and the red light-emitting layer 34R, is provided between the first electrode 21 and the second electrode.

In the subpixel 3G1, the blue fluorescent light-emitting layer 34B and the green fluorescent light-emitting layer 34G are provided adjacent to each other, whereas a separation layer 35 that inhibits Förster-type energy transfer (Förster transfer) is provided between the green fluorescent light-emitting layer 34G and the red light-emitting layer 34R.

The separation layer 35 does not contain a luminescent material, is constituted by at least one function layer aside from the light-emitting layer, and has a thickness exceeding the Förster radius. Preferably, the separation layer 35 is at least 15 nm thick.

“Förster radius” refers to the distance between adjacent light-emitting layers 34 at which Förster transfer can arise (specifically, the distance between opposing surfaces of adjacent light-emitting layers 34 that are closest to each other). The Förster radius is higher when there is a large amount of overlap between the photoluminescence (PL) emission spectrum of the luminescent material contained in one of the adjacent light-emitting layers 34 and the absorption spectrum of the luminescent material contained in the other of the light-emitting layers 34, and the Förster radius is lower when there is a small amount of such overlap.

The Förster radius is said to typically be approximately from 1 to 10 nm. As such, Förster transfer will not arise as long as the distance between the opposing surfaces of light-emitting layers 34 adjacent to each other is kept greater than 10 nm.

However, making the distance between adjacent light-emitting layers 34 at least 15 nm ensures that Förster transfer will not arise between the adjacent light-emitting layers 34 even if the photoluminescence (PL) emission spectrum and the absorption spectrum of the luminescent materials in the adjacent light-emitting layers 34 overlap perfectly. It is therefore preferable that the distance between opposing surfaces of the green fluorescent light-emitting layer 34G and the red light-emitting layer 34R (an opposing surface distance D_{GR}), i.e., a distance between the surface of the green fluorescent light-emitting layer 34G located furthest on the red light-emitting layer 34R side (a lower surface of the green fluorescent light-emitting layer 34G, in the present embodiment) and the surface of the red light-emitting layer 34R located furthest on the green fluorescent light-emitting layer 34G side (an upper surface of the red light-emitting layer 34R, in the present embodiment), be greater than or equal to 15 nm. For this reason, preferably, the separation layer 35 is at least 15 nm thick.

Like the red light-emitting layer 34R, the separation layer 35 is provided in common for the subpixel 3G1 and the subpixel 3R. Note that the thickness of the separation layer 35 may be set to any thickness capable of inhibiting Förster transfer, and is not limited to a thickness exceeding the Förster radius. An increase in the thickness of the separation layer 35 will result in a corresponding increase in the thickness of the organic EL display device 1, and thus from the standpoint of keeping the organic EL display device 1 small, achieving low voltages for the elements, and the like, a thickness of less than or equal to 50 nm is preferable, and a thickness of less than or equal to 30 nm is more preferable.

As such, part of the separation layer 35 is interposed between the green fluorescent light-emitting layer 34G and the red light-emitting layer 34R in the subpixel 3G1, and another part is layered adjacent to the red light-emitting layer 34R in the subpixel 3R.

In each embodiment, a layered body constituted by the light-emitting layer 34 and an intermediate layer including function layers, aside from the light-emitting layer 34, that are at least partially interposed between a plurality of light-emitting layers 34, is referred to as the light-emitting layer unit 33. Note that the intermediate layer is the separation layer 35 in the organic EL display device 1 according to the present embodiment.

In the organic EL display device 1 according to the present embodiment, the light-emitting layers 34 and the separation layer 35 constituting the light-emitting layer unit 33 in the pixel 2 are layered in the following order, from the first electrode 21 side, as illustrated in FIGS. 1, 2, and 4: the red light-emitting layer 34R, the separation layer 35, the green fluorescent light-emitting layer 34G, and the blue fluorescent light-emitting layer 34B.

The light-emitting layer unit 33 is constituted by the blue fluorescent light-emitting layer 34B in the subpixel 3B, and in the subpixel 3G1, has a layered structure in which the red light-emitting layer 34R, the separation layer 35, the green fluorescent light-emitting layer 34G, and the blue fluorescent light-emitting layer 34B are layered in that order from the first electrode 21 side. In the subpixel 3G2, the light-emitting layer unit 33 is constituted by the green fluorescent light-emitting layer 34G, and in the subpixel 3R, has a layered structure in which the red light-emitting layer 34R and the separation layer 35 are layered in that order from the first electrode 21 side.

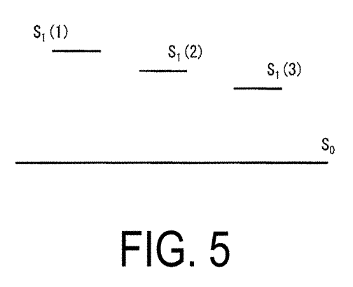

FIG. 5 is a diagram illustrating a relationship between energy levels of the blue fluorescent luminescent material, the green fluorescent luminescent material, and the red luminescent material, in minimum excited singlet states (denoted as “S₁ levels” hereinafter). In FIG. 5, S₁(1) indicates the S₁ level of the blue fluorescent luminescent material, which is a first fluorescent luminescent material; S₁(2) indicates the S₁ level of the green fluorescent luminescent material, which is a second fluorescent luminescent material; and S₁(3) indicates the S₁ level of the red luminescent material, which is a third luminescent material. Note that S₀ indicates a ground state in FIG. 5.

As illustrated in FIG. 5, the energy level of the green fluorescent luminescent material in the minimum excited singlet state (S₁(2)) is lower than the S₁ level of the blue fluorescent luminescent material (S₁(1)) and is higher than the S₁ level of the red luminescent material (S₁(3)).

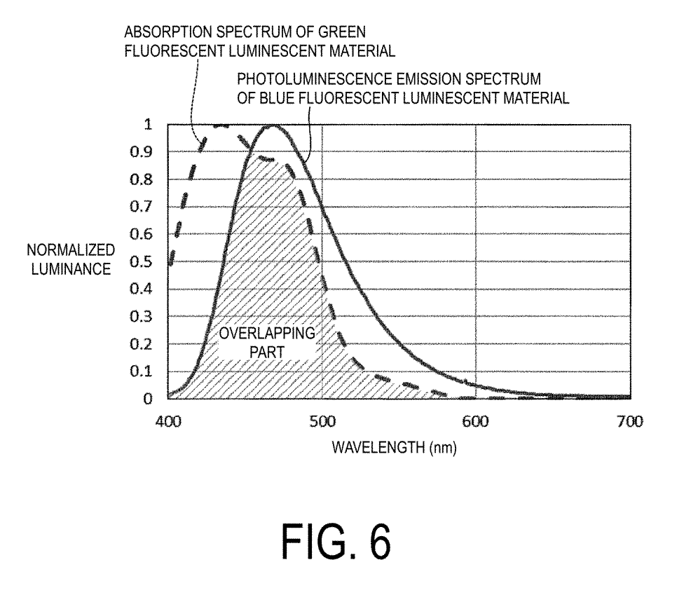

FIG. 6 is a graph illustrating an example of the photoluminescence (PL) emission spectrum of the blue fluorescent luminescent material and the absorption spectrum of the green fluorescent luminescent material used in the present embodiment.

Note that FIG. 6 indicates the PL emission spectrum of 2,5,8,11-tetra-tert-butylperylene (TBPe), used in Example 1 defining dimensions, materials, and the mixing ratio of materials (described later), as the PL emission spectrum of the blue fluorescent luminescent material, and indicates the absorption spectrum of 2,3-(2-benzothiazolyl)-7-(diethylamino) coumarin (coumarin 6), used in Example 1 defining dimensions, materials, and the mixing ratio of materials (described later), as the absorption spectrum of the green fluorescent luminescent material.

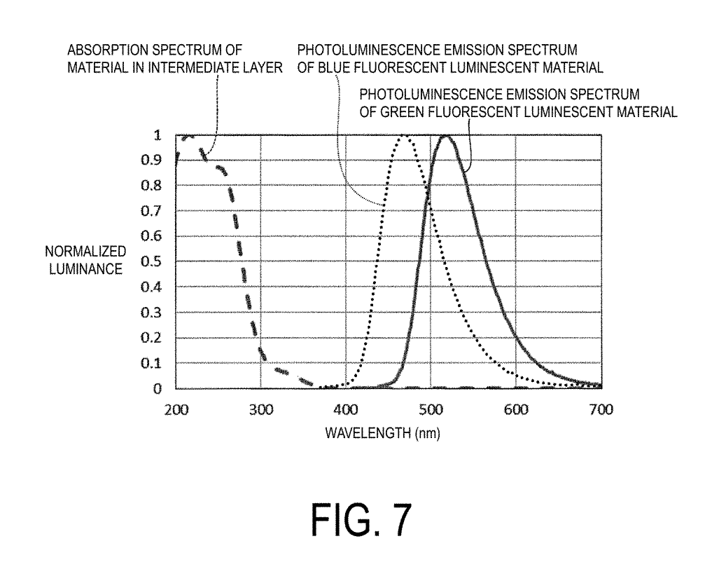

FIG. 7 is a graph illustrating an example of the absorption spectrum of the material of the separation layer 35, the PL emission spectrum of the green fluorescent luminescent material, and the PL emission spectrum of the blue fluorescent luminescent material, used in the present embodiment.

Note that FIG. 7 indicates the absorption spectrum of 4,4′-bis (9-carbazoyl)-biphenyl (CBP), used in Example 1 defining dimensions, materials, and the mixing ratio of materials (described later), as the absorption spectrum of the material of the separation layer 35. FIG. 7 also indicates the PL emission spectrum of coumarin 6, described above used in Example 1 defining dimensions, materials, and the mixing ratio of materials (described later), as the PL emission spectrum of the green fluorescent luminescent material; and the PL emission spectrum of TBPe, used in Example 1 defining dimensions, materials, and the mixing ratio of materials (described later) and illustrated in FIG. 6, as the PL emission spectrum of the blue fluorescent luminescent material.

As illustrated in FIG. 6, preferably, the PL emission spectrum of the blue fluorescent luminescent material and the absorption spectrum of the green fluorescent luminescent material partially overlap. Furthermore, as illustrated in FIG. 7, it is preferable that there is no overlapping between the following: the absorption spectrum of an intermediate layer adjacent to the red light-emitting layer 34R (a first intermediate layer), or in other words, of all the materials in the intermediate layer provided between the red light-emitting layer 34R and the light-emitting layer adjacent to the red light-emitting layer 34R in the layering direction (the green fluorescent light-emitting layer 34G, in the present embodiment) (in other words, the material of the separation layer 35); and the PL emission spectrum of at least the green fluorescent luminescent material in the green fluorescent light-emitting layer 34G, which is the light-emitting layer adjacent to the stated intermediate layer (i.e., the separation layer 35), among the blue fluorescent light-emitting layer 34B and the green fluorescent light-emitting layer 34G that are the light-emitting layers provided on the opposite side of the intermediate layer from the red light-emitting layer 34R. Additionally, it is preferable that there is no overlapping between the absorption spectrum of all the materials contained in the intermediate layer (i.e., the separation layer 35), and the PL emission spectrum of the green fluorescent luminescent material and the PL emission spectrum of the blue fluorescent luminescent material.

Ensuring the PL emission spectrum of the blue fluorescent luminescent material and the absorption spectrum of the green fluorescent luminescent material partially overlap in this manner makes it easy for energy to be transferred from the blue fluorescent luminescent material to the green fluorescent luminescent material.

In the subpixel 3G1, the blue fluorescent light-emitting layer 34B and the green fluorescent light-emitting layer 34G are in direct contact, and thus the distance between opposing surfaces of the blue fluorescent light-emitting layer 34B and the green fluorescent light-emitting layer 34G (an opposing surface distance D_{BG}) is less than or equal to the Förster radius.

Thus, in the subpixel 3G1, Förster transfer arises, from the S₁ level of the blue fluorescent luminescent material to the S₁ level of the green fluorescent luminescent material. In other words, Förster transfer arises from the blue fluorescent light-emitting layer 34B to the green fluorescent light-emitting layer 34G.

Note that in the present embodiment, the distance between opposing surfaces of the blue fluorescent light-emitting layer 34B and the green fluorescent light-emitting layer 34G (the opposing surface distance D_{BG}) is a distance between the surface of the blue fluorescent light-emitting layer 34B located furthest on the green fluorescent light-emitting layer 34G side (a lower surface of the blue fluorescent light-emitting layer 34B, in the present embodiment) and the surface of the green fluorescent light-emitting layer 34G located furthest on the blue fluorescent light-emitting layer 34B side (an upper surface of the green fluorescent light-emitting layer 34G, in the present embodiment).

On the other hand, having no overlapping between the absorption spectrum of all the materials contained in the intermediate layer (the first intermediate layer; the separation layer 35) and the PL emission spectrum of at least the green fluorescent luminescent material in the green fluorescent light-emitting layer 34G, which among the blue fluorescent light-emitting layer 34B and the green fluorescent light-emitting layer 34G is the light-emitting layer adjacent to the separation layer 35, makes it difficult for energy transfer to occur from the blue fluorescent luminescent material and the green fluorescent luminescent material to the material contained in the intermediate layer. Note that ensuring that there is no overlapping between the absorption spectrum of all the materials contained in the intermediate layer (the first intermediate layer; the separation layer 35), and the PL emission spectrum of the green fluorescent luminescent material and the PL emission spectrum of the blue fluorescent luminescent material, makes it even more difficult for energy transfer to occur from the green fluorescent luminescent material and the blue fluorescent luminescent material to the material contained in the intermediate layer.

The separation layer 35 has a thickness exceeding the Förster radius, and thus the opposing surface distance D_{GR} in the subpixel 3G1 is greater than the Förster radius.

Thus in the subpixel 3G1, Förster-type energy transfer does not arise from the green fluorescent light-emitting layer 34G to the red light-emitting layer 34R through the separation layer 35. Of course, the separation layer 35 is provided between the green fluorescent light-emitting layer 34G and the red light-emitting layer 34R, and the green fluorescent light-emitting layer 34G and the red light-emitting layer 34R are not in contact with each other, which means that Dexter-type energy transfer does not occur as well.

Each of the light-emitting layers 34 may be formed from a two-component system including a host material for transporting holes and electrons and a luminescent dopant (guest) material serving as a luminescent material and emitting light, or may be formed from a luminescent material alone.

Of the materials (components) of the light-emitting layer 34, either the host material or the luminescent material may have the greater content percentage.

The host material is a material into which holes and electrons can be injected, and has a function of causing the luminescent material to emit light by holes and electrons being transported and recombining within the molecules of the material. When using a host material, the luminescent material is dispersed uniformly throughout the host material.

When using a host material, an organic compound having a higher value for the S₁ level, the energy level in a minimum excited triplet state (denoted as “T₁ level” hereinafter), or both, than that of the luminescent material, is used for the host material. Accordingly, the host material can trap the energy of the luminescent material in the luminescent material, which makes it possible to improve the light emission efficiency of the luminescent material.

To improve the efficiency of the luminescent colors to be displayed by the subpixels 3 having the layered structure described in the present embodiment, it is desirable that the material in the green fluorescent light-emitting layer 34G having the highest content percentage and the material in the blue fluorescent light-emitting layer 34B having the highest content percentage, and desirably both materials, be hole transporting materials with extremely low electron mobility, as indicated by the arrows in FIGS. 1 and 2 that represent the movement of holes (h⁺) and electrons (e⁻). Additionally, it is desirable that the separation layer 35 exhibit bipolar transport properties, where both the hole transport properties and the electron transport properties are high, for the separation layer 35 as a whole. Accordingly, the material contained in the separation layer 35 may be a material exhibiting bipolar transport properties alone, such as a bipolar transporting material. Alternatively, two or more types of a material that alone exhibits hole transport properties in which the hole mobility is higher than the electron mobility, or a material that alone exhibits electron transport properties in which the electron mobility is higher than the hole mobility, may be used in combination so as to exhibit bipolar transport properties as the separation layer 35. Furthermore, it is desirable that the material in the red light-emitting layer 34R having the highest combination ratio be a bipolar transporting material, as indicated in FIGS. 1 and 2. However, this material may be a hole transporting material.

Hole transporting materials such as 4,4′-bis [N-phenyl-N-(3″-methylphenyl) amino] biphenyl (TPD), 9,10-di (2-naphthyl) anthracene (ADN), 1,3-bis (carbazol-9-yl) benzene (mCP), and 3,3′-di (9H-carbazol-9-yl) biphenyl (mCBP), can be given as examples of host materials having hole transport properties. Electron transporting materials such as 2,9-dimethyl-4,7-diphenyl-1,10-phenanthroline (BCP), bis [(2-diphenylphosphoryl) phenyl] ether (DPEPO), 4,4′-Bis (2,2-diphenylvinyl)-1,1′-biphenyl (DPVBi), 2,2′,2″-(1,3,5-benztrile)-tris (1-phenyl-benzimidazolyl) (TPBi), and bis (2-methyl-8-quinolinolate)-4-(phenylphenolate) aluminum (BAlq), can be given as examples of host materials having electron transport properties. A bipolar transporting material such as 4,4′-bis (9-carbazoyl)-biphenyl (CBP) can be given as an example of a host material having bipolar transport properties.

The luminescent materials in the blue fluorescent light-emitting layer 34B and the green fluorescent light-emitting layer 34G are both fluorescent luminescent materials.

A fluorescent luminescent material that emits blue light, such as 2,5,8,11-tetra-tert-butylperylene (TBPe), bis [4-(9,9-dimethyl-9,10-dihydroacridine) phenyl] sulfone (DMAC-DPS), perylene, and 4,5-bis (carbazol-9-yl)-1,2-dicyanobenzene (2CzPN), can be used as the blue fluorescent luminescent material.

3-(2-benzothiazolyl)-7-(diethylamino) coumarin (coumarin 6), 8-hydroxyquinoline aluminum (Alq 3), 1,2,3,5-tetrakis (carbazol-9-yl)-4,6-dicyano benzene (4CzIPN), 1,2,3,4-tetrakis (carbazol-9-yl)-5,6-dicyanobenzene (4CzPN), PXZ-DPS indicated in the following formula, and the like can be given as examples of green fluorescent luminescent materials.

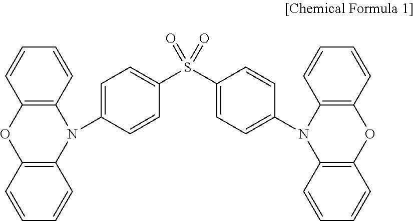 [SMILES: O=S(=O)(c1ccc(N2c3ccccc3Oc3ccccc32)cc1)c1ccc(N2c3ccccc3Oc3ccccc32)cc1]

These materials can be given as examples of green fluorescent luminescent.

The red luminescent material may be a phosphorescent luminescent material or a fluorescent luminescent material, as long as the luminescent color is red. However, because the red light-emitting layer 34R does not use energy transfer, a phosphorescent luminescent material or a Thermally Activated Delayed Fluorescence (TADF) material has a high light emission efficiency and is therefore desirable.

The TADF material is a material in which a minimum excited singlet state can be generated through reverse intersystem crossing from a minimum excited triplet state by thermal activation, and is a delayed fluorescent material in which the energy difference ΔE_{ST} between the S₁ level and the T₁ level is extremely small. When a delayed fluorescent material in which the energy difference ΔE_{ST} between the S₁ level and the T₁ level is extremely small is used for the luminescent material, reverse intersystem crossing from the T₁ level to the S₁ level occurs due to thermal energy. Using the delayed fluorescence provided by the TADF material can theoretically enhance the internal quantum efficiency to 100%, even in the case of fluorescent light emission. The lower ΔE_{ST} is, the easier it is for reverse intersystem crossing to arise from the minimum excited triplet state to the minimum excited singlet state, and reverse intersystem crossing can occur comparatively easily, even at room temperature, if ΔE_{ST} is less than or equal to 0.3 eV.

Tetraphenyldibenzoperilenthene (DBP), (E)-2-{2-[4-(dimethylamino) styryl]-6-methyl-4H-pyran-4-ylidene} malononitrile (DCM), and the like can be given as examples of red fluorescent luminescent materials. Tris (1-phenylisoquinoline) iridium (III) (Ir(piq)3), bis (2-benzo [b] thiophen-2-yl-pyridine) (acetylacetonate) iridium (III) (Ir (btp) 2 (acac)), and the like can be given as examples of red phosphorescent luminescent materials. Examples of the TADF material that emits red light include PPZ-DPO, indicated by the following formula:

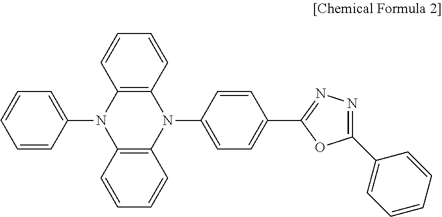 [SMILES: c1ccc(-c2nnc(-c3ccc(N4c5ccccc5N(c5ccccc5)c5ccccc54)cc3)o2)cc1]

PPZ-DPS, indicated by the following formula:

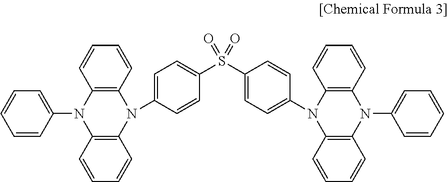 [SMILES: O=S(=O)(c1ccc(N2c3ccccc3N(c3ccccc3)c3ccccc32)cc1)c1ccc(N2c3ccccc3N(c3ccccc3)c3ccccc32)cc1]

and 4CzTPN-Ph, indicated by the following formula:

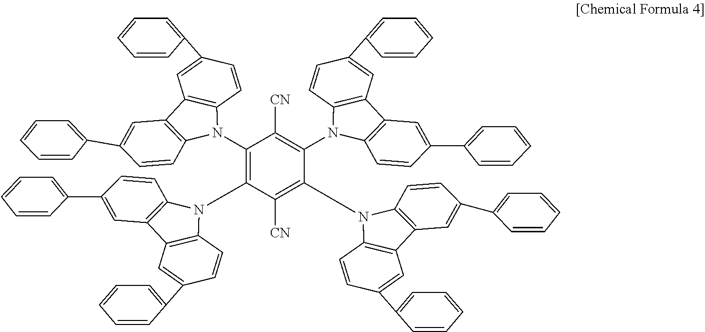 [SMILES: N#Cc1c(-n2c3ccc(-c4ccccc4)cc3c3cc(-c4ccccc4)ccc32)c(-n2c3ccc(-c4ccccc4)cc3c3cc(-c4ccccc4)ccc32)c(C#N)c(-n2c3ccc(-c4ccccc4)cc3c3cc(-c4ccccc4)ccc32)c1-n1c2ccc(-c3ccccc3)cc2c2cc(-c3ccccc3)ccc21]

These material can be used.

4,4′-bis (9-carbazoyl)-biphenyl (CBP) or the like, which is one of the above-described bipolar transporting materials, can be given as an example of the separation layer 35.

The thicknesses of the function layers in the light-emitting layer unit 33 are not particularly limited as long as the layers are formed so that the opposing surface distance D_{GR} and the opposing surface distance D_{BG} satisfy the above-described conditions.

However, of the light-emitting layer unit 33, it is preferable that the thickness of the blue fluorescent light-emitting layer 34B be set to less than or equal to 10 nm. Setting the thickness of the blue fluorescent light-emitting layer 34B to less than or equal to 10 nm ensures that the distance, in the subpixel 3G1, from the molecules of the blue fluorescent luminescent material in the blue fluorescent light-emitting layer 34B that are furthest from the green fluorescent light-emitting layer 34G (i.e., the molecules at the surface of the blue fluorescent light-emitting layer 34B on the side opposite from the side on which the green fluorescent light-emitting layer 34G is located, which in the present embodiment are the molecules of the blue fluorescent luminescent material located on the upper surface of the blue fluorescent light-emitting layer 34B) to green fluorescent luminescent material in the green fluorescent light-emitting layer 34G is less than or equal to 10 nm. In other words, the shortest distances from given positions of the blue fluorescent light-emitting layer 34B to the green fluorescent light-emitting layer 34G are all less than or equal to 10 nm. As such, Förster transfer is possible from the molecules at a given location of the blue fluorescent luminescent material to the green fluorescent luminescent material in the subpixel 3G1. Förster transfer is also possible from, for example, molecules of the blue fluorescent luminescent material located at the surface of the blue fluorescent light-emitting layer 34B on the opposite side from the side on which the green fluorescent light-emitting layer 34G is located.

### Hole Injection Layer 31 and Hole Transport Layer 32

The hole injection layer 31 includes a material with hole injecting properties, and has a function of increasing the hole injection efficiency to the light-emitting layer 34. The hole injection layer 31 and the hole transport layer 32 may be formed as mutually independent layers, or may be integrated together as a hole injection-cum-transport layer. It is not necessary that both the hole injection layer 31 and the hole transport layer 32 be provided, and only one (e.g., the hole transport layer 32) may be provided.

A known material can be used as the material of the hole injection layer 31, the hole transport layer 32, or the hole injection-cum-transport layer, that is, as a hole injection material or a hole transporting material.

Examples of such a material include linear or heterocyclic conjugated monomers, oligomers, or polymers such as naphthalene, anthracene, azatriphenylene, fluorenone, hydrazone, stilbene, triphenylene, benzine, styrylamine, triphenylamine, porphyrins, triazole, imidazole, oxadiazole, oxazole, polyarylalkane, phenylenediamine, arylamine, and derivatives thereof, a thiophene-based compound, a polysilane-based compound, a vinyl carbazole-based compound, and an aniline-based compound. Specifically, N,N′-di(naphthalen-1-yl)-N,N′-diphenyl-benzidine (α-NPD), 2,3,6,7,10,11-hexacyano-1,4,5,8,9,12-hexaazatriphenylene (HAT-CN), 1,3-bis(carbazol-9-yl)benzene (mCP), di-[4-(N,N-ditolyl-amino)-phenyl]cyclohexane (TAPC), 9,10-diphenylanthracene-2-sulfonate (DPAS), N,N′-diphenyl-N,N′-(4-(di(3-tolyl)amino)phenyl)-1,1′-biphenyl-4,4′-diamine (DNTPD), iridium (III) tris[N,N′-diphenylbenzimidazol-2-ylidene-C2,C2′] (Ir(dpbic)₃), 4,4′,4″-tris-(N-carbazolyl)-triphenylamine (TCTA), 2,2-bis(p-trimellitic oxyphenyl)propanoic anhydride (BTPD), bis[4-(p,p-ditolylamino)phenyl]diphenylsilane (DTASi), or the like is used.

For the hole injection layer 31, the hole transport layer 32, or the hole injection-cum-transport layer, an intrinsic hole injecting material or an intrinsic hole transporting material that is not doped with an impurity may be used. Alternatively, the material may be doped with an impurity to enhance the electrical conductivity.

To achieve highly-efficient light emission, it is desirable that the excitation energy be trapped within the light-emitting layer unit 33, and particularly within the light-emitting layer 34 of the light-emitting layer unit 33. Therefore, it is desirable that as the hole injecting material and the hole transporting material, a material having an S₁ level and a T₁ level that are excitation levels higher than the S₁ level and the T₁ level of the luminescent material in the light-emitting layer 34 be used. Therefore, it is more preferable that as the hole injecting material and the hole transporting material, a material having high excitation level and high hole mobility be selected.

### Electron Transport Layer 36 and Electron Injection Layer 37

The electron injection layer 37 includes an electron injecting material and has a function of increasing the electron injection efficiency to the light-emitting layer 34.

The electron transport layer 36 includes an electron transporting material and has a function of increasing the electron transport efficiency to the light-emitting layers 34.

The electron injection layer 37 and the electron transport layer 36 may be formed as mutually independent layers, or may be integrated together as an electron injection-cum-transport layer. It is not necessary that both the electron injection layer 37 and the electron transport layer 36 be provided, and only one, e.g., the electron transport layer 36, may be provided. Of course, it is acceptable for neither to be provided as well.

A known material can be used as a material for the electron injection layer 37, the electron transport layer 36, or an electron injection-cum-transport layer, i.e., a material used as the electron injecting material or the electron transporting material.

Examples of the material include quinoline, perylene, phenanthroline, bistyryl, pyrazine, triazole, oxazole, oxadiazole, fluorenone, and derivatives and metal complexes thereof, and lithium fluoride (LiF).

More specific examples thereof include bis[(2-diphenylphosphoryl)phenyl]ether (DPEPO), 4,7-diphenyl-1,10-phenanthroline (Bphen), 3,3′-bis(9H-carbazole-9-yl)biphenyl (mCBP), 2,9-dimethyl-4,7-diphenyl-1,10-phenanthroline (BCP), 1,3,5-tris(N-phenylbenzoimidazole-2-yl)benzene (TPBI), 3-phenyl-4(1′-naphthyl)-5-phenyl-1,2,4-triazole (TAZ), 1,10-phenanthroline, Alq(tris(8-hydroxyquinoline)aluminum), LiF, and the like.

### Protection Layer 24

The protection layer 24 is formed from a transparent insulating material or conductive material. Inorganic insulating materials such as silicon nitride (SiN), silicon oxide (SiO), silicon oxynitride (SiON), and aluminum oxide (Al₂O₃), conductive materials such as ITO, and the like can be given as examples of the material of the protection layer 24. Note that the protection layer 24 may have a layered structure including an inorganic insulating layer and an organic insulating layer. A polysiloxane, silicon oxide carbide (SiOC), an acrylate, a polyurea, parylene, a polyimide, a polyamide, and the like can be given as examples of organic insulating materials that can be used as the organic insulating layer.

The thickness of the protection layer 24 is not particularly limited, and may be set as appropriate in accordance with the material so that oxygen, moisture, and the like can be prevented from infiltrating into the organic EL elements 20.

### Sealing Substrate 40

An insulating substrate such as a glass substrate or a plastic substrate can be used as the sealing substrate 40. When the organic EL display device 1 is a top-emitting organic EL display device as in the present embodiment, a transparent insulating substrate is used as the sealing substrate 40.

Note that the insulating substrate 11 and the sealing substrate 40 may be flexible insulating films. Using flexible substrates for the insulating substrate 11 and the sealing substrate 40 makes it possible to make the organic EL display device 1 a flexible display or a bendable display.

Note that gap spacers (not illustrated) may be provided between the TFT substrate 10 and the sealing substrate 40, to prevent the sealing substrate 40 from contacting the TFT substrate 10 and damaging the organic EL elements 20.

### Display Method of Organic EL Display Device 1

A display method of the organic EL display device 1 according to the present embodiment will be described next.

As described earlier, the organic EL display device 1 includes a plurality of subpixels 3 in which the organic EL elements 20, which include the light-emitting layers 34 of the respective colors, are provided. A color display is achieved by using the TFTs 12 to selectively cause the organic EL elements 20 in the subpixels 3 to emit light at desired luminances. The emission of light by the subpixels 3 will be described next.

The organic EL display device 1 according to the present embodiment is an active-matrix organic EL display device, and a plurality of the pixels 2 are arranged in a matrix in a display region.

As described above, each pixel 2 includes two types of green subpixels 3 (subpixels 3G), namely the subpixel 3G1 and the subpixel 3G2, and is therefore constituted by four subpixels 3, namely the subpixel 3B, the subpixel 3G1, the subpixel 3G2, and the subpixel 3R.

As illustrated in FIG. 3, the pixels 2 in the display region have a PenTile-type pixel arrangement (PenTile arrangement), in which the subpixel 3G1 is adjacent to the subpixel 3B in a row direction (a first direction) and adjacent to the subpixel 3R in the column direction (i.e., a direction orthogonal to the row direction; a second direction), the subpixel 3G2 is adjacent to the subpixel 3R in the row direction and adjacent to the subpixel 3B in the column direction, and the subpixel 3B is adjacent to the subpixel 3R, and the subpixel 3G1 to the subpixel 3G2, in an oblique direction (a third direction) intersecting with the row direction and the column direction (specifically, intersecting with those directions at an angle of 45 degrees). Accordingly, in the display region, the pixels 2 are arranged such that in the row direction, the subpixel 3B is adjacent to the subpixel 3G1 and the subpixel 3G2 is adjacent to the subpixel 3R, and in the column direction, the subpixel 3B is adjacent to the subpixel 3G2 and the subpixel 3G1 is adjacent to the subpixel 3R. A column constituted by the subpixel 3B and the subpixel 3G1, and a column constituted by the subpixel 3G2 and the subpixel 3R, which are formed along the row direction, are arranged so as to alternate in the column direction. The subpixels 3B and the subpixels 3G1 are arranged in an alternating manner in odd-numbered rows, for example, and the subpixels 3G2 and the subpixels 3R are arranged in an alternating manner in even-numbered rows. Additionally, the subpixels 3B and the subpixels 3G2 are arranged in an alternating manner in odd-numbered columns, for example, and the subpixels 3G1 and the subpixels 3R are arranged in an alternating manner in even-numbered columns.

According to the present embodiment, employing a PenTile type pixel arrangement makes it possible to improve the apparent resolution.

Unlike organic EL display devices having a known PenTile-type pixel arrangement, the subpixel 3G1 and the subpixel 3G2 have different layered structures in the present embodiment, as illustrated in FIGS. 1, 2, and 4.

In the organic EL display device 1 according to the present embodiment, the holes (h⁺) and electrons (e⁻) injected into the organic EL layer 22 from the first electrode 21 and the second electrode 23, respectively, as indicated in FIG. 4, recombine and generate excitons in the blue fluorescent light-emitting layer 34B of the subpixel 3B, and recombine and generate excitons in the green fluorescent light-emitting layer 34G of the subpixel 3G2, as indicated in FIG. 1. The generated excitons give out light upon deactivating and returning to a ground state (denoted as “S₀” hereinafter). As a result, the subpixel 3B emits blue light, and the subpixel 3G2 emits green light.

Furthermore, as described earlier, a bipolar transporting material, for example, is used for the material having the highest content percentage among the materials in the red light-emitting layer 34R and the separation layer 35. Accordingly, in the subpixel 3R, the holes and electrons injected into the organic EL layer 22 from the first electrode 21 and the second electrode 23, respectively, recombine in the red light-emitting layer 34R and generate excitons, as indicated in FIG. 1.

Additionally, as described earlier, the S₁ level of the green fluorescent luminescent material is lower than the S₁ level of the blue fluorescent luminescent material, and a hole transporting material is used for at least one of the material in the blue fluorescent light-emitting layer 34B having the highest content percentage and the material in the green fluorescent light-emitting layer 34G having the highest content percentage. A bipolar transporting material, for example, is used for the material in the red light-emitting layer 34R and the separation layer 35 having the highest content percentage. The S₁ level of the green fluorescent luminescent material is higher than the S₁ level of the red luminescent material, but because the separation layer 35 having a thickness exceeding the Förster radius is provided between the green fluorescent light-emitting layer 34G and the red light-emitting layer 34R, no energy moves to the red light-emitting layer 34R.

As such, in the subpixel 3G1, the holes and electrons injected into the organic EL layer 22 from the first electrode 21 and the second electrode 23 recombine and generate excitons in the blue fluorescent light-emitting layer 34B or the green fluorescent light-emitting layer 34G.

As described above, in the present embodiment, a hole transporting material is used for the material of at least one of the material in the blue fluorescent light-emitting layer 34B having the highest content percentage and the material in the green fluorescent light-emitting layer 34G having the highest content percentage. Whether excitons are generated in the blue fluorescent light-emitting layer 34B or in the green fluorescent light-emitting layer 34G is determined by the relationship between the carrier mobility of the material in the blue fluorescent light-emitting layer 34B having the highest content percentage and the carrier mobility of the material in the green fluorescent light-emitting layer 34G having the highest content percentage, as well as the layering order of the blue fluorescent light-emitting layer 34B and the green fluorescent light-emitting layer 34G.

As one example, FIG. 1 illustrates a case where the blue fluorescent light-emitting layer 34B is located further on the cathode electrode side (the second electrode 23 side) than the green fluorescent light-emitting layer 34G, both the material in the blue fluorescent light-emitting layer 34B having the highest content percentage and the material in the green fluorescent light-emitting layer 34G having the highest content percentage are hole transporting material, and excitons are generated in the blue fluorescent light-emitting layer 34B.

When the S₁ level of the blue fluorescent light-emitting layer 34B is higher than the S₁ level of the green fluorescent light-emitting layer 34G and excitons are generated in the blue fluorescent light-emitting layer 34B, the excitons generated in the blue fluorescent light-emitting layer 34B transfer energy from the blue fluorescent light-emitting layer 34B to the green fluorescent light-emitting layer 34G through Förster transfer between the S₁ levels. However, energy transfer to the red light-emitting layer 34R from the blue fluorescent light-emitting layer 34B and the green fluorescent light-emitting layer 34G is inhibited by the separation layer 35, as described above. Accordingly, in the subpixel 3G1, the green fluorescent light-emitting layer 34G emits light at substantially 100% (green light emission). Accordingly, in the present embodiment, color mixing is suppressed in the subpixel 3G1 despite a plurality of light-emitting layers 34 being layered.

Additionally, according to the present embodiment, when forming the blue fluorescent light-emitting layer 34B in common for the subpixel 3B and the subpixel 3G1 through linear deposition (described later), even if the blue fluorescent light-emitting layer 34B has infiltrated into the subpixel 3G2 and the blue fluorescent light-emitting layer 34B has been formed on the green fluorescent light-emitting layer 34G, energy is transferred from the blue fluorescent luminescent material to the green fluorescent luminescent material as described above, and thus blue color mixing will not arise in the subpixel 3G2. “Linear deposition” refers to deposition in a linear shape rather than in dot shapes.

Additionally, according to the present embodiment, when forming the red light-emitting layer 34R in common for the subpixel 3G1 and the subpixel 3R through linear deposition (described later), even if the red light-emitting layer 34R has infiltrated into the subpixel 3B and the red light-emitting layer 34R has been formed under (i.e., on the first electrode 21 side of) the blue fluorescent light-emitting layer 34B, electrons will not reach the red light-emitting layer 34R, and red color mixing will therefore not arise in the subpixel 3B, as long as the material in the blue fluorescent light-emitting layer 34B having the highest content percentage is a hole transporting material.

Likewise, when forming the red light-emitting layer 34R in common for the subpixel 3G1 and the subpixel 3R through linear deposition (described later), even if the red light-emitting layer 34R has infiltrated into the subpixel 3G2 and the red light-emitting layer 34R has been formed under the green fluorescent light-emitting layer 34G, electrons will not reach the red light-emitting layer 34R, and red color mixing will therefore not arise in the subpixel 3G2, as long as the material in the green fluorescent light-emitting layer 34G having the highest content percentage is a hole transporting material.

Thus, according to the present embodiment, using a hole transporting material for both the material in the blue fluorescent light-emitting layer 34B having the highest content percentage and the material in the green fluorescent light-emitting layer 34G having the highest content percentage makes it possible to achieve a configuration in which color mixing does not easily arise even if even a minute amount of the red luminescent material infiltrates into another subpixel 3 (i.e., at least one of the subpixel 3B and the subpixel 3G2) when depositing the red light-emitting layer 34R.

In this manner, according to the present embodiment, the number of conditions under which color mixing arises can be reduced by controlling the mobilities of the light-emitting layers 34 and through the Förster transfer effect.

### Manufacturing Method for Organic EL Display Device 1

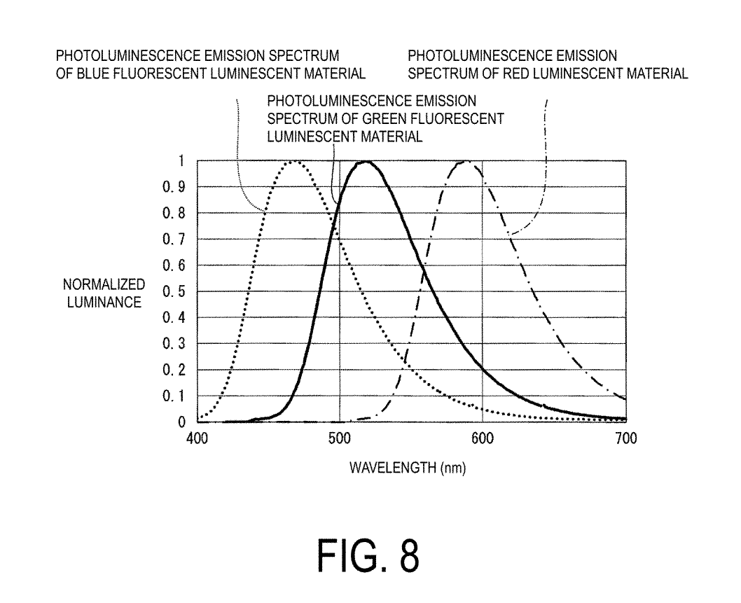

A manufacturing method for the organic EL display device 1 according to the present embodiment will be described next with reference to FIGS. 8 to 11.

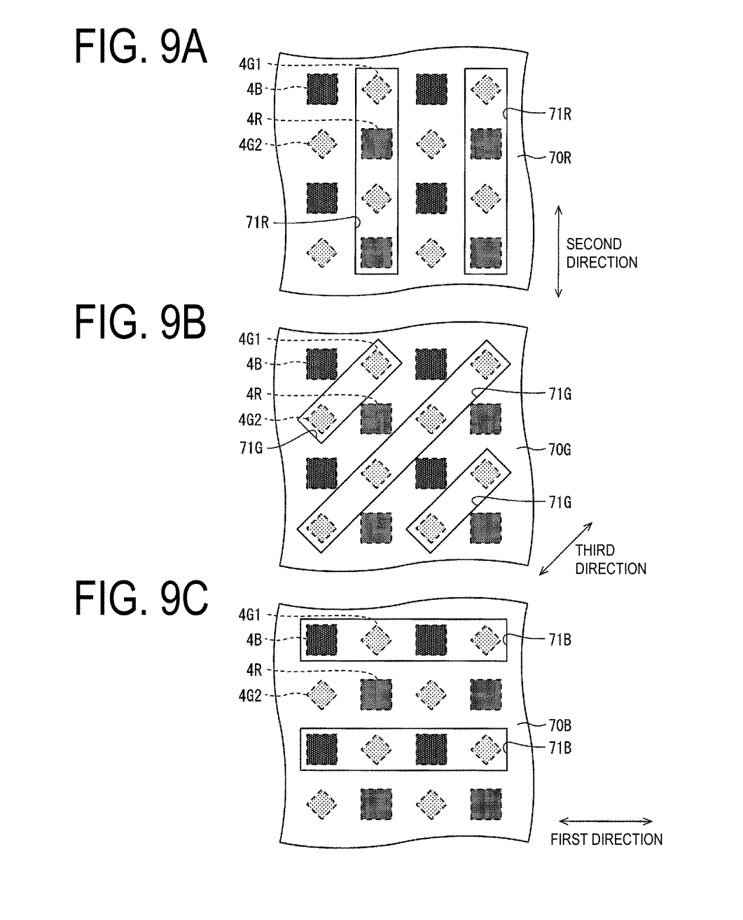

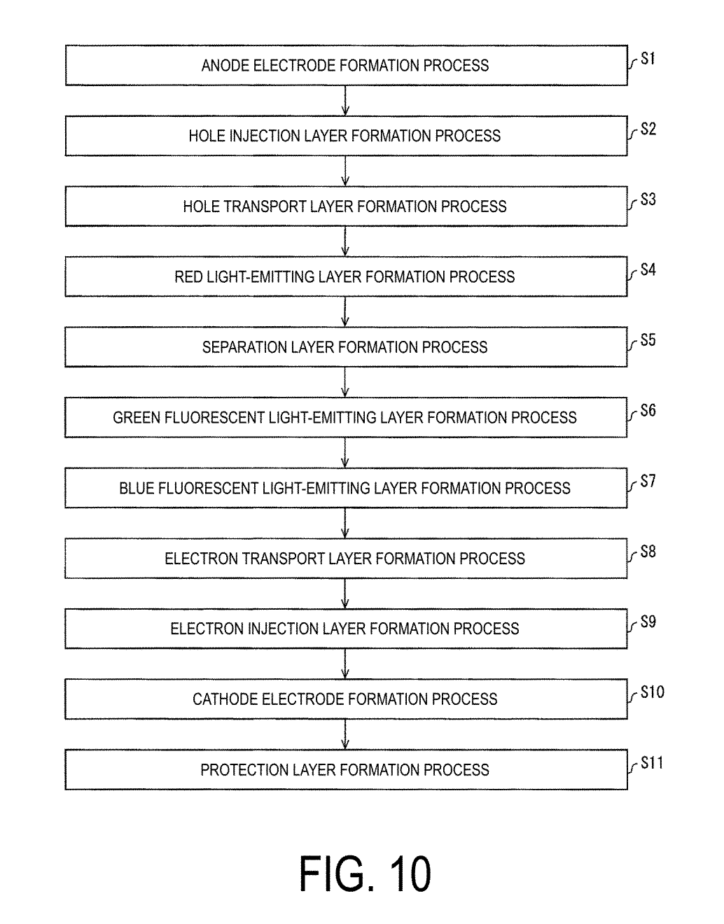

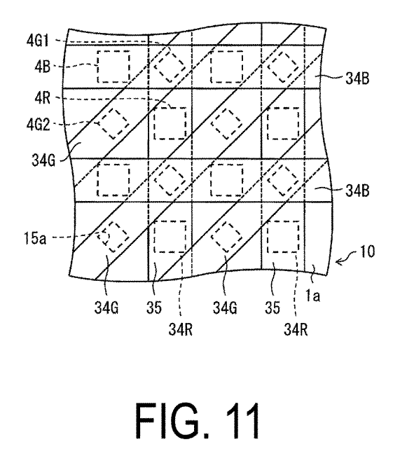

FIGS. 9A to 9C are plan views illustrating processes for producing the light-emitting layer unit 33 in the organic EL display device 1 according to the present embodiment, in the order of those processes. FIG. 10 is a flowchart illustrating the flow of processes for producing main portions of the organic EL display device 1 according to the present embodiment. FIG. 11 is a plan view illustrating the layered state of each color of light-emitting layer 34 and the separation layer 35 in the organic EL display device 1 according to the present embodiment. Note that FIG. 11 illustrates the light-emitting layer 34R and the separation layer 35 as overlapping such that the separation layer 35 serves as the upper layer and the light-emitting layer 34R serves as the lower layer.

Note that in FIGS. 9A to 9C, the same hatching as that indicated in FIG. 3 has been added to the light emitting regions 4 for the purpose of identifying the light emitting region 4B, the light emitting region 4G1, the light emitting region 4G2, and the light emitting region 4R. The actual deposition is carried out through openings 71B, 71R, and 71G (mask openings) in vapor deposition masks 70B, 70R, and 70G, respectively. The light emitting region 4B, the light emitting region 4G1, the light emitting region 4G2, and the light emitting region 4R are positioned within the subpixel 3B, the subpixel 3G1, the subpixel 3G2, and the subpixel 3R, respectively, in that order.

FIG. 11 illustrates only the light-emitting layers 34B, 34R, and 34G, and the openings 15a in the banks 15 corresponding to the light emitting regions 4B, 4G1, 4G2, and 4R, in a display region 1a of the TFT substrate 10, for the sake of simplicity.

The vapor deposition masks 70B, 70R, and 70G will collectively be referred to simply as “vapor deposition masks 70” hereinafter when there is no need to distinguish between the vapor deposition masks 70B, 70R, and 70G. Likewise, the openings 71B, 71R, and 71G will collectively be referred to simply as “openings 71” hereinafter when there is no need to distinguish between the openings 71B, 71R, and 71G.

It is desirable that a slitted mask having slit-shaped openings 71 be used as the vapor deposition masks 70 for depositing the function layers of the light-emitting layer unit 33, and particularly when depositing the light-emitting layers 34. In the present embodiment, a slitted mask is used for each of the vapor deposition masks 70B, 70R, and 70G.

The processes of manufacturing the organic EL display device 1 according to the present embodiment include a TFT substrate preparation process of preparing the above-described TFT substrate 10, an organic EL element preparation process of forming the organic EL elements 20 on the TFT substrate 10, and a sealing process of sealing the organic EL elements 20 prepared in the organic EL element preparation process.

As illustrated in FIG. 10, the organic EL element preparation process includes, for example, an anode electrode formation process (S1), a hole injection layer formation process (S2), a hole transport layer formation process (S3), a red light-emitting layer formation process (S4), a separation layer formation process (S5), a green fluorescent light-emitting layer formation process (S6), a blue fluorescent light-emitting layer formation process (S7), an electron transport layer formation process (S8), an electron injection layer formation process (S9), a cathode electrode formation process (S10), and a protection layer formation process (S11). The organic EL element preparation process is carried out in this order, for example, in the present embodiment. Note that the signs in the parentheses indicate step numbers.

Each of the processes indicated above will be described next.

First, in the TFT substrate preparation process, a photosensitive resin is applied, using a known technique, to the insulating substrate 11 in which the TFTs 12, the wiring lines 14, and the like are formed, and is then patterned through a photolithography technique to form the interlayer insulating film 13 on the insulating substrate 11.

An acrylic resin, a polyimide resin, or the like can be used as the interlayer insulating film 13, for example. As long as steps produced by the TFTs 12 can be compensated for, the film thickness of the interlayer insulating film 13 is not particularly limited.

Next, the contact hole 13a for electrically connecting the first electrode 21, serving as the anode electrode, to the TFT 12, is formed in the interlayer insulating film 13. The TFT substrate 10 is prepared as a result.

Next, the organic EL elements 20 are formed on the TFT substrate 10 formed in this manner (the organic EL element preparation process).

In the organic EL element preparation process, first, the first electrode 21 is formed on the TFT substrate 10 as the anode electrode (S1).

The anode electrode formation process (S1) according to the present embodiment includes a reflective electrode formation process of forming the reflective electrode 21a on the TFT substrate 10, and a light-transmissive electrode formation process of forming the light-transmissive electrode 21b on the reflective electrode 21a.

Accordingly, in the anode electrode formation process (S1), first, a reflective electrode material is patterned and formed at a prescribed thickness on the TFT substrate 10 as the reflective electrode 21a of the first electrode 21.

The reflective electrode 21a may, for example, be patterned by forming a reflective electrode material as a film through sputtering or the like, using photolithography to form a resist pattern (not illustrated) for each subpixel 3, etching the layer constituted by the reflective electrode material using the resist patterns as a mask, and then separating the resist pattern on a subpixel 3-by-subpixel 3 basis through peeling and cleaning. Alternatively, a pattern film may be formed through a printing method, vapor deposition using a vapor deposition mask, or the like. For example, vacuum vapor deposition, chemical vapor deposition (CVD), plasma CVD, or the like can be used as the vapor deposition method.

Next, a light-transmissive electrode material is patterned and formed at a prescribed thickness on the reflective electrode 21a as the light-transmissive electrode 21b of the first electrode 21.

It is desirable that the distance between the reflective electrode 21a and the second electrode 23 serving as the cathode electrode be set to a distance that strengthens the intensity of the peak wavelengths of light in the wavelength ranges of the colors of light emitted from the respective subpixels 3.

FIG. 8 is a graph illustrating an example of the PL emission spectrum of the blue fluorescent luminescent material, the PL emission spectrum of the green fluorescent luminescent material, and the PL emission spectrum of the red luminescent material.

Note that FIG. 8 indicates the PL emission spectrum of TBPe, used in Example 1 defining dimensions, materials, and the mixing ratio of materials (described later), as the PL emission spectrum of the blue fluorescent luminescent material; the PL emission spectrum of coumarin 6, used in Example 1 defining dimensions, materials, and the mixing ratio of materials (described later), as the PL emission spectrum of the green fluorescent luminescent material; and the PL emission spectrum of Ir(piq)3, used in Example 1 defining dimensions, materials, and the mixing ratio of materials (described later), as the PL emission spectrum of the red luminescent material.

As illustrated in FIG. 8, the peak wavelength of the blue fluorescent luminescent material (a first peak wavelength) is approximately 470 nm, the peak wavelength of the green fluorescent luminescent material (a second peak wavelength) is approximately 520 nm, and the peak wavelength of the red luminescent material (a third peak wavelength) is approximately 590 nm.

The organic EL elements 20 according to the present embodiment are microcavity-type organic EL elements. In a microcavity-type organic EL element, emitted light is reflected in multiple between the anode electrode and the cathode electrode and resonated to produce a steep emission spectrum, and the light emission intensity at a specific wavelength is amplified.

A method of varying lengths between two resonance surfaces of organic EL elements (cavity lengths) on a luminescent color-by-luminescent color basis, i.e., varying the optical path length, is known as an example of a method for introducing such a resonance structure (microcavity structure) into organic EL elements.

In the present embodiment, the cavity length is varied on a subpixel 3-by-subpixel 3 basis by setting the thickness of the light-transmissive electrode 21b on a subpixel 3-by-subpixel 3 basis, and the microcavity effect is used to improve the light emission color, the light emission efficiency, and the like.

Accordingly, some of the light emitted from the luminescent materials in each subpixel 3 according to the present embodiment is emitted directly to the exterior, and the remaining light is reflected in multiple and then emitted to the exterior. In other words, the light emitted to the exterior from each subpixel 3 includes: light that is emitted from the luminescent material, and is emitted as-is to the exterior through the light-transmissive electrode (the second electrode 23, in the present embodiment) provided on the side opposite from the side on which the reflective electrode is provided, with the organic EL layer 22 interposed therebetween; and light that is emitted from the luminescent material, is reflected in multiple between the anode electrode and the cathode electrode (and more specifically, between the reflective electrode and the light-transmissive electrode, which in the present embodiment is between the reflective electrode 21a of the first electrode 21 and the second electrode 23), and is then emitted to the exterior through the light-transmissive electrode (the second electrode 23, in the present embodiment) provided on the side opposite from the side on which the reflective electrode is provided.

As such, in the subpixel 3B, the light emitted from the blue fluorescent light-emitting layer 34B is emitted to the exterior, and the light emitted to the exterior at this time includes light obtained by the light emitted from the blue fluorescent light-emitting layer 34B (i.e., light emitted from the blue fluorescent luminescent material) being reflected in multiple between the anode electrode and the cathode electrode in the subpixel 3B. Likewise, in the subpixel 3G1 and the subpixel 3G2, the light emitted from the green fluorescent light-emitting layer 34G is emitted to the exterior; the light emitted to the exterior from the subpixel 3G1 includes light obtained by the light emitted from the green fluorescent light-emitting layer 34G (i.e., light emitted from the green fluorescent luminescent material) being reflected in multiple between the anode electrode and the cathode electrode in the subpixel 3G1, and the light emitted to the exterior from the subpixel 3G2 includes light obtained by the light emitted from the green fluorescent light-emitting layer 34G being reflected in multiple between the anode electrode and the cathode electrode in the subpixel 3G2. Additionally, in the subpixel 3R, the light emitted from the red light-emitting layer 34R is emitted to the exterior, and the light emitted to the exterior at this time includes light obtained by the light emitted from the red light-emitting layer 34R (i.e., light emitted from the red luminescent material) being reflected in multiple between the anode electrode and the cathode electrode in the subpixel 3R.

In the subpixel 3B, the thickness of the light-transmissive electrode 21b is set such that the distance between the reflective electrode 21a and the second electrode 23 is an optimal thickness for emitting light in a blue wavelength range to the exterior (a distance that strengthens the intensity of the peak wavelength of the blue fluorescent luminescent material). Likewise, in the subpixel 3G1 and the subpixel 3G2, the thickness of the light-transmissive electrode 21b is set such that the distance between the reflective electrode 21a and the second electrode 23 is an optimal thickness for emitting light in a green wavelength range to the exterior (a distance that strengthens the intensity of the peak wavelength of the green fluorescent luminescent material); and in the subpixel 3R, the thickness of the light-transmissive electrode 21b is set such that the distance between the reflective electrode 21a and the second electrode 23 is an optimal thickness for emitting light in a red wavelength range to the exterior (a distance that strengthens the intensity of the peak wavelength of the red luminescent material).

The method for changing the thickness of the light-transmissive electrode 21b in each subpixel 3 is not particularly limited. The light-transmissive electrode material may be formed at a desired thickness for each subpixel 3 through vapor deposition, a printing method, or the like; or the light-transmissive electrode material may be formed through sputtering and patterned through photolithography, after which the thickness of each layer constituted by the light-transmissive electrode material is adjusted to the desired thickness through ashing or the like.

As a result, the first electrodes 21, which have a different thickness for each of the subpixels 3, are formed in a matrix on the TFT substrate 10.

Next, the banks 15 are patterned and formed so as to cover the end portions of the first electrodes 21, in the same manner as the interlayer insulating film 13. Through this process, the first electrodes 21 are formed as the anode electrodes, so as to be separated by the bank 15 in each subpixel 3.

The TFT substrate 10 that has gone through the processes described above is then subjected to low-pressure baking to remove moisture, and an oxygen plasma process to clean the surfaces of the first electrodes 21.

Next, the material of the hole injection layer 31 and the material of the hole transport layer 32 are vapor-deposited, in that order, on the entirety of the display region 1a (see FIG. 11) of the TFT substrate 10 on which the first electrodes 21 are formed, as carried out in the past (S2, S3).

Next, the red light-emitting layer 34R is formed on the hole transport layer 32 (S4).

In the red light-emitting layer formation process (S4), the material of the red light-emitting layer 34R is linearly-deposited in the direction connecting the light emitting region 4B and the light emitting region 4G1 adjacent in the column direction (i.e., the direction connecting the subpixel 3G1 and the subpixel 3R) using, as the vapor deposition mask 70R for forming the red light-emitting layer, a slitted mask having the slit-shaped openings 71R in which the openings are longer in the above-described second direction, which is provided spanning a plurality of the pixels 2 so as to connect the subpixel 3G1 and the subpixel 3R adjacent in the column direction (the second direction) (i.e., directly adjacent); as a result, the red light-emitting layer 34R is formed in the light emitting region 4G1 and the light emitting region 4R indicated by the broken lines in FIG. 9A.

In the present embodiment, the following descriptions of the method of manufacturing the organic EL display device 1 can be given with equivalent meaning by replacing “light emitting regions 4”, “light emitting region 4B”, “light emitting region 4G1”, “light emitting region 4G2”, and “light emitting region 4R” with “subpixels 3”, “subpixel 3B”, “subpixel 3G1”, “subpixel 3G2”, and “subpixel 3R”, respectively.

Assuming, for example, that the light emitting region 4G1 and the light emitting region 4R provided in the same pixel 2 constitute a single set, the openings 71R are formed corresponding to a plurality of sets of the light emitting regions 4 connected in the column direction, so as to connect, in an alternating manner, the light emitting regions 4G1 and the light emitting regions 4R within the same pixel 2 and in the pixel 2 adjacent thereto in the column direction.

The number of pixels 2 is not illustrated in FIGS. 9A to 9C and 11 for the sake of simplicity. Accordingly, the example in FIG. 9A illustrates a case where a plurality of the openings 71R are formed spanning the light emitting regions 4G1 and the light emitting regions 4R corresponding to two pixels arranged in the column direction (i.e., the light emitting regions 4G1 and the light emitting regions 4R corresponding to four subpixels).

However, each of the openings 71R may be formed corresponding to the light emitting regions 4G1 and the light emitting regions 4R in three or more pixels 2 arranged consecutively in the column direction, and may, for example, be formed continuously from one end of the display region 1a of the TFT substrate 10 to the other end of the display region 1a with respect to the column direction.

Accordingly, the openings 71R may be formed as intermittent stripes along the column direction so as to correspond to the light emitting regions 4G1 and the light emitting regions 4R in a plurality of pixels 2 arranged in the column direction, or may be formed as continuous stripes from one end to the other end of the display region 1a with respect to the column direction.

In either case, in the red light-emitting layer formation process (S4), the red light-emitting layer 34R is formed having the same pattern as the openings 71R in the vapor deposition mask 70R when viewed in a plan view (i.e., when viewed from a direction perpendicular to the mask surface of the vapor deposition mask 70). As a result, in the present embodiment, a line-shaped red light-emitting layer 34R spanning a plurality of pixels along the column direction is formed in subpixel columns of even-numbered columns that constitute the subpixel 3G1 and the subpixel 3R, as illustrated in FIG. 11.

Next, the material of the separation layer 35 is linearly-deposited in a direction connecting the light emitting region 4G1 and the light emitting region 4R, using the vapor deposition mask 70R for forming the red light-emitting layer, on the red light-emitting layer 34R. As a result, the separation layer 35 having the same pattern as the red light-emitting layer 34R when viewed in a plan view is layered upon the red light-emitting layer 34R, as illustrated in FIG. 11 (S5).

Note that in the present embodiment, the red light-emitting layer 34R and the separation layer 35 have the same pattern when viewed in a plan view, and thus an example in which the red light-emitting layer 34R and the separation layer 35 are formed consecutively using the same vapor deposition mask 70R has been described as an example. However, the present embodiment is not limited thereto. The red light-emitting layer 34R and the separation layer 35 may be patterned and formed using separate dedicated vapor deposition masks having the same opening pattern.

Next, the green fluorescent light-emitting layer 34G is formed on the hole transport layer 32 so as to intersect (specifically, intersect at an oblique angle of 45 degrees) with the separation layer 35 (S6).

In the green fluorescent light-emitting layer formation process (S6), the material of the green fluorescent light-emitting layer 34G is linearly-deposited in the direction connecting the light emitting region 4G1 and the light emitting region 4G2 adjacent in the oblique direction using, as the vapor deposition mask 70G for forming the green fluorescent light-emitting layer, a slitted mask having the slit-shaped openings 71G in which the openings are longer in the above-described third direction, which is provided spanning a plurality of the pixels 2 so as to connect the light emitting region 4G1 and the light emitting region 4G2 adjacent in the oblique direction (the third direction) (i.e., directly adjacent); as a result, the green fluorescent light-emitting layer 34G is formed in the light emitting region 4G1 and the light emitting region 4G2 indicated by the broken lines in FIG. 9B.

The openings 71G are formed corresponding to the light emitting regions 4G1 and the light emitting regions 4G2 in a plurality of the pixels 2 arranged in the oblique direction so that the light emitting regions 4G1 and the light emitting regions 4G2 adjacent in the oblique direction at least within the same pixel 2 are connected, and so that some of the openings 71G connect the light emitting regions 4G1 and the light emitting regions 4G2 in the pixels 2 adjacent in the oblique direction in an alternating manner.

As described above, the number of pixels 2 is not illustrated in FIGS. 9A to 9C and 11 for the sake of simplicity. Accordingly, the example in FIG. 9C illustrates a case where the opening 71G is formed spanning the light emitting regions 4G2 and the light emitting regions 4G1 corresponding to two subpixels arranged in the oblique direction within the same pixel 2, on either side of the opening 71G spanning the light emitting regions 4G1 and the light emitting regions 4G2 corresponding to two pixels arranged in the oblique direction (i.e., the light emitting regions 4G1 and the light emitting regions 4G2 corresponding to four subpixels), so as to connect the light emitting regions 4G1 and the light emitting regions 4G2 arranged in the oblique direction within 2×2 pixels 2 adjacent in the up, down, left, and right directions (i.e., the row direction and the column direction) (to rephrase, 4×4 subpixels 3).

However, the openings 71G may, for example, include openings 71G spanning the light emitting regions 4G1 and the light emitting regions 4G2 in three or more pixels 2 arranged consecutively in the oblique direction, or may be formed continuously from one end of the display region 1a of the TFT substrate 10 to the other end of the display region 1a with respect to the oblique direction (i.e., a direction parallel to a diagonal line).

In other words, the openings 71G may be formed as continuous stripes from one end to the other end of the display region 1a in the oblique direction, and only the openings 71G arranged in parallel on both ends may be formed spanning the light emitting regions 4G1 and the light emitting regions 4G2 corresponding to two subpixels arranged in the oblique direction within the same pixel 2 so as to be located on either side of a plurality of openings 71G spanning the light emitting regions 4G1 and the light emitting regions 4G2 in a plurality of the pixels 2.

Assuming 2×2 pixels 2 adjacent in the row direction and the column direction constitute a single set, for example, a group of the openings 71G constituted by the slit-shaped openings 71G may be provided for each set so as to connect the light emitting regions 4G1 and the light emitting regions 4G2 adjacent in the oblique direction (i.e., directly adjacent) within the corresponding set. In other words, the openings 71G may be formed as intermittent stripes along the oblique direction by stripe-shaped openings 71G extending in the oblique direction being partitioned on a set-by-set basis.

However, the present embodiment is not limited thereto. The vapor deposition mask 70G may have a configuration in which four or more pixels 2, in which individual pluralities of the pixels are adjacent in the row direction and the column direction, are taken as a single set, and a group of openings 71G constituted by slit-shaped openings 71G is provided for each of the sets. For example, 2×3 or 4×4 pixels 2 in the row direction×column direction may be taken as a single set, and a slitted mask in which a group of openings 71G constituted by slit-shaped openings 71G is provided for each set may be used as the vapor deposition mask 70G. By taking four or more pixels 2, in which individual pluralities of the pixels are adjacent in the row direction and the column direction, as a single set, and providing a group of openings 71G constituted by slit-shaped openings 71G for each of the sets in this manner, the same green fluorescent light-emitting layer 34G spanning both the light emitting regions 4G1 and the light emitting regions 4G2 can be formed in common for the light emitting regions 4G1 and the light emitting regions 4G2 within the same pixel 2 without the openings 71G being partitioned within the pixel 2. In other words, the same green fluorescent light-emitting layer 34G spanning both the subpixel 3G1 and the subpixel 3G2 can be formed in common for the subpixel 3G1 and the subpixel 3G2 within the same pixel 2.

In either case, in the green fluorescent light-emitting layer formation process (S6), the green fluorescent light-emitting layer 34G is formed having the same pattern as the openings 71G in the vapor deposition mask 70G when viewed in a plan view.

Accordingly, in the present embodiment, a plurality of green fluorescent light-emitting layers 34G are formed, in line shapes following the oblique direction, on the hole transport layer 32, overlapping the separation layer 35 in the subpixel 3G1 and disposed directly on the hole transport layer 32 in the subpixel 3G2, and having the same pattern as the openings 71G when viewed in a plan view, as illustrated in FIG. 11.

Next, a stripe-shaped green fluorescent light-emitting layer 34G following the row direction is formed on the hole transport layer 32 so as to intersect with the separation layer 35 and the green fluorescent light-emitting layer 34G (specifically, so as to intersect with those layers at an oblique angle of 45 degrees) (S7).

In the blue fluorescent light-emitting layer formation process (S7), the material of the blue fluorescent light-emitting layer 34B is linearly-deposited in the direction connecting the light emitting region 4B and the light emitting region 4G1 adjacent in the row direction using, as the vapor deposition mask 70B for forming the blue fluorescent light-emitting layer, a slitted mask having the slit-shaped openings 71B in which the openings are longer in the above-described first direction, which is provided spanning a plurality of the pixels 2 so as to connect the light emitting region 4B and the light emitting region 4G1 adjacent in the row direction (the first direction) (i.e., directly adjacent); as a result, the blue fluorescent light-emitting layer 34B is formed in the light emitting region 4B and the light emitting region 4G1 indicated by the broken lines in FIG. 9C.

Assuming, for example, that the light emitting region 4B and the light emitting region 4G1 provided in the same pixel 2 constitute a single set, the openings 71B are formed corresponding to a plurality of sets of the light emitting regions 4 connected in the row direction, so as to connect, in an alternating manner, the light emitting regions 4B and the light emitting regions 4G1 within the same pixel 2 and in the pixels 2 adjacent in the row direction.

For the sake of simplicity, the example in FIG. 9C illustrates a case where a plurality of the openings 71B are formed spanning the light emitting regions 4B and the light emitting regions 4G1 (i.e., the light emitting regions 4B and the light emitting regions 4G1 corresponding to four subpixels).

However, each of the openings 71B may be formed corresponding to the light emitting regions 4B and the light emitting regions 4G1 in three or more pixels 2 arranged consecutively in the row direction, and may, for example, be formed continuously from one end of the display region 1a of the TFT substrate 10 to the other end of the display region 1a with respect to the row direction.

Accordingly, the openings 71B may be formed as intermittent stripes along the row direction so as to correspond to the light emitting regions 4B and the light emitting regions 4G1 in a plurality of pixels 2 arranged in the row direction, or may be formed as continuous stripes from one end to the other end of the display region 1a with respect to the row direction.

In either case, in the blue fluorescent light-emitting layer formation process (S7), the blue fluorescent light-emitting layer 34B is formed having the same pattern as the openings 71B in the vapor deposition mask 70B when viewed in a plan view. Thus in the present embodiment, the blue fluorescent light-emitting layer 34B is formed as a line spanning a plurality of pixels and following the row direction, overlapping the green fluorescent light-emitting layer 34G in the subpixel 3G1 and disposed directly on the hole transport layer 32 in the subpixel 3B, in subpixel columns of odd-numbered rows constituted by the subpixels 3B and the subpixels 3G1, as illustrated in FIG. 11.

The light-emitting layers 34 can be formed as follows, for example. First, when viewed in a plan view, each of the vapor deposition masks 70 (specifically, the vapor deposition masks 70R, 70G, and 70B, for example), which are substantially the same size as the TFT substrate 10, are aligned with respect to the TFT substrate 10 and then affixed to the TFT substrate 10 in contact with the TFT substrate 10. Then, while rotating the TFT substrate 10 and the vapor deposition masks 70 together, vapor deposition particles dispersed from a vapor deposition source (not illustrated) are vapor-deposited uniformly across the entire surface of the display region 1a through the openings 71 in the vapor deposition masks 70.

Alternatively, the light-emitting layers 34 may be formed as follows. First, the vapor deposition masks 70 are aligned with respect to the TFT substrate 10 and then affixed to the TFT substrate 10 in contact with the TFT substrate 10. Then, vapor deposition particles dispersed from a vapor deposition source are vapor-deposited uniformly across the entire surface of the display region 1a through the openings 71 in the vapor deposition masks 70 by moving the TFT substrate 10 and vapor deposition masks 70, the vapor deposition source, or both relative to each other.

Additionally, the light-emitting layers 34 may be formed by using vapor deposition masks smaller than the TFT substrate 10 as the vapor deposition masks 70 and carrying out stepwise deposition, in which the vapor deposition masks 70 are moved in order relative to the TFT substrate 10 and brought into contact with the TFT substrate 10 each time.

Note that metal masks formed from a metal or composite masks containing metal can be used as the vapor deposition masks 70, for example. When using such masks as the vapor deposition masks 70, disposing a magnet such as a magnet plate or a magnetism generating source such as an electromagnet on the side of the vapor deposition mask 70 opposite from the side where the TFT substrate 10 is located and then attaching and holding the vapor deposition mask 70 through magnetic force makes it possible to fix the vapor deposition masks 70 to the TFT substrate 10 in contact with the TFT substrate 10 when forming the light-emitting layers 34. However, the present embodiment is not limited thereto, and it goes without saying that resin-based vapor deposition masks may be used as the vapor deposition masks 70.

Then, the material of the electron transport layer 36 and the material of the electron injection layer 37 are vapor-deposited, in that order, on the entirety of the display region 1a of the TFT substrate 10 on which the above-described colors of light-emitting layers 34 are formed, as carried out in the past (S8, S9).

Next, the second electrode 23 is formed as the cathode electrode on the entirety of the display region 1a in the TFT substrate 10, so as to cover the electron injection layer 37 (S10).

Vapor deposition such as vacuum vapor deposition, CVD, and plasma CVD, sputtering, a printing method, or the like may be used to form the second electrode 23.

Then, the material of the protection layer 24 is vapor-deposited on the entirety of the display region in the TFT substrate 10, so as to cover the second electrode 23 (S11). The organic EL elements 20 are formed on the TFT substrate 10 as a result.

The TFT substrate 10 on which the organic EL elements 20 are formed and the sealing substrate 40 are then affixed to each other by a filler layer and a sealing member (not illustrated), as illustrated in FIG. 4, by carrying out the sealing process. The organic EL display device 1 according to the present embodiment is obtained in this manner.

However, the method of sealing the organic EL elements 20 is not limited to the method described above, and various known sealing methods can be employed instead.

In the present embodiment, the reflective electrode 21a, the light-transmissive electrode 21b, the hole injection layer 31, the hole transport layer 32, the red light-emitting layer 34R, the separation layer 35, the green fluorescent light-emitting layer 34G, the blue fluorescent light-emitting layer 34B, the electron transport layer 36, the electron injection layer 37, the second electrode 23, and the protection layer 24 are layered on the TFT substrate 10, in that order from the TFT substrate 10 side, on the basis of the flowchart illustrated in FIG. 10, as Example 1 defining dimensions, materials, and the mixing ratio of materials.

Materials for the layers layered on the TFT substrate 10 and thicknesses thereof in Example 1 defining dimensions, materials, and the mixing ratio of materials are as follows. However, the dimensions and materials denoted below are merely examples, and the present embodiment is not intended to be limited to these specific dimensions and materials. The following assumes that the thickness of the light-transmissive electrode 21b has been optically optimized through optical simulations to align the luminescent color of the subpixel 3G1 and the luminescent color of the subpixel 3G2.

### Example 1: Defining Dimensions, Materials, and Mixing Ratio of Materials

Reflective electrode 21a (first electrode 21; anode electrode): Ag (100 nm)

Light-transmissive electrode 21b (first electrode 21, anode electrode): ITO (subpixel 3B: 135 nm/subpixel 3G1: 135 nm/subpixel 3G2: 165 nm/subpixel 3R: 40 nm)

Hole injection layer 31: HAT-CN (10 nm)

Hole transport layer 32: TCTA (20 nm)

Red light-emitting layer 34R: CBP (host material 90%)/Ir(piq)3 (red luminescent material, 10%) (10 nm)

Separation layer 35: CBP (20 nm)

Green fluorescent light-emitting layer 34G: TPD (host material, 90%)/coumarin 6 (green fluorescent luminescent material, 10%) (10 nm)

Blue fluorescent light-emitting layer 34B: ADN (host material, 90%)/TBPe (blue fluorescent luminescent material, 10%) (10 nm)

Electron transport layer 36: BCP (30 nm)

Electron injection layer 37: LiF (1 nm)

Second electrode 23 (cathode electrode, semitransparent electrode): Ag—Mg alloy (Ag/Mg mixing ratio=0.9/0.1) (20 nm)

Protection layer 24: ITO (80 nm)

As described above, in the present embodiment, the blue fluorescent light-emitting layer 34B, the green fluorescent light-emitting layer 34G, and the red light-emitting layer 34R are common light-emitting layers that are each common to two of the subpixels 3 in each pixel 2. By using common light-emitting layers, light emission is achieved using the Förster-type energy transfer of the fluorescent luminescent material and the transferable distance thereof, while improving the productivity.

As described above, according to the present embodiment, the blue fluorescent light-emitting layer 34B, the green fluorescent light-emitting layer 34G, and the red light-emitting layer 34R are layered in the subpixel 3G1; however, while Förster-type energy transfer occurs from the blue fluorescent light-emitting layer 34B to the green fluorescent light-emitting layer 34G, no Förster-type energy transfer occurs from the blue fluorescent light-emitting layer 34B and the green fluorescent light-emitting layer 34G to the red light-emitting layer 34R, and thus only the green fluorescent luminescent material emits light.

In other words, the green fluorescent luminescent material, which is the luminescent material of the green fluorescent light-emitting layer 34G, has a lower S₁ level than the blue fluorescent luminescent material, which is the luminescent material of the blue fluorescent light-emitting layer 34B, and the opposing surface distance D_{BG} between the blue fluorescent light-emitting layer 34B and the green fluorescent light-emitting layer 34G is less than or equal to the Förster radius. As such, even if, for example, holes and electrons recombine in the blue fluorescent light-emitting layer 34B, the Förster transfer enables the green fluorescent luminescent material to emit light at substantially 100%. Additionally, the separation layer 35 is provided between the red light-emitting layer 34R and the green fluorescent light-emitting layer 34G, which of the blue fluorescent light-emitting layer 34B and the green fluorescent light-emitting layer 34G is located on the red light-emitting layer 34R side, and thus energy transfer from the blue fluorescent light-emitting layer 34B and the green fluorescent light-emitting layer 34G to the red light-emitting layer 34R is inhibited. Thus as described above, color mixing can be suppressed even if the RGB light-emitting layers 34 are layered in the subpixel 3G1.

In an organic EL display device having a PenTile arrangement that does not employ the above-described layered structure, linear deposition can only be carried out for subpixel columns constituted by green subpixels. To rephrase, in an organic EL display device having a PenTile arrangement lacking the above-described layered structure, a slitted mask can only be used to form the light-emitting layer of a single color.

However, according to the present embodiment, employing the above-described layered structure makes it possible, when depositing the red light-emitting layer 34R, the green fluorescent light-emitting layer 34G, and the blue fluorescent light-emitting layer 34B, to form at least some of the light-emitting layers 34 spanning a plurality of pixels 2 while using a plurality of adjacent subpixels 3 including the subpixel 3G1 as a deposition region for each light-emitting layer. In other words, the subpixel 3G1 has a layered structure including all colors of the light-emitting layers 34 provided in the subpixel 3B, the subpixel 3G1, and the subpixel 3R. Therefore, as described above, linear deposition can be carried out not only in the direction connecting the light emitting region 4G1 and the light emitting region 4G2, but also in the direction connecting the light emitting region 4G1 and the light emitting region 4R and in the direction connecting the light emitting region 4B and the light emitting region 4G1. In other words, according to the present embodiment, linear deposition can be carried out not only in the direction connecting the subpixel 3G1 and the subpixel 3G2, but also in the direction connecting the subpixel 3G1 and the subpixel 3R and in the direction connecting the subpixel 3B and the subpixel 3G1, which makes it possible to suppress color mixing in those directions as well.

That is to say, according to the present embodiment, a slitted mask can be used for any of the red light-emitting layer formation process (S4), the green fluorescent light-emitting layer formation process (S6), and the blue fluorescent light-emitting layer formation process (S7). Thus according to the present embodiment, a slitted mask can be used in the formation of a plurality of light-emitting layers 34 having different colors, the luminescent colors of which have different peak wavelengths (i.e., can be used in at least two of the processes of S4, S6, and S7), unlike in the past.

Going even further, according to the present embodiment, a slitted mask can, as described above, be used to form all of the light-emitting layers 34, unlike in the past.

Thus according to the present embodiment, linear deposition is possible for a plurality of light-emitting layers 34 having different colors, and furthermore for all of the light-emitting layers 34, which has not been possible with organic EL display devices having PenTile arrangements lacking the above-described layered structure.

Furthermore, according to the present embodiment, the light-emitting layers 34 and the separation layer 35 serving as an intermediate layer (the first intermediate layer) in all of the RGB subpixels 3, which are arranged having a PenTile arrangement, can be deposited using a slitted mask having the slit-shaped openings 71 provided spanning a plurality of the pixels 2, as described above. Thus according to the present embodiment, a slitted mask can be used to form not only the light-emitting layers 34, but also all of the layers constituting the light-emitting layer unit 33, as described above.

Using slitted masks for the vapor deposition masks 70 in this manner makes it possible to reduce non-opening patterns (e.g., metal patterns) between adjacent subpixels 3 deposited at the same time, in known vapor deposition masks for forming light-emitting layers.

The present embodiment describes, as an example, a case where a slitted mask, which has the openings 71 including slit-shaped openings 71 provided spanning a plurality of the pixels 2 (e.g., four light emitting regions 4), is used to form all of the layers constituting the light-emitting layer unit 33. However, the present embodiment is not limited thereto.

A vapor deposition mask 70 in which the openings 71 are provided for two subpixels, corresponding to the subpixel 3B and the subpixel 3G1 in each of the pixels 2, for example, may be used as the vapor deposition mask 70. non-opening patterns between adjacent subpixels 3 within each of the pixels 2 can be eliminated when forming the light-emitting layers 34 for each of the pixels 2 in this manner. Thus in this case as well, non-opening patterns between adjacent subpixels 3 deposited at the same time can be reduced in known vapor deposition masks for forming light-emitting layers.

Of course, when forming some of the light-emitting layers 34 among the blue fluorescent light-emitting layer 34B, the red light-emitting layer 34R, and the green fluorescent light-emitting layer 34G, a normal vapor deposition mask having an opening pattern in which individual openings 71 are provided for each subpixel may be used as the vapor deposition mask 70.

For example, of the function layers constituting the light-emitting layer unit 33, the green fluorescent light-emitting layer 34G may be deposited using the above-described normal vapor deposition mask, and the other function layers may be formed using the above-described slitted mask. This makes it possible to linearly-deposit the blue fluorescent light-emitting layer 34B and linearly-deposit the red light-emitting layer 34R, which cannot be carried out in an organic EL display device having a PenTile arrangement that lacks the above-described layered structure.

However, using slitted masks having slit-shaped openings 71 provided spanning a plurality of pixels 2 as the vapor deposition masks 70 is advantageous, compared to a case where the light-emitting layers 34 are formed for each of the pixels 2 as described above, in that non-opening patterns in the vapor deposition masks between adjacent pixels 2 can be eliminated.

According to the present embodiment, shadow dependent on the thicknesses of the above-described non-opening pattern between adjacent subpixels 3 and the non-opening pattern between adjacent pixels 2 can be eliminated, and variations in film thickness within subpixels 3 can be reduced.

Additionally, according to the present embodiment, the deposition margin for preventing color mixing can be reduced; additionally, when forming the light-emitting layers 34, the resolution can be improved by reducing the pitch of the subpixels 3 adjacent within each of the openings 71, and the surface area of the subpixels 3 can be broadened and current stress reduced while providing the same resolution, which makes it possible to lengthen the lifespan of the organic EL elements 20.

Thus according to the present embodiment, the blue fluorescent light-emitting layer 34B, the green fluorescent light-emitting layer 34G, and the red light-emitting layer 34R can be linearly deposited, and color mixing does not arise easily despite a plurality of the light-emitting layers 34 being layered in the subpixel 3G1 as described above. Accordingly, the deposition margin for preventing color mixing can be reduced more than in display devices using known separate-patterning techniques, and a higher resolution can be achieved more easily than in display devices using known separate-patterning techniques.

Additionally, the organic EL display device 1 does not require a CF layer or an optical interference effect as with the white CF technique or PTL 1, despite having the above-described layered structure for the light-emitting layers. This makes it possible to avoid a situation where more power is consumed, the light distribution properties worsen, and the like. Therefore, a high color level and low power consumption can be achieved at the same time.

Thus according to the present embodiment, it is possible to provide a display device that can reduce the deposition margin for preventing color mixing by making color mixing less likely than in display devices using the known separate-patterning technique, thereby achieving higher resolutions more easily, and that can achieve both high color levels and low power consumption.

Additionally, in the present embodiment, the light emitting regions 4G1 and 4G2 (the subpixels 3G1 and 3G2) are rotated by 45 degrees relative to the light emitting regions 4B and 4R (the subpixels 3B and 3R), for diamond shapes, as illustrated in FIGS. 3, 9A to 9C, and 11.

In the present embodiment, the green fluorescent light-emitting layer 34G is linearly-deposited in an oblique direction, as illustrated in FIG. 9B. Thus as illustrated in FIG. 9C, by carrying out linear deposition so that the respective sides of the opening 71G (the ends of the respective openings) in the vapor deposition mask 70G are parallel to the respective sides of the light emitting regions 4G1 and 4G2 that oppose the stated sides, the gaps between the light emitting regions 4 can be used to the greatest extent possible, which makes it possible to increase the density at which the subpixels 3 are provided.

### Modified Example

The present embodiment describes an example in which the display device according to the present embodiment is an organic EL display device. However, the display device according to the present embodiment may be any display device employing PL light emission. The display device according to the present embodiment is therefore not limited to the above-described examples, and may be, for example, an inorganic EL display device, a display device aside from an EL display device that employs PL light emission, or the like. Furthermore, inorganic materials may be used for the luminescent materials, and inorganic layers may be formed instead of organic layers.

The present embodiment describes forming the blue fluorescent light-emitting layer 34B as the first light-emitting layer containing the first fluorescent luminescent material, forming the green fluorescent light-emitting layer 34G as the second light-emitting layer containing the second fluorescent luminescent material, and forming the red light-emitting layer 34R as the third light-emitting layer containing the third luminescent material. However, the present embodiment is not limited thereto. The combination of the first fluorescent luminescent material, the second fluorescent luminescent material, and the third luminescent material is not limited to a combination of the blue fluorescent luminescent material, the green fluorescent luminescent material, and the red luminescent material. Any combination may be used as long as the second fluorescent luminescent material emits light having a peak wavelength (second peak wavelength) longer than the peak wavelength of the light emitted from the first fluorescent luminescent material (first peak wavelength), the third luminescent material emits light having a peak wavelength (third peak wavelength) longer than the second peak wavelength, and the S₁ level of the second fluorescent luminescent material is lower than the S1 level of the first fluorescent luminescent material and higher than the S₁ level of the third luminescent material.

### Second Embodiment

A description follows regarding another embodiment of the disclosure, primarily on the basis of FIGS. 1 to 4, 10 and 12 to 14.

The present embodiment will describe differences from the first embodiment, and constituent elements having the same functions as the constituent elements described in the first embodiment will be assigned the same reference signs, with descriptions thereof omitted. It goes without saying that the same modifications as those of the first embodiment can be applied to the present embodiment as well.

### Overall Configuration of Organic EL Display Device 1

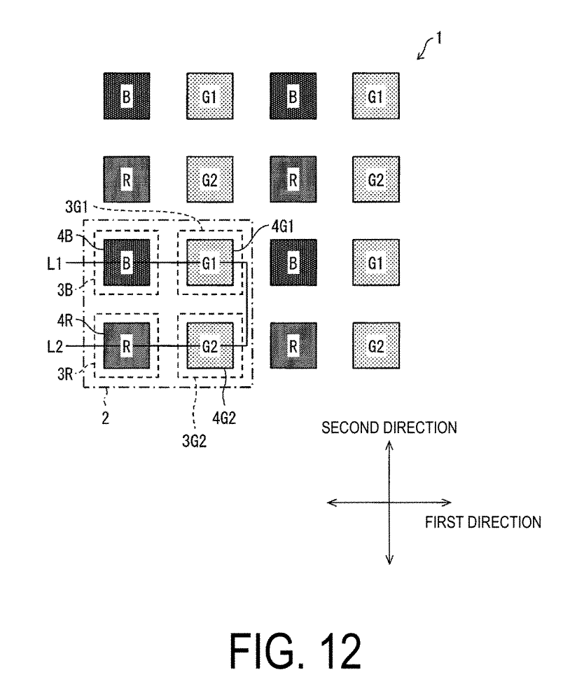

FIG. 12 is a diagram schematically illustrating a pixel arrangement in the organic EL display device 1 according to the present embodiment.

The first and second embodiments describe a case where the organic EL display device 1 has a PenTile arrangement as an example. However, as illustrated in FIG. 12, the organic EL display device 1 may have an S-Stripe pixel arrangement (an S-Stripe arrangement), in which the subpixel 3B is adjacent to the subpixel 3G1 and the subpixel 3R is adjacent to the subpixel 3G2 in the row direction (the first direction), and the subpixel 3B is adjacent to the subpixel 3R and the subpixel 3G1 is adjacent to the subpixel 3G2 in the column direction (the second direction) orthogonal to the row direction. Columns constituted by the subpixels 3B and the subpixels 3G1 and columns constituted by the subpixels 3G2 and the subpixels 3R, which are formed following the row direction, are arranged alternating in the column direction, and in the display region, the respective colors of the subpixels 3 repeat in the row direction such that the subpixel 3B and the subpixel 3G1 are arranged in an alternating manner in odd-numbered rows, and the subpixel 3R and the subpixel 3G2 are arranged in an alternating manner in even-numbered rows, for example, in the S-Stripe arrangement as well, in the same manner as in the PenTile arrangement.

These arrangements make use of the fact that human vision is less sensitive to R and B and more sensitive to G. As illustrated in FIGS. 3 and 12, in these arrangements, each row is constituted by two colors at a time, namely the subpixel 3B and the subpixel 3G1 or the subpixel 3G2 and the subpixel 3R. Also, in each row, subpixels of colors lacking as compared to RGB arrangements are reproduced in a simulated manner through combinations with subpixels in adjacent rows.

Thus in these arrangements, the dot width of the subpixels 3 in each row can be increased in the row direction by an amount corresponding to the subpixels of the colors lacking, as compared to a vertical stripe-type RGB arrangement. Accordingly, a high-resolution organic EL display device 1 can be manufactured with ease, and a resolution that appears high can be maintained, even with a lower number of pixels.

Note that in the present embodiment, the light emitting regions 4 (the subpixels 3) are all rectangular in shape, as illustrated in FIGS. 12 to 14.

Unlike an organic EL display device having a known S-Stripe arrangement, the subpixel 3G1 and the subpixel 3G2 in the organic EL display device 1 according to the present embodiment have a different layered structure, as illustrated in FIGS. 1, 2, and 4.

### Manufacturing Method for Organic EL Display Device 1

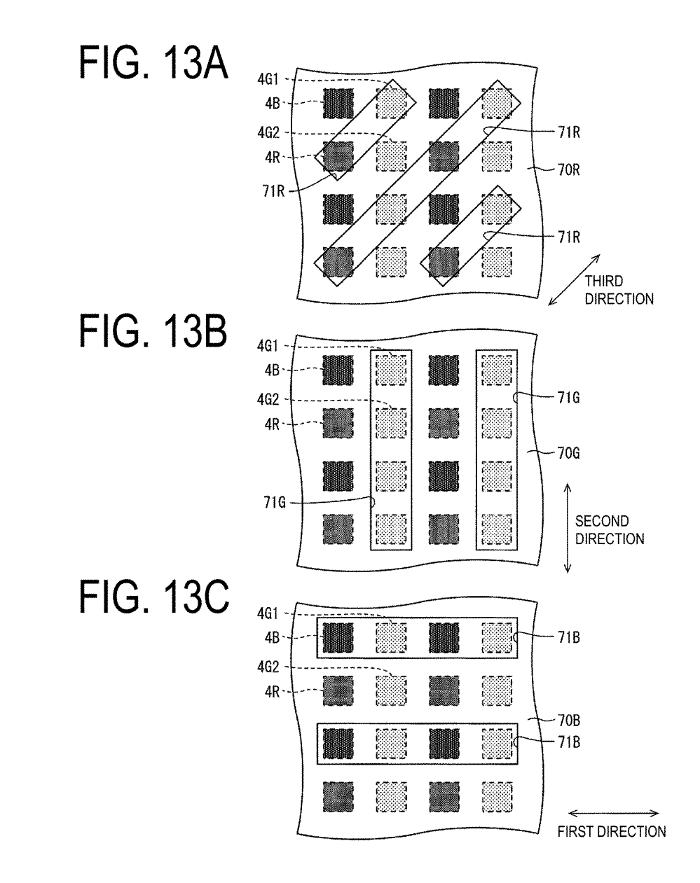

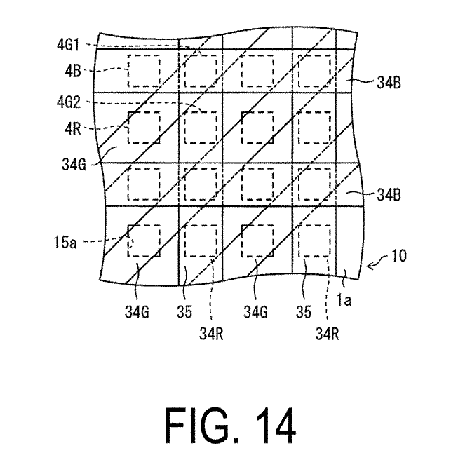

FIGS. 13A to 13C are plan views illustrating processes for producing the light-emitting layer unit 33 in the organic EL display device 1 according to the present embodiment, in the order of those processes. FIG. 14 is a plan view illustrating the layered state of each color of light-emitting layer 34 and the separation layer 35 in the organic EL display device 1 according to the present embodiment. Note that FIG. 14 illustrates the light-emitting layer 34R (indicated as “34R (34)” in FIG. 1) and the separation layer 35 as overlapping such that the separation layer 35 serves as the upper layer and the light-emitting layer 34R serves as the lower layer.

Note that in FIGS. 13A to 13C, the same hatching as that indicated in FIG. 12 has been added to the light emitting regions 4 for the purpose of identifying the light emitting region 4B, the light emitting region 4G1, the light emitting region 4G2, and the light emitting region 4R. The actual deposition is carried out through openings 71B, 71R, and 71G in vapor deposition masks 70B, 70R, and 70G, respectively. As described earlier, the light emitting region 4B, the light emitting region 4G1, the light emitting region 4G2, and the light emitting region 4R are positioned within the subpixel 3B, the subpixel 3G1, the subpixel 3G2, and the subpixel 3R, respectively, in that order.

FIG. 14 illustrates only the light-emitting layers 34B, 34R, and 34G, and the openings 15a in the banks 15 corresponding to the light emitting regions 4B, 4G1, 4G2, and 4R, in a display region 1a of the TFT substrate 10, for the sake of simplicity.

In the manufacturing method for the organic EL display device 1 according to the present embodiment, when forming the bank 15, the bank 15 is patterned and formed so that the openings 15a corresponding to the light emitting regions 4 illustrated in FIG. 14 (i.e., the light emitting regions 4B, 4G1, 4G2, and 4R) are formed; and as illustrated in FIG. 13A, in the red light-emitting layer 34R (S4) and the green fluorescent light-emitting layer formation process (S6), vapor deposition masks 70R and 70G having different opening patterns than the vapor deposition masks 70R and 70G according to Embodiment 1 are used. Aside from these points, however, the manufacturing method according to the present embodiment is the same as the manufacturing method for the organic EL display device 1 according to Embodiment 1.

In the manufacturing method for the organic EL display device 1 according to the present embodiment, vapor deposition is carried out using the vapor deposition masks 70R, 70G, and 70B illustrated in FIGS. 13A to 13C in the red light-emitting layer formation process (S4) to the blue fluorescent light-emitting layer formation process (S7) illustrated in FIG. 10.

In the red light-emitting layer formation process (S4) and the separation layer formation process (S5) according to the present embodiment, the materials of the red light-emitting layer 34R and the separation layer 35 are linearly-deposited in the direction connecting the light emitting region 4G1 and the light emitting region 4 (i.e., the direction connecting the light emitting region 4G1 and the light emitting region 4R that are directly adjacent, that is, the subpixel 3G1 and the subpixel 3R that are directly adjacent) using, as the vapor deposition mask 70R, a slitted mask having at least the slit-shaped openings 71R in which the openings are longer in the above-described third direction, which is provided spanning a plurality of the pixels 2 so as to connect the light emitting region 4G1 and the light emitting region 4R adjacent in the oblique direction (the third direction) (i.e., directly adjacent); as a result, the red light-emitting layer 34R and the separation layer 35 are formed, on the hole transport layer 32, in the light emitting region 4G1 and the light emitting region 4R indicated by the broken lines in FIG. 13A.

In the present embodiment too, the following descriptions of the method of manufacturing the organic EL display device 1 can be given with equivalent meaning by replacing “light emitting regions 4”, “light emitting region 4B”, “light emitting region 4G1”, “light emitting region 4G2”, and “light emitting region 4R” with “subpixels 3”, “subpixel 3B”, “subpixel 3G1”, “subpixel 3G2”, and “subpixel 3R”, respectively, as described above.

The openings 71R are formed corresponding to the light emitting regions 4G1 and the light emitting regions 4R in a plurality of the pixels 2 arranged in the oblique direction so that the light emitting regions 4G1 and the light emitting regions 4R adjacent in the oblique direction at least within the same pixel 2 are connected, and so that some of the openings 71R connect the light emitting regions 4G1 and the light emitting regions 4R in the pixels 2 adjacent in the oblique direction in an alternating manner.

The number of pixels 2 is not illustrated in FIGS. 13A to 13C and 14 for the sake of simplicity. Thus the example in FIG. 13A illustrates a case where the opening 71R is formed spanning the light emitting regions 4G1 and the light emitting regions 4R corresponding to two subpixels arranged in the oblique direction within the same pixel 2, on either side of the opening 71R spanning the light emitting regions 4G1 and the light emitting regions 4R corresponding to two pixels arranged in the oblique direction (i.e., the light emitting regions 4G1 and the light emitting regions 4R corresponding to four subpixels), so as to connect the light emitting regions 4G1 and the light emitting regions 4R arranged in the oblique direction within 2×2 pixels 2 adjacent in the up, down, left, and right directions (i.e., the row direction and the column direction) (to rephrase, 4×4 subpixels 3).

However, even when the red light-emitting layer 34R is deposited in the oblique direction as in the present embodiment, the openings 71R may, for example, include openings 71R spanning the light emitting regions 4G1 and the light emitting regions 4R in three or more pixels 2 arranged consecutively in the oblique direction, or may be formed continuously from one end of the display region 1a of the TFT substrate 10 to the other end of the display region 1a with respect to the oblique direction (i.e., a direction parallel to a diagonal line).

In other words, the openings 71R may be formed as continuous stripes from one end to the other end of the display region 1a in the oblique direction, and only the openings 71R arranged in parallel on both ends may be formed spanning the light emitting regions 4G1 and the light emitting regions 4R corresponding to two subpixels arranged in the oblique direction within the same pixel 2 so as to be located on either side of a plurality of openings 71R spanning the light emitting regions 4G1 and the light emitting regions 4R in a plurality of the pixels 2.

Assuming 2×2 pixels 2 adjacent in the row direction and the column direction constitute a single set, for example, a group of the openings 71R constituted by the slit-shaped openings 71R may be provided for each set so as to connect the light emitting regions 4G1 and the light emitting regions 4R adjacent in the oblique direction (i.e., directly adjacent) within the corresponding set. In other words, the openings 71R may be formed as intermittent stripes along the oblique direction by stripe-shaped openings 71R extending in the oblique direction being partitioned on a set-by-set basis.

However, the present embodiment is not limited thereto. The vapor deposition mask 70R may have a configuration in which four or more pixels 2, in which individual pluralities of the pixels are adjacent in the row direction and the column direction, are taken as a single set, and a group of openings 71R constituted by slit-shaped openings 71R is provided for each of the sets. For example, 2×3 or 4×4 pixels 2 in the row direction×column direction may be taken as a single set, and a slitted mask in which a group of openings 71R constituted by slit-shaped openings 71R is provided for each set may be used as the vapor deposition mask 70R. By taking four or more pixels 2, in which individual pluralities of the pixels are adjacent in the row direction and the column direction, as a single set, and providing a group of openings 71R constituted by slit-shaped openings 71R for each of the sets in this manner, the same red light-emitting layer 34R spanning both the light emitting regions 4G1 and the light emitting regions 4R can be formed in common for the light emitting regions 4G1 and the light emitting regions 4R within the same pixel 2 without the openings 71R being partitioned within the pixel 2.

In either case, in the red light-emitting layer formation process (S4) and the separation layer formation process (S5), the red light-emitting layer 34R and the separation layer 35 are formed having the same pattern as the openings 71R in the vapor deposition mask 70R when viewed in a plan view. Thus in the present embodiment, a plurality of line-shaped red light-emitting layers 34R following the oblique direction and having the same pattern as the openings 71R when viewed in a plan view are formed on the hole transport layer 32, and the separation layer 35 having the same pattern as the red light-emitting layers 34R when viewed in a plan view is formed on the red light-emitting layers 34R, as illustrated in FIG. 14.

However, in the present embodiment too, the red light-emitting layer 34R and the separation layer 35 may of course be patterned and formed using separate dedicated vapor deposition masks having the same opening pattern, in the same manner as in the first embodiment.

As illustrated in FIG. 13B, in the green fluorescent light-emitting layer formation process (S6), the green fluorescent light-emitting layer 34G is formed on the hole transport layer 32 having a plurality of line shapes following the column direction and spanning a plurality of pixels, so as to intersect with the separation layer 35 (specifically, so as to intersect at an oblique angle of 45 degrees) (S6).

In other words, in the green fluorescent light-emitting layer formation process (S6) in the present embodiment, the material of the green fluorescent light-emitting layer 34G is linearly-deposited in a direction connecting the light emitting regions 4G1 and the light emitting regions 4G2 adjacent in the column direction, using, as the vapor deposition mask 70G, a slitted mask having slit-shaped openings 71G, in which the openings are longer in the above-described second direction, which is provided spanning a plurality of the pixels 2 so as to connect the light emitting regions 4G1 and the light emitting regions 4G2 adjacent in the column direction (the second direction) (i.e., directly adjacent); as a result, the green fluorescent light-emitting layer 34G is formed in the light emitting regions 4G1 and the light emitting regions 4G2 indicated by the broken lines in FIG. 13B.

Assuming, for example, that the light emitting region 4G1 and the light emitting region 4G2 provided in the same pixel 2 constitute a single set, the openings 71G are formed corresponding to a plurality of sets of the light emitting regions 4 connected in the column direction, so as to connect, in an alternating manner, the light emitting regions 4G1 and the light emitting regions 4G2 within the same pixel 2 and in the pixels 2 adjacent in the column direction.

Note that as described above, the number of pixels 2 is not illustrated in FIGS. 13A to 13C and 14 for the sake of simplicity. Thus in the present embodiment too, the example in FIG. 13B illustrates a case where a plurality of the openings 71G are formed spanning the light emitting regions 4G1 and the light emitting regions 4G2 corresponding to two pixels arranged in the column direction (i.e., the light emitting regions 4G1 and the light emitting regions 4G2 corresponding to four subpixels).

However, each of the openings 71G may be formed corresponding to the light emitting regions 4G1 and the light emitting regions 4G2 in three or more pixels 2 arranged consecutively in the column direction, and may, for example, be formed continuously from one end of the display region 1a of the TFT substrate 10 to the other end of the display region 1a with respect to the row direction.

Accordingly, the openings 71G may be formed as intermittent stripes along the column direction so as to correspond to the subpixels 3G1 and the subpixels 3G2 in a plurality of pixels 2 arranged in the column direction, or may be formed as continuous stripes from one end to the other end of the display region 1a with respect to the column direction.

In either case, in the green fluorescent light-emitting layer formation process (S6), the green fluorescent light-emitting layer 34G is formed having the same pattern as the openings 71G in the vapor deposition mask 70G when viewed in a plan view.

In the present embodiment, the material of the green fluorescent light-emitting layer 34G is linearly-deposited in subpixel columns of even-numbered columns that constitute the subpixel 3G1 and the subpixel 3G2. As a result, a line-shaped green fluorescent light-emitting layer 34G spanning a plurality of pixels along the column direction is formed on the hole transport layer 32, having the same pattern as the openings 71G and overlapping with the separation layer 35 in the subpixel 3G1 when viewed in a plan view, and disposed directly on the hole transport layer 32 in the subpixel 3G2, as illustrated in FIG. 14.

As illustrated in FIG. 13C, in the blue fluorescent light-emitting layer formation process (S7), the blue fluorescent light-emitting layer 34B is formed having a line shape following the row direction and spanning a plurality of pixels, so as to be orthogonal to the separation layer 35 and intersect with the green fluorescent light-emitting layer 34G (specifically, so as to intersect at an oblique angle of 45 degrees).

That is, in the blue fluorescent light-emitting layer formation process (S7) according to the present embodiment, the material of the blue fluorescent light-emitting layer 34B is linearly-deposited in the direction connecting the light emitting region 4B and the light emitting region 4G1 adjacent in the row direction using, as the vapor deposition mask 70B in the same manner as in Embodiment 1, a slitted mask having the slit-shaped openings 71B in which the openings are longer in the above-described first direction, which is provided spanning a plurality of the pixels 2 so as to connect the light emitting region 4B and the light emitting region 4G1 adjacent in the row direction (the first direction); as a result, the blue fluorescent light-emitting layer 34B is formed in the light emitting region 4B and the light emitting region 4G1 indicated by the broken lines in FIG. 13C.

In the present embodiment too, assuming, for example, that the light emitting region 4B and the light emitting region 4G1 provided in the same pixel 2 constitute a single set, the openings 71B are formed corresponding to a plurality of sets of the light emitting regions 4 connected in the row direction, so as to connect, in an alternating manner, the light emitting regions 4B and the light emitting regions 4G1 within the same pixel 2 and in the pixels 2 adjacent in the row direction.

For the sake of simplicity, the example in FIG. 13C illustrates a case where a plurality of the openings 71B are formed spanning the light emitting regions 4B and the light emitting regions 4G1 arranged in the row direction (i.e., the light emitting regions 4B and the light emitting regions 4G1 corresponding to four subpixels), in the same manner as in Embodiment 1.

However, in the present embodiment too, the openings 71B may be formed as intermittent stripes along the row direction so as to correspond to the light emitting regions 4B and the light emitting regions 4G1 in a plurality of pixels 2 arranged in the row direction, or may be formed as continuous stripes from one end to the other end of the display region 1a with respect to the row direction.

In either case, in the blue fluorescent light-emitting layer formation process (S7), the blue fluorescent light-emitting layer 34B is formed having the same pattern as the openings 71B in the vapor deposition mask 70B when viewed in a plan view.

Like Embodiment 1, in the present embodiment, the material of the blue fluorescent light-emitting layer 34B is linearly-deposited in subpixel columns of odd-numbered rows that constitute the subpixel 3B and the subpixel 3G1. As a result, a line-shaped blue fluorescent light-emitting layer 34B spanning a plurality of pixels along the row direction is formed overlapping the green fluorescent light-emitting layer 34G in the subpixel 3G1 and disposed directly on the hole transport layer 32 in the subpixel 3B, as illustrated in FIG. 14.

According to the present embodiment, employing an S-Stripe pixel arrangement as described above makes it possible to improve the apparent resolution.

In an organic EL display device having an S-Stripe arrangement that does not employ the above-described layered structure, linear deposition can only be carried out for subpixel columns constituted by green subpixels. To rephrase, in an organic EL display device having an S-Stripe arrangement lacking the above-described layered structure, a slitted mask can only be used to form the light-emitting layer of a single color.

However, according to the present embodiment, employing the above-described layered structure makes it possible to carry out linear deposition not only in the direction connecting the light emitting region 4G1 and the light emitting region 4G2, but also in the direction connecting the light emitting region 4G1 and the light emitting region 4R and in the direction connecting the light emitting region 4B and the light emitting region 4G1, in the same manner as in Embodiment 1. This makes it possible to suppress color mixing in these directions. In other words, according to the present embodiment, linear deposition can be carried out not only in the direction connecting the subpixel 3G1 and the subpixel 3G2, but also in the direction connecting the subpixel 3G1 and the subpixel 3R and in the direction connecting the subpixel 3B and the subpixel 3G1, which makes it possible to suppress color mixing in those directions as well.

Thus according to the present embodiment, linear deposition is possible for a plurality of light-emitting layers 34 having different colors, and furthermore for all of the layers constituting the light-emitting layer unit 33, including all of the light-emitting layers 34, which has not been possible with organic EL display devices having S-Stripe arrangements lacking the above-described layered structure.

The organic EL display device 1 according to the present embodiment simply has a different pixel arrangement, as described above. The display method (display principles) of the organic EL display device 1 is the same as in Embodiment 1.

Accordingly, the present embodiment can also achieve effects similar to those of Embodiment 1. The same modifications as those of Embodiment 1 can be applied to the present embodiment as well.

For example, in the present embodiment too, a vapor deposition mask 70 in which the openings 71 are provided for two subpixels, corresponding to the subpixel 3B and the subpixel 3G1 in each of the pixels 2, for example, may be used as the vapor deposition mask 70; and when forming some of the light-emitting layers 34 among the blue fluorescent light-emitting layer 34B, the red light-emitting layer 34R, and the green fluorescent light-emitting layer 34G, a normal vapor deposition mask having an opening pattern in which individual openings 71 are provided for each subpixel may be used as the vapor deposition mask 70. Additionally, the light-emitting layers 34 may be formed by using vapor deposition masks smaller than the TFT substrate 10 as the vapor deposition masks 70 and carrying out stepwise deposition, in which the vapor deposition masks 70 are moved in order relative to the TFT substrate 10 and brought into contact with the TFT substrate 10 each time.

Additionally, the light-emitting layer unit 33 in the organic EL display device 1 according to the present embodiment has the same layered structure as the layered structure illustrated in FIGS. 1, 2, and 4, as described above. Accordingly, when forming the red light-emitting layer 34R in common for the subpixel 3G1 and the subpixel 3R, even if the red light-emitting layer 34R has infiltrated into the subpixel 3B and the red light-emitting layer 34R has been formed under the blue fluorescent light-emitting layer 34B, electrons will not reach the red light-emitting layer 34R, and red color mixing will therefore not arise in the subpixel 3B, as long as the material in the blue fluorescent light-emitting layer 34B having the highest content percentage is a hole transporting material. Likewise, when forming the red light-emitting layer 34R in common for the subpixel 3G1 and the subpixel 3R, even if the red light-emitting layer 34R has infiltrated into the subpixel 3G2 and the red light-emitting layer 34R has been formed under the green fluorescent light-emitting layer 34G, electrons will not reach the red light-emitting layer 34R, and red color mixing will therefore not arise in the subpixel 3G2, as long as the material in the green fluorescent light-emitting layer 34G having the highest content percentage is a hole transporting material. Thus using a hole transporting material for both the material in the blue fluorescent light-emitting layer 34B having the highest content percentage and the material in the green fluorescent light-emitting layer 34G having the highest content percentage makes it possible to achieve a configuration in which color mixing does not easily arise even if even a minute amount of the red luminescent material infiltrates into another subpixel 3 (i.e., at least one of the subpixel 3B and the subpixel 3G2) when depositing the red light-emitting layer 34R.

Additionally, in the present embodiment, when depositing the red light-emitting layer 34R, the respective sides of the openings 71R in the vapor deposition mask 70R (the respective ends of the openings) are, when viewed in a in a plan view, in a non-parallel relationship with the respective sides of the light emitting regions 4 in the subpixels 3 located within the openings 71R (in other words, the respective ends of the openings 15a in the banks 15 in the subpixels 3 located in the openings 71R), as illustrated in FIG. 13A. As such, in the subpixels 3R and 3G1 where the red light-emitting layer 34R is deposited, unless the light emitting regions 4R and 4G1 are formed smaller than the light emitting regions 4B and 4G2 in the other subpixels 3B and 3G2 adjacent to the light emitting regions 4R and 4G1, and the openings 71R in the vapor deposition mask 70R are made smaller as well, it becomes easier for the material of the red light-emitting layer 34R to infiltrate into the subpixels 3B and 3G2.

In other words, when the light emitting regions 4R and 4G1 in which the red light-emitting layer 34R is formed are the same size as the light emitting regions 4B and 4G2 as illustrated in FIG. 13A, and the openings 71R are formed in the vapor deposition mask 70R at a size at which the entirety of the light emitting regions 4R and 4G1 corresponding to two subpixels are included therein, the openings 71R in the vapor deposition mask 70R will partially overlap with the corners of the other light emitting regions 4B and 4G2 unless the deposition margin for preventing color mixing is increased and the non-emissive region is formed larger than as illustrated in FIG. 13A.

However, according to the present embodiment, a hole transporting material is used for both the material in the blue fluorescent light-emitting layer 34B having the highest content percentage and the material in the green fluorescent light-emitting layer 34G having the highest content percentage, as described above; it is thus difficult for color mixing to arise even if the red luminescent material infiltrates into other subpixels 3, and therefore unnecessary for the light emitting regions 4R and 4G1 to be formed smaller than the light emitting regions 4B and 4G2 as illustrated in FIGS. 12 and 13A to 13C. In other words, by using a hole transporting material for both the material in the blue fluorescent light-emitting layer 34B having the highest content percentage and the material in the green fluorescent light-emitting layer 34G having the highest content percentage as described above, the aperture ratio of the subpixels 3 can be made higher than when such is not the case.

### Third Embodiment

A description follows regarding yet another embodiment of the disclosure, mainly with reference to FIGS. 9A to 9C, 13A to 13C, 15A, and 15B.

The present embodiment will describe differences from the first and second embodiments, and constituent elements having the same functions as the constituent elements described in the first and second embodiments will be assigned the same reference signs, with descriptions thereof omitted. It goes without saying that the same modifications as those of the first and second embodiments can be applied to the present embodiment as well.

When using a slitted mask as the vapor deposition mask 70 as described in Embodiments 1 and 2, the function layers in the light-emitting layer unit 33 may be deposited through scanning vapor deposition (small-mask scanning vapor deposition) in which vapor deposition is carried out while scanning (scanning deposition) using a vapor deposition mask 70 smaller than the film formed substrate, which is the substrate on which the function layers are formed.

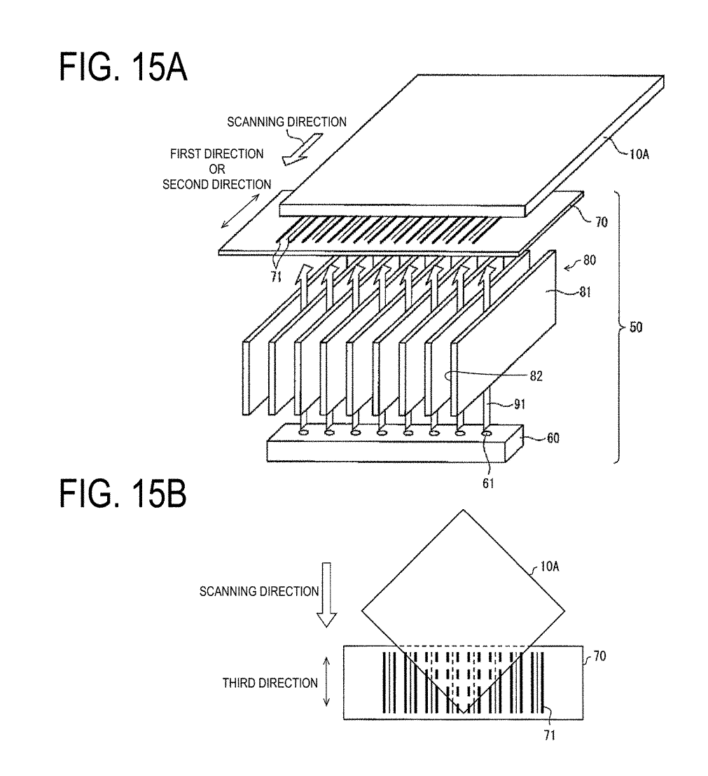

FIG. 15A is a perspective view illustrating the overall configuration of the main portions of a vapor deposition apparatus used to manufacture the organic EL display device 1 according to the present embodiment, and FIG. 15B is a plan view illustrating a state in which a TFT substrate 10A serving as a film formed substrate has been rotated by 45 degrees relative to the vapor deposition mask 70 in the vapor deposition apparatus illustrated in FIG. 15A.

As illustrated in FIG. 15A, a vapor deposition apparatus using a scanning vapor deposition method includes a film formation chamber (vacuum chamber) (not illustrated), as well as a mask unit 50 that includes at least a vapor deposition source 60 serving as a supply source of vapor deposition particles 91 and the vapor deposition mask 70, provided within the film formation chamber. It is desirable that the mask unit 50 further include a limiting plate unit 80, which limits the passage angle (flow) of the vapor deposition particles 91 emitted from the vapor deposition source 60, between the vapor deposition source 60 and the vapor deposition mask 70.

The vapor deposition source 60, the limiting plate unit 80, the vapor deposition mask 70, and the TFT substrate 10A serving as the film formed substrate are arranged opposing each other in that order, from the vapor deposition source 60 side, within the film formation chamber (not illustrated), with set spaces provided between those elements (in other words, separated by set distances).

The relative positions of the vapor deposition source 60, the limiting plate unit 80, and the vapor deposition mask 70 are fixed as the mask unit 50.

In the present embodiment, a rectangular vapor deposition mask 70 having a smaller area than the TFT substrate 10A serving as the film formed substrate (and more precisely, having a shorter length in a scanning direction of the TFT substrate 10 than the length of the TFT substrate 10A in that scanning direction) is used as the vapor deposition mask 70.

The TFT substrate 10A serving as the film formed substrate may be the TFT substrate 10 for a single organic EL display device 1, or may be a mother substrate that can be cut to configure a plurality of organic EL display devices 1 (i.e., an oversized TFT substrate provided with a plurality of circuits corresponding to a plurality of TFT substrates 10 for a plurality of organic EL display devices 1). In a mass-manufacturing process, a plurality of organic EL display devices 1 are formed on the mother substrate and are then divided into the individual organic EL display devices 1.

A plurality of openings 71 are provided in the vapor deposition mask 70 along a direction orthogonal to the scanning direction of the TFT substrate 10A.

The vapor deposition source 60 is, for example, a receptacle containing a vapor deposition material in its interior. The vapor deposition source 60 may be a receptacle that contains the vapor deposition material directly within the receptacle interior, or may have a load-lock pipe and be formed so that the vapor deposition material is supplied from the exterior.

A plurality of emission openings 61 from which the vapor deposition particles 91 are emitted are arranged in the surface of the vapor deposition source 60 opposing the limiting plate unit 80, at a constant pitch along the direction orthogonal to the scanning direction (i.e., along the direction in which the openings 71 are arranged).

However, the present embodiment is not limited thereto. Depending on the size of the TFT substrate 10A, a single vapor deposition source 60 provided with only one emission opening 61 may be used, or a plurality of vapor deposition sources 60, each provided with only one emission opening 61, may be arranged in the direction orthogonal to the scanning direction.

The vapor deposition source 60 is preferably disposed opposing the vapor deposition mask 70 with the limiting plate unit 80 provided therebetween. The vapor deposition source 60 generates the vapor deposition particles 91 in a gaseous state by heating and vaporizing the vapor deposition material (in a case where the vapor deposition material is a liquid material) or sublimating the vapor deposition material (in a case where the vapor deposition material is a solid material). The vapor deposition source 60 emits the vapor deposition material in this gaseous state from the emission openings 61 toward the limiting plate unit 80 and the vapor deposition mask 70 as the vapor deposition particles 91.

The limiting plate unit 80 includes a plurality of limiting plates 81 provided parallel to each other and separated from each other with respect to the direction orthogonal to the scanning direction. A limiting plate opening 82 is formed, as an opening regions, between each of the limiting plates 81 adjacent in the second direction.

The vapor deposition particles 91 emitted from the vapor deposition source 60 pass through the limiting plate openings 82, pass through the openings 71 serving as mask openings formed in the vapor deposition mask 70, and are deposited on the TFT substrate 10A serving as the film formed substrate.

In the present embodiment, the function layers of the light-emitting layer unit 33 are formed by disposing the mask unit 50 opposing the TFT substrate 10A with a set gap provided therebetween, moving at least one of the mask unit 50 and the TFT substrate 10A relative to the other in a direction parallel to the above-described scanning direction, and depositing the vapor deposition particles 91 on the surface of the TFT substrate 10A opposing the vapor deposition mask 70 (i.e., a film formed surface) through the openings 71 in the vapor deposition mask 70, as illustrated in FIG. 15A.

Of course, the vapor deposition apparatus including the above-described mask unit 50 can also be used to deposit the organic layers (function layers) among the organic EL layers 22 which are not included in the light-emitting layer unit 33. When using the above-described vapor deposition apparatus to deposit the organic layers (function layers) among the organic EL layers 22 which are not included in the light-emitting layer unit 33, an open mask in which the entirety of a region opposing the display region 1a is open can be used as the vapor deposition mask 70.

Thus with a scanning vapor deposition method, the deposition is carried out while scanning the film formed substrate, without the film formed substrate and the vapor deposition mask 70 being in contact. Thus in the past, it has not been possible to form all of the light-emitting layers through the scanning vapor deposition method to achieve an S-Stripe- or PenTile-type pixel arrangement, and it has not been possible to use a scanning vapor deposition method to form the light-emitting layers aside from the light-emitting layers having a luminescent color of green.

However, according to the present embodiment, scanning deposition is carried out using the vapor deposition mask 70, which has the openings 71 corresponding to each of the blue fluorescent light-emitting layer 34B, the red light-emitting layer 34R and separation layer 35, and the green fluorescent light-emitting layer 34G, as the vapor deposition mask 70. This makes it possible to form the function layers constituting the high resolution light-emitting layer unit 33 having a PenTile- or S-Stripe pixel arrangement, while utilizing the advantages provided by scanning deposition.

In scanning vapor deposition, it is not necessary to use a vapor deposition mask 70 having the same size as the film formed substrate, as described above, and an oversized film formed substrate can be used as the film formed substrate. This makes it possible to use an oversized TFT substrate 10A as the film formed substrate. Additionally, according to the present embodiment, it is not necessary to increase the distance between the vapor deposition source and the film formed substrate, as is the case when using a separate-patterning technique. The distance between the vapor deposition source 60 and the TFT substrate 10A serving as the film formed substrate can be reduced, which provides greater material utilization efficiency and makes it possible to reduce the size of the apparatus.

### Manufacturing Method for Organic EL Display Device 1

According to the present embodiment, in a case where, in the green fluorescent light-emitting layer formation process (S6) illustrated in FIG. 9C or the red light-emitting layer formation process (S4) and the separation layer formation process (S5) illustrated in FIG. 13A, the film formed substrate (TFT substrate 10A) is rotated 45 degrees relative to the vapor deposition mask 70 and deposition is then carried out in an oblique direction, a slitted mask can be used as the vapor deposition mask 70 to form all of the layers in the light-emitting layer unit 33, as illustrated in FIGS. 9A to 9C and FIGS. 13A to 13C.

Here, rotating the film formed substrate by 45 degrees relative to the vapor deposition mask 70 and depositing in an oblique direction refers to arranging the film formed substrate so that the long side directions of the openings 71 in the vapor deposition mask 70 and the limiting plate openings 82 (i.e., a slit direction, which corresponds to the longer direction of the openings) are arranged in a direction parallel to an oblique direction forming a 45-degree angle with one side of the film formed substrate (and more precisely, a display region of the film formed substrate) or an axis of the film formed substrate (if the film formed substrate or the display region of the film formed substrate is circular or elliptical), and carrying out the deposition while moving at least one of the mask unit 50 and the film formed substrate relative to each other in the direction parallel to the oblique direction.

Accordingly, in the present embodiment, rotating the film formed substrate by 45 degrees relative to the vapor deposition mask 70 and depositing in the oblique direction refers to disposing the film formed substrate so that the long side directions of the openings 71 in the vapor deposition mask 70 and the limiting plate openings 82 correspond to a direction parallel to a diagonal line of the film formed substrate (and more precisely, a diagonal line of the display region 1a of the film formed substrate), and then depositing while moving at least one of the mask unit 50 and the film formed substrate relative to each other in the direction parallel to the diagonal line of the film formed substrate.

This will be described in more detail below.

The manufacturing method of the organic EL display device 1 according to the present embodiment is the same as the manufacturing method of the organic EL display device 1 according to Embodiments 1 and 2, except that in the red light-emitting layer formation process (S4) to the blue fluorescent light-emitting layer formation process (S7) illustrated in FIG. 10, the red light-emitting layer 34R, the separation layer 35, the green fluorescent light-emitting layer 34G, and the blue fluorescent light-emitting layer 34B are formed using scanning vapor deposition.

Accordingly, the following will describe a method of forming the red light-emitting layer 34R, the separation layer 35, the green fluorescent light-emitting layer 34G, and the blue fluorescent light-emitting layer 34B using scanning vapor deposition in the red light-emitting layer formation process (S4) to the blue fluorescent light-emitting layer formation process (S7).

A case where the organic EL display device 1 has a PenTile-type pixel arrangement, as illustrated in FIG. 13, will be described first.

When the organic EL display device 1 has a PenTile-type pixel arrangement, in the red light-emitting layer formation process (S4) illustrated in FIG. 9A, first, the vapor deposition mask 70R having a smaller area than the TFT substrate 10A when viewed in a plan view is used as the vapor deposition mask 70 illustrated in FIG. 15A, and the TFT substrate 10A is arranged so that the longer direction of the openings in the vapor deposition mask 70R corresponds to the column direction of the TFT substrate 10A (the second direction). Then, the material of the red light-emitting layer 34R is linearly-deposited in the direction connecting the light emitting regions 4G1 and the light emitting regions 4R adjacent in the above-described second direction (i.e., the direction connecting the subpixel 3G1 and the subpixel 3R) while moving at least one of the mask unit 50 and the TFT substrate 10A relative to the other so that the longer direction of the openings in the vapor deposition mask 70R (i.e., the above-described second direction) corresponds to the scanning direction.

As a result, in the present embodiment, the red light-emitting layer 34R is formed as a continuous stripe, from one end to the other end of the display region of the TFT substrate 10A, with respect to the column direction (e.g., the display region 1a of the TFT substrate 10 illustrated in FIG. 11). More specifically, in the present embodiment, the red light-emitting layer 34R is formed as a continuous stripe from one end to the other end of the TFT substrate 10A with respect to the column direction.

Next, in the separation layer formation process (S5), the material of the separation layer 35 is linearly-deposited, on the red light-emitting layer 34R, in the direction connecting the light emitting regions 4G1 and the light emitting regions 4R adjacent in the above-described second direction (i.e., the direction connecting the subpixel 3G1 and the subpixel 3R), in the same manner as in the above-described red light-emitting layer formation process (S4), using the above-described vapor deposition mask 70R or a dedicated vapor deposition mask having the same opening pattern as the above-described vapor deposition mask 70R. As a result, the separation layer 35 having the same pattern as the red light-emitting layer 34R when viewed in a plan view is layered upon the red light-emitting layer 34R.

Then, in the green fluorescent light-emitting layer formation process (S6), the vapor deposition mask 70G having a smaller area than the TFT substrate 10A when viewed in a plan view is used as the vapor deposition mask 70 illustrated in FIGS. 15A and 15B, and the TFT substrate 10A is rotated 45 degrees relative to the vapor deposition mask 70 (i.e., the vapor deposition mask 70G) so that the longer direction of the openings in the vapor deposition mask 70G corresponds to the oblique direction (the third direction) with respect to the TFT substrate 10A, as illustrated in FIG. 15B. Then, the material of the green fluorescent light-emitting layer 34G is linearly-deposited in the direction connecting the light emitting regions 4G1 and the light emitting regions 4G2 adjacent in the above-described third direction (i.e., the direction connecting the subpixel 3G1 and the subpixel 3G2) while moving at least one of the mask unit 50 and the TFT substrate 10A relative to the other so that the longer direction of the openings in the vapor deposition mask 70G (i.e., the above-described third direction) corresponds to the scanning direction.

As a result, in the present embodiment, the green fluorescent light-emitting layer 34G is formed as a continuous stripe, from one end to the other end of the display region of the TFT substrate 10A (e.g., the display region 1a of the TFT substrate 10 illustrated in FIG. 11), with respect to the oblique direction (the diagonal line direction, in the example illustrated in FIG. 15B). More specifically, in the present embodiment, the green fluorescent light-emitting layer 34G is formed as a continuous stripe from one end to the other end of the TFT substrate 10A with respect to the oblique direction (the diagonal line direction, in the example illustrated in FIG. 15B).

Note that in the present embodiment, the openings 71G in the vapor deposition mask 70G are formed so that the opening widths thereof are smaller than the opening widths of the openings 71R and 71B in the vapor deposition masks 70R and 70B, as illustrated in FIGS. 3 and 9A to 9C. Thus while the foregoing describes a case where a dedicated vapor deposition mask 70G is used as the vapor deposition mask 70 in the green fluorescent light-emitting layer formation process (S6) as an example, in a case where the openings 71G and the openings 71R have the same opening widths and the same opening pitches, a vapor deposition mask 70 having the same opening pattern as the vapor deposition mask 70 used in the red light-emitting layer formation process (S4), for example, may be used as the vapor deposition mask 70; or, in a case where color mixing caused by the sublimation of vapor deposition films adhering to the vapor deposition masks 70 or the sublimation of vapor deposition films that have peeled off from the vapor deposition masks 70 is not a problem, the same vapor deposition mask 70 may be used as the vapor deposition mask 70 used in the red light-emitting layer formation process (S4). When employing scanning vapor deposition, the light-emitting layers 34 and the openings 71 need not have the same shapes when viewed in a plan view, and thus a vapor deposition mask 70 having the same opening pattern as the vapor deposition mask 70R can be used as the vapor deposition mask 70G as long as the opening widths and opening pitches are the same for the openings 71G and the openings 71R.

In any event, according to the present embodiment, rotating the TFT substrate 10A by 90 degrees within the same plane after carrying out the separation layer formation process (S5) makes it possible to linearly-deposit the material of the green fluorescent light-emitting layer 34G in the direction connecting the light emitting regions 4G1 and the light emitting regions 4G2 adjacent in the oblique direction using a slitted mask as the vapor deposition mask 70.

Then, in the blue fluorescent light-emitting layer formation process (S7), the vapor deposition mask 70B having a smaller area than the TFT substrate 10A when viewed in a plan view is used as the vapor deposition mask 70 illustrated in FIG. 15A, and the TFT substrate 10A is further rotated 45 degrees from the state illustrated in FIG. 15B, in the same direction as the rotation direction of the TFT substrate 10A in the green fluorescent light-emitting layer formation process (S6) (e.g., the clockwise direction), so that the longer direction of the openings in the vapor deposition mask 70B corresponds to the row direction of the TFT substrate 10A (the first direction). As a result, in the blue fluorescent light-emitting layer formation process (S7), the TFT substrate 10A is arranged at a rotation of 90 degrees, within the same plane, relative to the TFT substrate 10A in the red light-emitting layer formation process (S4) and the separation layer formation process (S5). Then, the material of the blue fluorescent light-emitting layer 34B is linearly-deposited in the direction connecting the light emitting regions 4B and the light emitting regions 4G1 adjacent in the above-described first direction (i.e., the direction connecting the subpixel 3B and the subpixel 3G1) while moving at least one of the mask unit 50 and the TFT substrate 10A relative to the other so that the longer direction of the openings in the vapor deposition mask 70B (i.e., the above-described first direction) corresponds to the scanning direction.

As a result, in the present embodiment, the blue fluorescent light-emitting layer 34B is formed as a continuous stripe, from one end to the other end of the display region of the TFT substrate 10A, with respect to the row direction (e.g., the display region 1a of the TFT substrate 10 illustrated in FIG. 11). More specifically, in the present embodiment, the blue fluorescent light-emitting layer 34B is formed as a continuous stripe from one end to the other end of the TFT substrate 10A with respect to the row direction.

Although the foregoing describes a case where a dedicated vapor deposition mask 70B is used as the vapor deposition mask 70 in the blue fluorescent light-emitting layer formation process (S7) as an example, a vapor deposition mask 70 having the same opening pattern as the vapor deposition mask 70R can be used for the vapor deposition mask 70B if scanning vapor deposition is to be employed, in the same manner as with the vapor deposition mask 70G. Accordingly, if the above-described color mixing is not a problem, the same vapor deposition mask 70 as the vapor deposition mask 70 used in the red light-emitting layer formation process (S4) or the green fluorescent light-emitting layer formation process (S6), for example, may be used as the vapor deposition mask 70.

Thus when the organic EL display device 1 has a PenTile-type pixel arrangement, after the separation layer formation process (S5), the TFT substrate 10A is rotated by 45 degrees within the same plane, and the TFT substrate 10A is arranged so that the longer direction of the openings in the vapor deposition mask 70 is parallel to the diagonal line direction of the TFT substrate 10A, as illustrated in FIG. 15B. As a result, the material of the green fluorescent light-emitting layer 34G can be linearly-deposited in the direction connecting the light emitting regions 4G1 and the light emitting regions 4G2 adjacent in the oblique direction by using a slitted mask as the vapor deposition mask 70.

Although the foregoing describes, as an example, a case where the TFT substrate 10A is rotated relative to the mask unit 50, the present embodiment is not limited thereto. For example, the mask unit 50 may be rotated relative to the TFT substrate 10A within the same plane by using an XY stage or the like. Here, rotating the mask unit 50 relative to the TFT substrate 10A within the same plane refers to rotating the mask unit 50 in the horizontal direction while maintaining the individual relative positional relationships with the constituent elements constituting the mask unit, such as the vapor deposition source 60, the limiting plate unit 80, and the vapor deposition mask 70. In this case, in a case where the constituent elements constituting the mask unit 50 are held integrally using a single holder, those constituent elements may be rotated together in the horizontal direction (i.e., the mask unit 50 itself may be rotated in the horizontal direction) by rotating the entire holder in the horizontal direction; in a case where the constituent elements are held individually by separate holding members in a state where the relative positional relationships of those constituent elements are maintained, the constituent elements may be rotated individually in the horizontal direction while ultimately maintaining the relative positional relationships between those constituent elements.

Thus as described above, at least one of the mask unit 50 and the TFT substrate 10A is rotated relative to the other, in the same plane, from the state in the previous light-emitting layer formation process, and as a result, linear deposition can be carried out in either direction using a slitted mask as the vapor deposition mask 70. Accordingly, the linear deposition can be carried out using a slitted mask in all of the processes from the red light-emitting layer formation process (S4) to the blue fluorescent light-emitting layer formation process (S7). Here, rotating at least one of the mask unit 50 and the TFT substrate 10A within the same plane relative to the other refers, in the case where the mask unit 50 is rotated, to rotating the mask unit 50 within the same plane as the plane in which that mask unit is arranged, and refers, in the case where the TFT substrate 10A is rotated, to rotating the TFT substrate 10A within the same plane as the plane in which that TFT substrate 10A is arranged.

A case where the organic EL display device 1 has an S-Stripe pixel arrangement, as illustrated in FIG. 12, will be described next.

If the organic EL display device 1 has an S-Stripe pixel arrangement, in the red light-emitting layer formation process (S4) illustrated in FIG. 13A, the vapor deposition mask 70R having a smaller area than the TFT substrate 10A when viewed in a plan view is used as the vapor deposition mask 70 illustrated in FIGS. 15A and 15B, and the TFT substrate 10A is disposed with its outer edges (respective sides) rotated (angled) 45 degrees relative to the outer edges (respective sides) of the vapor deposition mask 70 (i.e., the vapor deposition mask 70R) so that the longer direction of the openings in the vapor deposition mask 70R corresponds to the oblique direction (the third direction) with respect to the TFT substrate 10A, as illustrated in FIG. 15B. Then, the material of the red light-emitting layer 34R is linearly-deposited in the direction connecting the light emitting regions 4G1 and the light emitting regions 4R adjacent in the above-described third direction while moving at least one of the mask unit 50 and the TFT substrate 10A relative to the other so that the longer direction of the openings in the vapor deposition mask 70R (i.e., the above-described third direction) corresponds to the scanning direction.

As a result, in the present embodiment, the red light-emitting layer 34R is formed as a continuous stripe, from one end to the other end of the display region of the TFT substrate 10A (e.g., the display region 1a of the TFT substrate 10 illustrated in FIG. 14), with respect to the oblique direction (the diagonal line direction, in the example illustrated in FIG. 15B). More specifically, in the present embodiment, the red light-emitting layer 34R is formed as a continuous stripe from one end to the other end of the TFT substrate 10A with respect to the oblique direction (the diagonal line direction, in the example illustrated in FIG. 15B).

Then, in the separation layer formation process (S5), the material of the separation layer 35 is linearly-deposited, on the red light-emitting layer 34R, in the direction connecting the light emitting regions 4G1 and the light emitting regions 4R adjacent in the above-described third direction, in the same manner as in the above-described red light-emitting layer formation process (S4), using the above-described vapor deposition mask 70R or a dedicated vapor deposition mask having the same opening pattern as the above-described vapor deposition mask 70R. As a result, the separation layer 35 having the same pattern as the red light-emitting layer 34R when viewed in a plan view is layered upon the red light-emitting layer 34R.

Then, in the green fluorescent light-emitting layer formation process (S6), the vapor deposition mask 70G having a smaller area than the TFT substrate 10A when viewed in a plan view is used as the vapor deposition mask 70 illustrated in FIG. 15A, and the TFT substrate 10A is rotated counterclockwise or clockwise by 45 degrees relative to the vapor deposition mask 70 (i.e., the vapor deposition mask 70G) so that the longer direction of the openings in the vapor deposition mask 70G corresponds to the column direction (the second direction) with respect to the TFT substrate 10A, as illustrated in FIG. 15A. Then, the material of the green fluorescent light-emitting layer 34G is linearly-deposited in the direction connecting the light emitting regions 4G1 and the light emitting regions 4G2 adjacent in the above-described second direction while moving at least one of the mask unit 50 and the TFT substrate 10A relative to the other so that the longer direction of the openings in the vapor deposition mask 70G (i.e., the above-described second direction) corresponds to the scanning direction.

As a result, in the present embodiment, the green fluorescent light-emitting layer 34G is formed as a continuous stripe, from one end to the other end of the display region of the TFT substrate 10A, with respect to the column direction (e.g., the display region 1a of the TFT substrate 10 illustrated in FIG. 14). More specifically, in the present embodiment, the green fluorescent light-emitting layer 34G is formed as a continuous stripe from one end to the other end of the TFT substrate 10A with respect to the column direction.

Then, in the blue fluorescent light-emitting layer formation process (S7), the vapor deposition mask 70B having a smaller area than the TFT substrate 10A when viewed in a plan view is used as the vapor deposition mask 70 illustrated in FIG. 15A, and the TFT substrate 10A is rotated clockwise or counterclockwise by 90 degrees from the state (position) of the TFT substrate 10A in the green fluorescent light-emitting layer formation process (S6), so that the longer direction of the openings in the vapor deposition mask 70B corresponds to the row direction of the TFT substrate 10A (the first direction). Then, the material of the blue fluorescent light-emitting layer 34B is linearly-deposited in the direction connecting the light emitting regions 4G1 and the light emitting regions 4B adjacent in the above-described first direction while moving at least one of the mask unit 50 and the TFT substrate 10A relative to the other so that the longer direction of the openings in the vapor deposition mask 70B (i.e., the above-described first direction) corresponds to the scanning direction.

As a result, in the present embodiment, the blue fluorescent light-emitting layer 34B is formed as a continuous stripe, from one end to the other end of the display region of the TFT substrate 10A, with respect to the row direction (e.g., the display region 1a of the TFT substrate 10 illustrated in FIG. 14). More specifically, in the present embodiment, the blue fluorescent light-emitting layer 34B is formed as a continuous stripe from one end to the other end of the TFT substrate 10A with respect to the row direction.

Thus when the organic EL display device 1 has an S-Stripe pixel arrangement, the outer edges (sides) of the TFT substrate 10A are, in the red light-emitting layer formation process (S4) and the separation layer formation process (S5), angled (rotated) by 45 degrees relative to the outer edges (sides) of the vapor deposition mask 70 so that the longer direction of the openings in the vapor deposition mask 70 is parallel to the diagonal line direction of the TFT substrate 10A, as illustrated in FIG. 15B. As a result, the material of the red light-emitting layer 34R can be linearly-deposited in the direction connecting the light emitting regions 4G1 and the light emitting regions 4R adjacent in the oblique direction, by using a slitted mask as the vapor deposition mask 70.

Although the foregoing describes, as an example, a case where the TFT substrate 10A is rotated relative to the mask unit 50, the mask unit 50 may, for example, be rotated relative to the TFT substrate 10A within the same plane by using an XY stage or the like, as described earlier.

Thus even when the organic EL display device 1 has an S-Stripe pixel arrangement, at least one of the mask unit 50 and the TFT substrate 10A is rotated relative to the other, in the same plane, from the state in the previous light-emitting layer formation process, and as a result, linear deposition can be carried out in either direction using a slitted mask as the vapor deposition mask 70. Accordingly, the linear deposition can be carried out using a slitted mask in all of the processes from the red light-emitting layer formation process (S4) to the blue fluorescent light-emitting layer formation process (S7).

Additionally, the foregoing describes, as an example, a case where dedicated vapor deposition masks 70 are used as the vapor deposition masks 70 in the processes of forming the light-emitting layers 34 of the respective colors. However, as described above, in a case where color mixing caused by the sublimation of vapor deposition films adhering to the vapor deposition masks 70 or the sublimation of vapor deposition films that have peeled off from the vapor deposition masks 70 is not a problem, the same vapor deposition mask 70 as that used in the red light-emitting layer formation process (S4) may be used in the green fluorescent light-emitting layer formation process (S6) and the blue fluorescent light-emitting layer formation process (S7), or individual vapor deposition masks 70 having the same opening pattern as that vapor deposition mask 70 may be used.

Additionally, the present embodiment describes, as an example, a case where the mask unit 50 includes the limiting plate unit 80 and a linear vapor deposition source, in which the emission openings 61 are arranged in a line, is used as the vapor deposition source 60, as illustrated in FIG. 15A; and furthermore describes, as an example, a case where at least one of the mask unit 50 and the TFT substrate 10A is rotated relative to the other within the same plane from the state in the previous light-emitting layer formation process. However, the limiting plate unit 80 is not necessary, and the type of the vapor deposition source 60 is also not particularly limited. As such, depending on the configuration of the mask unit 50, when the mask unit 50 is rotated relative to the TFT substrate 10A, it is not necessary to rotate the entire mask unit 50, and it is sufficient to rotate at least the vapor deposition mask 70 relative to the TFT substrate 10A within the same plane.

Additionally, the present embodiment describes, as an example, a case where the red light-emitting layer 34R, the separation layer 35, the green fluorescent light-emitting layer 34G, and the blue fluorescent light-emitting layer 34B are formed using scanning vapor deposition in the red light-emitting layer formation process (S4) to the blue fluorescent light-emitting layer formation process (S7), as described above. However, the present embodiment is not limited thereto, and in at least one of the above-described S4 to S7, stepwise deposition, in which the vapor deposition masks 70 are moved in order relative to the TFT substrate 10 and brought into contact with the TFT substrate 10 each time, may be carried out instead of the above-described scanning deposition. In this case too, as described above, rotating at least one of the mask unit 50 and the TFT substrate 10A is relative to the other, in the same plane, from the state in the previous light-emitting layer formation process makes it possible to carry out linear deposition using the vapor deposition mask 70 smaller than the TFT substrate 10A.

### Fourth Embodiment

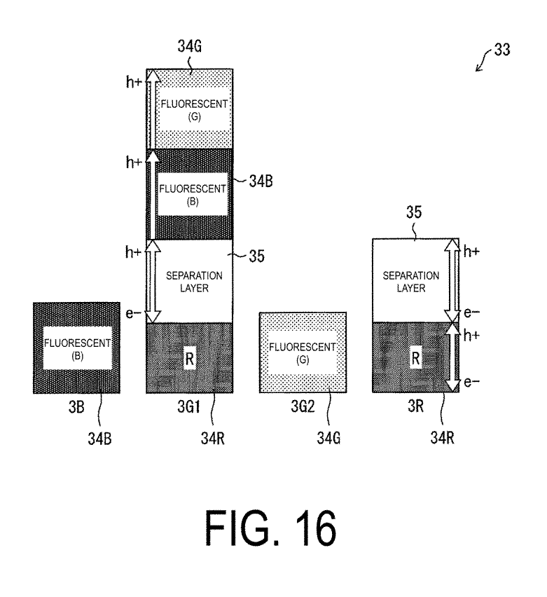

Yet another embodiment of the disclosure will be described below with reference primarily to FIGS. 16 to 18. The present embodiment will describe differences from the first to third embodiments, and constituent elements having the same functions as the constituent elements described in the first to third embodiments will be assigned the same reference signs, with descriptions thereof omitted. It goes without saying that the same modifications as those of the first to third embodiments can be applied to the present embodiment as well.

The organic EL display device 1 according to the present embodiment is the same as the organic EL display device 1 according to Embodiments 1 to 3 excepting the following points.

Embodiment 1 describes, as an example, a case where the processes indicated by S1 to S11 are carried out in that order, as illustrated in FIG. 10. However, the processes indicated by S4 to S7 do not absolutely need to be carried out in this order. The following will describe an example in which this order of processes is changed.

Furthermore, specific Examples of the materials and thicknesses of the layers layered on the TFT substrate 10 will be given below for each example. However, the dimensions and materials denoted in the Examples are merely examples, and the present embodiment is not intended to be limited to these specific dimensions and materials. As in Example 1 defining dimensions, materials, and the mixing ratio of materials, the following Examples defining dimensions, materials, and the mixing ratio of materials also assume that the thickness of the light-transmissive electrode 21b has been optically optimized through optical simulations to align the luminescent color of the subpixel 3G1 and the luminescent color of the subpixel 3G2.

### Example 1: Defining Layering Order of Function Layers in Light-Emitting Layer Unit

FIG. 16 is a diagram schematically illustrating the layered structure of the light-emitting layer unit 33 of the organic EL display device 1 according to the present embodiment.

In the example illustrated in FIG. 16, the light-emitting layer unit 33 has the red light-emitting layer 34R, the separation layer 35, the blue fluorescent light-emitting layer 34B, and the green fluorescent light-emitting layer 34G layered, in that order from the first electrode 21 side, between the first electrode 21 and the second electrode 23. Thus in the above-described light-emitting layer unit 33, the green fluorescent light-emitting layer 34G is located closer to the second electrode 23, which is a cathode electrode, than the blue fluorescent light-emitting layer 34B.

In this example, the blue fluorescent light-emitting layer 34B and the red light-emitting layer 34R are adjacent in the layering direction, with the separation layer 35 interposed therebetween, as illustrated in FIG. 16. Thus in this example, the distance between opposing surfaces of the blue fluorescent light-emitting layer 34B and the red light-emitting layer 34R (an opposing surface distance D_{BR}), i.e., a distance between the surface of the blue fluorescent light-emitting layer 34B located furthest on the red light-emitting layer 34R side (a lower surface of the blue fluorescent light-emitting layer 34B, in the present embodiment) and the surface of the red light-emitting layer 34R located furthest on the blue fluorescent light-emitting layer 34B side (an upper surface of the red light-emitting layer 34R, in the present embodiment), which is equal to the thickness of the separation layer 35, is set to a distance greater than the Förster radius. Note that like the opposing surface distance D_{GR}, the opposing surface distance D_{BR} is preferably greater than or equal to 15 nm and less than or equal to 50 nm, and more preferably greater than or equal to 15 nm and less than or equal to 30 nm.

Additionally, it is preferable that a hole transporting material be used for the material of at least one, and desirably both, of the material in the green fluorescent light-emitting layer 34G having the highest content percentage and the material in the blue fluorescent light-emitting layer 34B having the highest content percentage. Note that a bipolar transporting material or a hole transporting material is used for the red light-emitting layer 34R, and a material having bipolar transport properties as a whole is used for the intermediate layer such as the separation layer 35 and the like.

Additionally, the thickness of the blue fluorescent light-emitting layer 34B is preferably set to less than or equal to 10 nm, for the same reasons as those described in Embodiment 1.

Additionally, in this example, it is preferable, for the same reasons as those described in Embodiment 1, that part of the PL emission spectrum of the blue fluorescent luminescent material overlap with part of the absorption spectrum of the green fluorescent luminescent material. It is also preferable that there is no overlapping between the absorption spectrum of the material of the separation layer 35 and the PL emission spectrum of the fluorescent luminescent material of at least the light-emitting layer, among the blue fluorescent light-emitting layer 34B and the green fluorescent light-emitting layer 34G provided on the opposite side of the separation layer 35 from the red light-emitting layer 34R, that is adjacent to the separation layer 35 (the blue fluorescent light-emitting layer 34B, in this example), and further preferable that there is no overlapping between the PL emission spectrum of the green fluorescent luminescent material and the PL emission spectrum of the blue fluorescent luminescent material.

Additionally, it is preferable that at least one, and more desirably, both, of the blue fluorescent luminescent material and the green fluorescent luminescent material be a TADF material. The reasons for this are as follows.

Normally, in an organic EL element, electrons and holes are injected into the light-emitting layer and recombine to generate excitons, and the light given off when the excitons are deactivated is utilized. Here, the probability of the excitons being generated in the excited singlet state is 25%, and the probability of the excitons being generated in the excited triplet state is 75%.

However, while a transition from the excited singlet state (S₁ level) to the ground state (S₀ level) is a permitted transition between states having the same spin multiplicity, a transition from the excited triplet state (T₁ level) to the ground state (S₀ level) is a prohibited transition between states having different spin multiplicities. Therefore, the triplet excitons generated at the T₁ level change to thermal energy or the like and deactivate as heat, without emitting light, and therefore do not contribute to light emission. There is thus a problem in that the light emitting efficiency of a normal fluorescent luminescent material drops when excitons are generated at the T₁ level.

Furthermore, Förster transfer from a given material in an excited triplet state (one of two adjacent pigment molecules) to another material in an excited triplet state (the other of the two adjacent pigment molecules) is prohibited, and only Dexter transfer occurs. Thus when excitons have been generated at the T₁ level, energy is transferred only to molecules in direct contact.

Thus as illustrated in FIG. 1, for example, in the subpixel 3G1, when excitons are generated in the blue fluorescent light-emitting layer 34B, no energy is transferred from the blue fluorescent luminescent material at the T₁ level to the green fluorescent luminescent material. Energy is only transferred from the blue fluorescent luminescent material at the S₁ level to the green fluorescent luminescent material at the S₁ level, and thus in the subpixel 3G1, it is possible that color mixing, a drop in the light emitting efficiency, or the like will arise.

Accordingly, the blue fluorescent luminescent material used for the blue fluorescent light-emitting layer 34B is preferably a TADF material.

As described in Embodiment 1, a TADF material has an extremely low ΔE_{ST}, and reverse intersystem crossing from the T₁ level to the S₁ level arises. Thus if a TADF material is used for the blue fluorescent luminescent material, excitons at the T₁ level are upconverted to the S₁ level through the reverse intersystem crossing.

Thus, in a case where a TADF material is used for the blue fluorescent luminescent material, even if, for example, excitons have been generated in the blue fluorescent light-emitting layer 34B of the subpixel 3G1, energy will be transferred from the blue fluorescent luminescent material to the green fluorescent luminescent material due to Förster transfer between S₁ levels resulting from the reverse intersystem crossing from the T₁ level to the S₁ level. Accordingly, using a TADF material for the blue fluorescent luminescent material makes it possible to suppress blue color mixing in the subpixel 3G1 and thus improve the color level in the subpixel 3G1.

Additionally, using a TADF material for the blue fluorescent luminescent material results in excitons at the T₁ level being upconverted to the S₁ level in the subpixel 3B, which improves the light emitting efficiency in the subpixel 3B and in turn improves the light emitting efficiency of the organic EL display device 1. For the same reason, a TADF material may be used for the green fluorescent luminescent material. In this case, in the subpixels 3G1 and 3G2, excitons at the T₁ level are upconverted to the S₁ level, which improves the light emitting efficiency in the subpixels 3G1 and 3G2 and in turn improves the light emitting efficiency of the organic EL display device 1. Of course, a TADF material may be used as the red luminescent material, as described earlier, to improve the light emitting efficiency in the subpixel 3R.

The above-described 2CzPN, DMAC-DPS, and the like can be given as examples of TADF materials that emit blue light. The above-described 4CzIPN, 4CzPN, PXZ-DPS, and the like can be given as examples of TADF materials that emit green light.

In this example too, as in Embodiments 1 to 3, excitons are generated in the blue fluorescent light-emitting layer 34B in the subpixel 3B, excitons are generated in the green fluorescent light-emitting layer 34G in the subpixel 3G2, and excitons are generated in the red light-emitting layer 34R in the subpixel 3R. Even if, as in this example, the layering order of the blue fluorescent light-emitting layer 34B and the green fluorescent light-emitting layer 34G in the subpixel 3G1 is reversed from that in Embodiments 1 to 3, whether excitons are generated by the blue fluorescent light-emitting layer 34B or excitons are generated by the green fluorescent light-emitting layer 34G in the subpixel 3G1 differs depending on the relationship between the carrier mobility of the material in the blue fluorescent light-emitting layer 34B having the highest content percentage and the carrier mobility of the material in the green fluorescent light-emitting layer 34G having the highest content percentage.

As described above, in this example, the green fluorescent light-emitting layer 34G is located further on the cathode electrode side (the second electrode 23 side) than the blue fluorescent light-emitting layer 34B. Thus as illustrated in FIG. 16, excitons are generated in the green fluorescent light-emitting layer 34G when a hole transporting material is used for both the material in the blue fluorescent light-emitting layer 34B having the highest content percentage and the material in the green fluorescent light-emitting layer 34G having the highest content percentage.

In this case, it is desirable that a TADF material be used for both the blue fluorescent luminescent material and the green fluorescent luminescent material. When excitons are generated in the green fluorescent light-emitting layer 34G, the probability that the excitons are generated in an excited singlet state is 25%, and the probability that the excitons are generated in an excited triplet state is 75%, in the green fluorescent light-emitting layer 34G. As such, when a TADF material is not used for the green fluorescent luminescent material, the 75% excitons do not emit light, and thermally deactivate. Using a TADF material for the green fluorescent luminescent material results in excitons at the T₁ level being upconverted to the S₁ level in the subpixel 3G1, which improves the light emitting efficiency in the subpixel 3G1 and in turn improves the light emitting efficiency of the organic EL display device 1. Additionally, in a case where a TADF material is used for the blue fluorescent luminescent material, even if, for example, excitons have been generated in the blue fluorescent light-emitting layer 34B, energy will be transferred from the blue fluorescent luminescent material to the green fluorescent luminescent material due to Förster transfer between S₁ levels resulting from the reverse intersystem crossing from the T₁ level to the S₁ level. Accordingly, using a TADF material for the green fluorescent luminescent material and the blue fluorescent luminescent material makes it possible to suppress blue color mixing in the subpixel 3G1 and thus improve the color level in the subpixel 3G1.

In the manufacturing method for the organic EL display device 1 according to this example, the processes indicated by S4 to S7 in the organic EL element preparation process illustrated in FIG. 10 are carried out in the order of the red light-emitting layer formation process (S4), the separation layer formation process (S5), the blue fluorescent light-emitting layer formation process (S7), and the green fluorescent light-emitting layer formation process (S6). Accordingly, the organic EL display device 1 having the above-described layered structure can be manufactured. Examples defining dimensions, materials, and the mixing ratio of materials will be described below. Note that in the following example, a TADF material was used for both the blue fluorescent luminescent material and the green fluorescent luminescent material.

### Example 2: Defining Dimensions, Materials, and Mixing Ratio of Materials

Reflective electrode 21a (first electrode 21; anode electrode): Ag (100 nm)

Light-transmissive electrode 21b (first electrode 21, anode electrode): ITO (subpixel 3B: 135 nm/subpixel 3G1: 135 nm/subpixel 3G2: 165 nm/subpixel 3R: 40 nm)

Hole injection layer 31: HAT-CN (10 nm)

Hole transport layer 32: TCTA (20 nm)

Red light-emitting layer 34R: CBP (host material 90%)/Ir(piq)3 (red luminescent material, 10%) (10 nm)

Separation layer 35: CBP (20 nm)

Blue fluorescent light-emitting layer 34B: mCP (host material, 90%)/DMAC-DPS (blue fluorescent luminescent material, 10%) (10 nm)

Green fluorescent light-emitting layer 34G: mCP (host material, 90%)/4CzIPN (green fluorescent luminescent material, 10%) (10 nm)

Electron transport layer 36: BCP (30 nm)

Electron injection layer 37: LiF (1 nm)

Second electrode 23 (cathode electrode, semitransparent electrode): Ag—Mg alloy (Ag/Mg mixing ratio=0.9/0.1) (20 nm)

Protection layer 24: ITO (80 nm)

According to this example, in the subpixel 3G1, the green fluorescent light-emitting layer 34G is located furthest on the cathode electrode side (i.e., the second electrode 23 side) within the light-emitting layer unit 33, as illustrated in FIG. 16. Accordingly, in a case where, as described above, the carrier mobility provides hole transport properties in at least one of the material in the green fluorescent light-emitting layer 34G having the highest content percentage (mCP, which is the host material in Example 2 defining dimensions, materials, and the mixing ratio of materials) and the material in the blue fluorescent light-emitting layer 34B having the highest content percentage (mCP, which is the host material in Example 2 defining dimensions, materials, and the mixing ratio of materials), the probability that excitons will be generated in the green fluorescent light-emitting layer 34G increases, and the light emitting efficiency is improved.

Even if excitons are generated in the blue fluorescent light-emitting layer 34B, setting the thickness of the blue fluorescent light-emitting layer 34B to less than or equal to 10 nm as described above shortens the distance from the location where the excitons are generated to the green fluorescent light-emitting layer 34G. This is expected to improve the probability that Förster transfer will arise, improve the color level, and improve the light emitting efficiency.

Additionally, in this example, when forming the blue fluorescent light-emitting layer 34B in common for the subpixel 3B and the subpixel 3G1 through linear deposition, even if the blue fluorescent light-emitting layer 34B infiltrates into the subpixel 3G2 and the blue fluorescent light-emitting layer 34B is formed under the green fluorescent light-emitting layer 34G (i.e., on the first electrode 21 side), energy is transferred from the blue fluorescent luminescent material to the green fluorescent luminescent material, and thus no blue color mixing will occur in the subpixel 3G2.

Additionally, as in Embodiments 1 to 3, the red light-emitting layer 34R is located furthest on the anode electrode side (i.e., on the first electrode 21 side) in the light-emitting layer unit 33, and the red light-emitting layer formation process (S4) is carried out before the blue fluorescent light-emitting layer formation process (S7) and the green fluorescent light-emitting layer formation process (S6), in this example as well.

Thus in this example as well, when forming the red light-emitting layer 34R in common for the subpixel 3G1 and the subpixel 3R through linear deposition, even if the red light-emitting layer 34R has infiltrated into the subpixel 3B and the red light-emitting layer 34R has been formed under the blue fluorescent light-emitting layer 34B, electrons will not reach the red light-emitting layer 34R, and red color mixing will therefore not arise in the subpixel 3B, as long as the material in the blue fluorescent light-emitting layer 34B having the highest content percentage is a hole transporting material.

Likewise, when forming the red light-emitting layer 34R in common for the subpixel 3G1 and the subpixel 3R, even if the red light-emitting layer 34R has infiltrated into the subpixel 3G2 and the red light-emitting layer 34R has been formed under the green fluorescent light-emitting layer 34G, electrons will not reach the red light-emitting layer 34R, and red color mixing will therefore not arise in the subpixel 3G2, as long as the material in the green fluorescent light-emitting layer 34G having the highest content percentage is a hole transporting material.

Thus according to this example, using a hole transporting material for both the material in the blue fluorescent light-emitting layer 34B having the highest content percentage and the material in the green fluorescent light-emitting layer 34G having the highest content percentage makes it possible to achieve a configuration in which color mixing does not easily arise even if even a minute amount of the red luminescent material infiltrates into another subpixel 3 (i.e., at least one of the subpixel 3B and the subpixel 3G2) when depositing the red light-emitting layer 34R.

Note that even in this example, in the case where scanning vapor deposition is used in the processes indicated by S4 to S7, when vapor-depositing the luminescent materials (i.e., in each of the light-emitting layer formation processes), the film formed substrate and the mask unit 50 (at least the vapor deposition mask 70) are rotated relative to each other, after which the deposition is carried out. In this example, too, rotating at least one of the mask unit 50 and the TFT substrate 10 (the TFT substrate 10A) relative to the other, within the same plane, from the state in the previous light-emitting layer formation process makes it possible to ensure the longer direction of the openings in the vapor deposition mask 70 matches the scanning direction, and makes it possible to carry out linear deposition in the desired direction.

### Example 2: Defining Layering Order of Function Layers in Light-Emitting Layer Unit

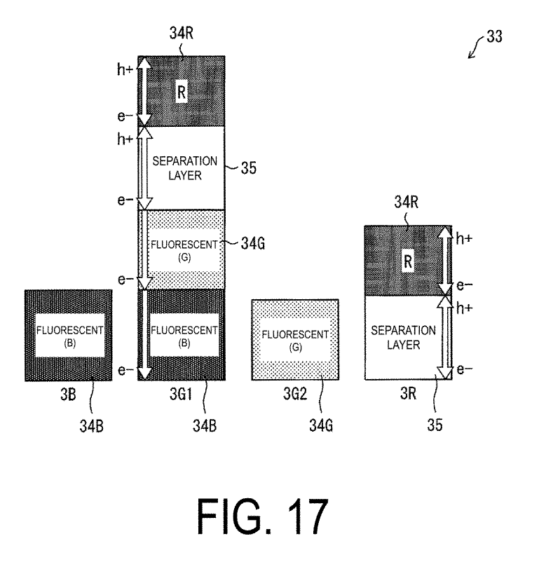

FIG. 17 is a diagram schematically illustrating the layered structure of the light-emitting layer unit 33 of another organic EL display device 1 according to the present embodiment.

In the example illustrated in FIG. 17, the light-emitting layer unit 33 has the blue fluorescent light-emitting layer 34B, the green fluorescent light-emitting layer 34G, the separation layer 35 (the first intermediate layer), and the red light-emitting layer 34R layered, in that order from the first electrode 21 side, between the first electrode 21 and the second electrode 23.

In other words, in this example, the layering order in the light-emitting layer unit 33 is reversed from the order in Embodiments 1 to 3. Thus in this example, an electron transporting material is used for at least one, and desirably both, of the material in the green fluorescent light-emitting layer 34G having the highest content percentage and the material in the blue fluorescent light-emitting layer 34B having the highest content percentage.

Additionally, in this example, a bipolar transporting material or an electron transporting material is used for the red light-emitting layer 34R. However, a material having bipolar transport properties as a whole is used for the separation layer 35.

Additionally, the thickness of the blue fluorescent light-emitting layer 34B is preferably set to less than or equal to 10 nm, for the same reasons as those described in Embodiment 1.

Additionally, in this example, it is preferable, for the same reasons as those described in Embodiment 1, that part of the PL emission spectrum of the blue fluorescent luminescent material overlap with part of the absorption spectrum of the green fluorescent luminescent material. It is also preferable that there is no overlapping between the absorption spectrum of the material of the separation layer 35 and the PL emission spectrum of the fluorescent luminescent material of at least the light-emitting layer, among the blue fluorescent light-emitting layer 34B and the green fluorescent light-emitting layer 34G provided on the opposite side of the separation layer 35 from the red light-emitting layer 34R, that is adjacent to the separation layer 35 (the green fluorescent light-emitting layer 34G, in this example), and further preferable that there is no overlapping between the PL emission spectrum of the green fluorescent luminescent material and the PL emission spectrum of the blue fluorescent luminescent material.

Additionally, in this example too, it is preferable that at least one of the blue fluorescent luminescent material and the green fluorescent luminescent material, and desirably both, be a TADF material, for the same reasons as those described above in Example 1 defining the layering order of the function layers in the light-emitting layer unit of the present embodiment.

In this example too, as in Embodiments 1 to 3, excitons are generated in the blue fluorescent light-emitting layer 34B in the subpixel 3B, excitons are generated in the green fluorescent light-emitting layer 34G in the subpixel 3G2, and excitons are generated in the red light-emitting layer 34R in the subpixel 3R. In the subpixel 3G1, whether excitons are generated in the blue fluorescent light-emitting layer 34B or in the green fluorescent light-emitting layer 34G is determined by the relationship between the carrier mobility of the material in the blue fluorescent light-emitting layer 34B having the highest content percentage and the carrier mobility of the material in the green fluorescent light-emitting layer 34G having the highest content percentage.

As described above, in this example, the layering order in the light-emitting layer unit 33 is reversed from the order in Embodiments 1 to 3. Excitons are therefore generated in the blue fluorescent light-emitting layer 34B when an electron transporting material is used for both the material in the green fluorescent light-emitting layer 34G having the highest content percentage and the material in the blue fluorescent light-emitting layer 34B having the highest content percentage, as illustrated in FIG. 17. Thus in this case, it is desirable that a TADF material be used for at least the blue fluorescent luminescent material, for the same reasons as those described above in Example 1 defining the layering order of the function layers in the light-emitting layer unit of the present embodiment.

In the manufacturing method for the organic EL display device 1 according to this example, the processes indicated by S4 to S7 in the organic EL element preparation process illustrated in FIG. 10 are carried out in the order of the blue fluorescent light-emitting layer formation process (S7), the green fluorescent light-emitting layer formation process (S6), the separation layer formation process (S5), and the red light-emitting layer formation process (S4). Accordingly, the organic EL display device 1 having the above-described layered structure can be manufactured. Examples defining dimensions, materials, and the mixing ratio of materials will be described below.

### Example 3: Defining Dimensions, Materials, and Mixing Ratio of Materials

Reflective electrode 21a (first electrode 21; anode electrode): Ag (100 nm)

Light-transmissive electrode 21b (first electrode 21, anode electrode): ITO (subpixel 3B: 135 nm/subpixel 3G1: 135 nm/subpixel 3G2: 165 nm/subpixel 3R: 40 nm)

Hole injection layer 31: HAT-CN (10 nm)

Hole transport layer 32: TCTA (20 nm)

Blue fluorescent light-emitting layer 34B: DPEPO (host material, 90%)/DMAC-DPS (blue fluorescent luminescent material, 10%) (10 nm)

Green fluorescent light-emitting layer 34G: BCP (host material, 90%)/coumarin 6 (green fluorescent luminescent material, 10%) (10 nm)

Separation layer 35: CBP (20 nm)

Red light-emitting layer 34R: CBP (host material 90%)/Ir(piq)3 (red luminescent material, 10%) (10 nm)

Electron transport layer 36: BCP (30 nm)

Electron injection layer 37: LiF (1 nm)

Second electrode 23 (cathode electrode, semitransparent electrode): Ag—Mg alloy (Ag/Mg mixing ratio=0.9/0.1) (20 nm)

Protection layer 24: ITO (80 nm)

In this example, the layering order in the light-emitting layer unit 33 is reversed from that in Embodiments 1 to 3 as described above. As such, using an electron transporting material for at least one, and desirably both, of the material in the green fluorescent light-emitting layer 34G having the highest content percentage and the material in the blue fluorescent light-emitting layer 34B having the highest content percentage makes it difficult for color mixing to arise, and thus the light emitting efficiency can be improved.

Thus in a case where a host material having good compatibility with the dopant material, which can improve the light emitting efficiency of the dopant material, a host material having a high S₁ level or T₁ level, which can suppress a drop in efficiency caused by energy transfer to the host material, is an electron transporting material, using the above-described layering order in the light-emitting layer unit 33 makes it possible to provide an organic EL display device 1 having better properties.

With respect to the recent state of development in the organic EL display device industry, host materials having hole transport properties can be synthesized more easily and have a wider range of types that host materials having electron transport properties, and have undergone much more development. Selecting a host material having electron transport properties as the host material therefore makes it easier to obtain a material having favorable properties than when selecting a host material having hole transport properties.

In reality, electron transporting materials having extremely high electron mobility are better known than hole transporting materials having extremely high hole mobility. Host materials having electron transport properties thus tend to have lower voltages than host materials having hole transport properties seen in the current market. Thus the organic EL display device 1 according to this example can be expected to achieve lower voltages than the organic EL display devices 1 according to Embodiments 1 to 3 and the above-described Example 1 defining the layering order of the function layers in the light-emitting layer unit of the present embodiment.

Additionally, in this example, when forming the blue fluorescent light-emitting layer 34B in common for the subpixel 3B and the subpixel 3G1 through linear deposition, even if the blue fluorescent light-emitting layer 34B infiltrates into the subpixel 3G2 and the blue fluorescent light-emitting layer 34B is formed below the green fluorescent light-emitting layer 34G (i.e., on the first electrode 21 side), energy is transferred from the blue fluorescent luminescent material to the green fluorescent luminescent material, and thus no blue color mixing will occur in the subpixel 3G2.

Additionally, in this example, the red light-emitting layer 34R is located furthest on the cathode electrode side (i.e., the second electrode 23 side) in the light-emitting layer unit 33, and the red light-emitting layer formation process (S4) is carried out after the blue fluorescent light-emitting layer formation process (S7) and the green fluorescent light-emitting layer formation process (S6).

Thus according to this example, when forming the red light-emitting layer 34R in common for the subpixel 3G1 and the subpixel 3R through linear deposition, even if the red light-emitting layer 34R has infiltrated into the subpixel 3B and the red light-emitting layer 34R has been formed above the blue fluorescent light-emitting layer 34B (i.e., on the second electrode 23 side), holes will not reach the red light-emitting layer 34R, and red color mixing will therefore not arise in the subpixel 3B, as long as the material in the blue fluorescent light-emitting layer 34B having the highest content percentage is an electron transporting material.

Likewise, when forming the red light-emitting layer 34R in common for the subpixel 3G1 and the subpixel 3R, even if the red light-emitting layer 34R has infiltrated into the subpixel 3G2 and the red light-emitting layer 34R has been formed above the green fluorescent light-emitting layer 34G, holes will not reach the red light-emitting layer 34R, and red color mixing will therefore not arise in the subpixel 3G2, as long as the material in the green fluorescent light-emitting layer 34G having the highest content percentage is an electron transporting material.

Thus according to this example, using an electron transporting material for both the material in the blue fluorescent light-emitting layer 34B having the highest content percentage and the material in the green fluorescent light-emitting layer 34G having the highest content percentage makes it possible to achieve a configuration in which color mixing does not easily arise even if even a minute amount of the red luminescent material infiltrates into another subpixel 3 (i.e., at least one of the subpixel 3B and the subpixel 3G2) when depositing the red light-emitting layer 34R.

Additionally, in this example, in the case where scanning vapor deposition is used in the processes indicated by S4 to S7, when vapor-depositing the luminescent materials (i.e., in each of the light-emitting layer formation processes), the film formed substrate and the mask unit 50 (at least the vapor deposition mask 70) are rotated relative to each other, after which the deposition is carried out. In this example, too, rotating at least one of the mask unit 50 and the TFT substrate 10 (the TFT substrate 10A) relative to the other, within the same plane, from the state in the previous light-emitting layer formation process makes it possible to ensure the longer direction of the openings in the vapor deposition mask 70 matches the scanning direction, and makes it possible to carry out linear deposition in the desired direction.

### Example 3: Defining Layering Order of Function Layers in Light-Emitting Layer Unit

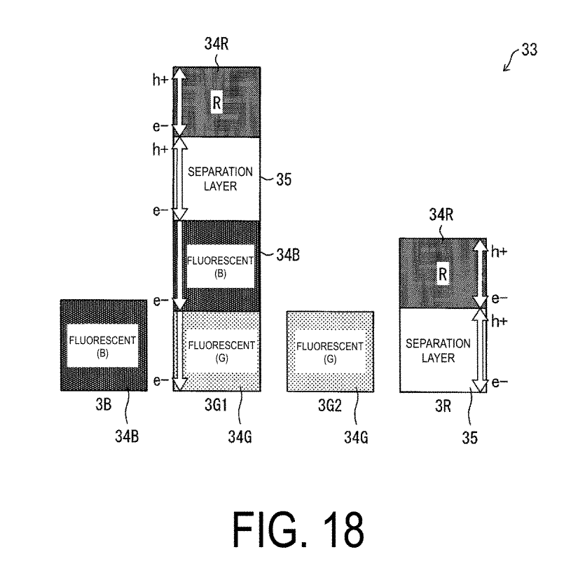

FIG. 18 is a diagram schematically illustrating the layered structure of the light-emitting layer unit 33 of yet another organic EL display device 1 according to the present embodiment.

In the example illustrated in FIG. 18, the light-emitting layer unit 33 has the green fluorescent light-emitting layer 34G, the blue fluorescent light-emitting layer 34B, the separation layer 35 (the first intermediate layer), and the red light-emitting layer 34R layered, in that order from the first electrode 21 side, between the first electrode 21 and the second electrode 23.

In other words, in this example, the layering order of the blue fluorescent light-emitting layer 34B and the green fluorescent light-emitting layer 34G in the subpixel 3G1 is reversed from that in the organic EL display device 1 according to the above-described Example 2 defining the layering order of the function layers in the light-emitting layer unit of the present embodiment, and the green fluorescent light-emitting layer 34G is located closer to the second electrode 23, which is a cathode electrode, than the blue fluorescent light-emitting layer 34B.

In this example, the blue fluorescent light-emitting layer 34B and the red light-emitting layer 34R are adjacent in the layering direction, with the separation layer 35 interposed therebetween, as illustrated in FIG. 18. Thus in this example, as in the above-described Example 1 defining the layering order of the function layers in the light-emitting layer unit according to the embodiment, the distance between opposing surfaces of the blue fluorescent light-emitting layer 34B and the red light-emitting layer 34R (the opposing surface distance D_{BR}), i.e., a distance between the surface of the blue fluorescent light-emitting layer 34B located furthest on the red light-emitting layer 34R side (an upper surface of the blue fluorescent light-emitting layer 34B, in the present embodiment) and the surface of the red light-emitting layer 34R located furthest on the blue fluorescent light-emitting layer 34B side (a lower surface of the red light-emitting layer 34R, in the present embodiment), which is equal to the thickness of the separation layer 35, is set to a distance exceeding the Förster radius. Note that in this example too, like the opposing surface distance D_{GR}, the opposing surface distance D_{BR} is preferably greater than or equal to 15 nm and less than or equal to 50 nm, and more preferably greater than or equal to 15 nm and less than or equal to 30 nm.

Also, like in the above-described Example 2 defining the layering order of the function layers in the light-emitting layer unit according to the present embodiment, in this example too, it is preferable that an electron transporting material be used for the material of at least one, and desirably both, of the material in the green fluorescent light-emitting layer 34G having the highest content percentage and the material in the blue fluorescent light-emitting layer 34B having the highest content percentage. Note that in this example too, a bipolar transporting material or a hole transporting material is used for the red light-emitting layer 34R, and a material having bipolar transport properties as a whole is used for the intermediate layer such as the separation layer 35 and the like.

In this example too, the thickness of the blue fluorescent light-emitting layer 34B is preferably set to less than or equal to 10 nm, for the same reasons as those described in Embodiment 1.

Additionally, in this example, it is preferable, for the same reasons as those described in Embodiment 1, that part of the PL emission spectrum of the blue fluorescent luminescent material overlap with part of the absorption spectrum of the green fluorescent luminescent material. It is also preferable that there is no overlapping between the absorption spectrum of the material of the separation layer 35 and the PL emission spectrum of the fluorescent luminescent material of at least the light-emitting layer, among the blue fluorescent light-emitting layer 34B and the green fluorescent light-emitting layer 34G provided on the opposite side of the separation layer 35 from the red light-emitting layer 34R, that is adjacent to the separation layer 35 (the blue fluorescent light-emitting layer 34B, in this example), and further preferable that there is no overlapping between the PL emission spectrum of the green fluorescent luminescent material and the PL emission spectrum of the blue fluorescent luminescent material.

Additionally, the organic EL display device 1 according to this example has a configuration in which, in the above-described Example 2 defining the layering order of the function layers in the light-emitting layer unit according to the present embodiment, the layering order of the blue fluorescent light-emitting layer 34B and the green fluorescent light-emitting layer 34G is reversed in the subpixel 3G1, as described above. On the other hand, the organic EL display device 1 according to this example can be said to have the same configuration as the organic EL display device 1 according to the above-described Example 1 defining the layering order of the function layers in the light-emitting layer unit of the present embodiment, aside from the following: that the layering order of the light-emitting layer unit 33 is reversed from the layering order in the organic EL display device 1 according to the above-described Example 1 defining the layering order of the function layers in the light-emitting layer unit; that an electron transporting material is used for at least one, and desirably both, of the material in the green fluorescent light-emitting layer 34G having the highest content percentage and the material in the blue fluorescent light-emitting layer 34B having the highest content percentage; and that a bipolar transporting material or a hole transporting material is used for the red light-emitting layer 34R.

In this example, the green fluorescent light-emitting layer 34G is located further on the anode electrode side (the first electrode 21 side) than the blue fluorescent light-emitting layer 34B, which is opposite from Examples 1 and 2 defining the layering order of the function layers in the light-emitting layer unit. Thus as illustrated in FIG. 18, excitons are generated in the green fluorescent light-emitting layer 34G, as in the organic EL display device 1 according to the above-described Example 1 defining the layering order of the function layers in the light-emitting layer unit, when an electron transporting material is used for both the material in the blue fluorescent light-emitting layer 34B having the highest content percentage and the material in the green fluorescent light-emitting layer 34G having the highest content percentage.

Thus according to the organic EL display device 1 illustrated in FIG. 18, it is desirable that a TADF material be used for both the blue fluorescent luminescent material and the green fluorescent luminescent material, for the same reasons as those described above in Example 1 defining the layering order of the function layers in the light-emitting layer unit.

Of course, in this example too, whether excitons are generated in the blue fluorescent light-emitting layer 34B or in the green fluorescent light-emitting layer 34G in the subpixel 3G1 is determined by the relationship between the carrier mobility of the material in the blue fluorescent light-emitting layer 34B having the highest content percentage and the carrier mobility of the material in the green fluorescent light-emitting layer 34G having the highest content percentage. Thus this example is not limited to the above-described configuration, and at least one of the blue fluorescent luminescent material and the green fluorescent luminescent material may be a TADF material.

In the manufacturing method for the organic EL display device 1 according to this example, the processes indicated by S4 to S7 in the organic EL element preparation process illustrated in FIG. 10 are carried out in the order of the blue fluorescent light-emitting layer formation process (S7), the separation layer formation process (S5), and the red light-emitting layer formation process (S4). Accordingly, the organic EL display device 1 having the above-described layered structure can be manufactured. Examples defining dimensions, materials, and the mixing ratio of materials will be described below.

### Example 4: Defining Dimensions, Materials, and Mixing Ratio of Materials

Reflective electrode 21a (first electrode 21; anode electrode): Ag (100 nm)

Light-transmissive electrode 21b (first electrode 21, anode electrode): ITO (subpixel 3B: 135 nm/subpixel 3G1: 135 nm/subpixel 3G2: 165 nm/subpixel 3R: 40 nm)

Hole injection layer 31: HAT-CN (10 nm)

Hole transport layer 32: TCTA (20 nm)

Green fluorescent light-emitting layer 34G: BCP (host material, 90%)/4CzIPN (green fluorescent luminescent material, 10%) (10 nm)

Blue fluorescent light-emitting layer 34B: DPEPO (host material, 90%)/DMAC-DPS (blue fluorescent luminescent material, 10%) (10 nm)

Separation layer 35: CBP (20 nm)

Red light-emitting layer 34R: CBP (host material 90%)/Ir(piq)3 (red luminescent material, 10%) (10 nm)

Electron transport layer 36: BCP (30 nm)

Electron injection layer 37: LiF (1 nm)

Second electrode 23 (cathode electrode, semitransparent electrode): Ag—Mg alloy (Ag/Mg mixing ratio=0.9/0.1) (20 nm)

Protection layer 24: ITO (80 nm)

According to this example, in the subpixel 3G1, the green fluorescent light-emitting layer 34G is located furthest on the anode electrode side (i.e., the first electrode 21 side) within the light-emitting layer unit 33, as illustrated in FIG. 18. Accordingly, in a case as described above the carrier mobility provides electron transport properties in at least one of the material in the green fluorescent light-emitting layer 34G having the highest content percentage (DPEPO, which is the host material in Example 4 defining dimensions, materials, and the mixing ratio of materials) and the material in the blue fluorescent light-emitting layer 34B having the highest content percentage (BCP, which is the host material in Example 4 defining dimensions, materials, and the mixing ratio of materials), the probability that excitons will be generated in the green fluorescent light-emitting layer 34G increases, and the light emitting efficiency is improved.

Even if excitons are generated in the blue fluorescent light-emitting layer 34B, setting the thickness of the blue fluorescent light-emitting layer 34B to less than or equal to 10 nm as described above shortens the distance from the location where the excitons are generated to the green fluorescent light-emitting layer 34G. This is expected to improve the probability that Förster transfer will arise, improve the color level, and improve the light emitting efficiency.

Additionally, according to this example, when forming the blue fluorescent light-emitting layer 34B in common for the subpixel 3B and the subpixel 3G1 through linear deposition, even if the blue fluorescent light-emitting layer 34B has infiltrated into the subpixel 3G2 and the blue fluorescent light-emitting layer 34B has been formed above the green fluorescent light-emitting layer 34G (i.e., on the second electrode 23 side), energy is transferred from the blue fluorescent luminescent material to the green fluorescent luminescent material, and thus blue color mixing will not arise in the subpixel 3G2.

Additionally, in this example, the red light-emitting layer 34R is located furthest on the cathode electrode side (i.e., the second electrode 23 side) within the light-emitting layer unit 33, as in the above-described Example 2 defining the layering order of the function layers in the light-emitting layer unit. The red light-emitting layer formation process (S4) is carried out after the green fluorescent light-emitting layer formation process (S6) and the blue fluorescent light-emitting layer formation process (S7).

Thus according to this example, when forming the red light-emitting layer 34R in common for the subpixel 3G1 and the subpixel 3R through linear deposition, even if the red light-emitting layer 34R has infiltrated into the subpixel 3B and the red light-emitting layer 34R has been formed above the blue fluorescent light-emitting layer 34B (i.e., on the second electrode 23 side), holes will not reach the red light-emitting layer 34R, and red color mixing will therefore not arise in the subpixel 3B, as long as the material in the blue fluorescent light-emitting layer 34B having the highest content percentage is an electron transporting material.

Likewise, when forming the red light-emitting layer 34R in common for the subpixel 3G1 and the subpixel 3R, even if the red light-emitting layer 34R has infiltrated into the subpixel 3G2 and the red light-emitting layer 34R has been formed above the green fluorescent light-emitting layer 34G, holes will not reach the red light-emitting layer 34R, and red color mixing will therefore not arise in the subpixel 3G2, as long as the material in the green fluorescent light-emitting layer 34G having the highest content percentage is an electron transporting material.

Thus like the above-described Example 2 defining the layering order of the function layers in the light-emitting layer unit, according to this example too, using an electron transporting material for both the material in the blue fluorescent light-emitting layer 34B having the highest content percentage and the material in the green fluorescent light-emitting layer 34G having the highest content percentage makes it possible to achieve a configuration in which color mixing does not easily arise even if even a minute amount of the red luminescent material infiltrates into another subpixel 3 (i.e., at least one of the subpixel 3B and the subpixel 3G2) when depositing the red light-emitting layer 34R.

Additionally, according to this example too, in a case where a host material having good compatibility with the dopant material, a host material having a high S₁ level or T₁ level, which can suppress a drop in efficiency caused by energy transfer to the host material, or the like, is an electron transporting material, using the above-described layering order as the layering order in the light-emitting layer unit 33 makes it possible to provide an organic EL display device 1 having better properties, like the above-described Example 2 defining the layering order of the function layers in the light-emitting layer unit.

Furthermore, as described above in Example 2 defining the layering order of the function layers in the light-emitting layer unit, selecting a host material having electron transport properties as the host material makes it easy to obtain a material having better properties than a host material having hole transport properties. Host materials having electron transport properties also tend to have lower voltages than host materials having hole transport properties seen in the current market. Thus the organic EL display device 1 according to this example can be expected to achieve lower voltages than the organic EL display devices 1 according to Embodiments 1 to 3 and the above-described Example 1 defining the layering order of the function layers in the light-emitting layer unit, in the same manner as the organic EL display device 1 according to the above-described Example 2 defining the layering order of the function layers in the light-emitting layer unit.

Additionally, in this example, in the case where scanning vapor deposition is used in the processes indicated by S4 to S7, when vapor-depositing the luminescent materials (i.e., in each of the light-emitting layer formation processes), the film formed substrate and the mask unit 50 (at least the vapor deposition mask 70) are rotated relative to each other, after which the deposition is carried out. In this example, too, rotating at least one of the mask unit 50 and the TFT substrate 10 (the TFT substrate 10A) relative to the other, within the same plane, from the state in the previous light-emitting layer formation process makes it possible to ensure the longer direction of the openings in the vapor deposition mask 70 matches the scanning direction, and makes it possible to carry out linear deposition in the desired direction.

### Other Modified Examples

Embodiments 1 to 3 and the present embodiment describe, as an example, a case where the organic EL display device 1 is a top-emitting display device in which the light from the light-emitting layer unit 33 is emitted from the sealing substrate 40 side. However, the light-emission direction of the organic EL display device 1 may be on the first electrode 21 side or on the second electrode 23 side. Accordingly, the organic EL display device 1 may be a bottom-emitting organic EL display device in which the light from the light-emitting layer unit 33 is emitted from the first electrode 21 side, i.e., the TFT substrate 10 side. In this case, the first electrode 21 may be a transparent electrode, and instead of providing the protection layer 24, a reflective electrode thicker than the second electrode 23 (the semitransparent electrode) in the case where the organic EL display device 1 is a top-emitting display device may be used as the second electrode 23.

Note that when the organic EL display device 1 is a bottom-emitting device, an insulating substrate that is transparent, called a transparent substrate or a light-transmitting substrate, such as a glass substrate or a plastic substrate, is used as the insulating substrate 11.

Additionally, when the organic EL display device 1 is a bottom-emitting device, the light from the light-emitting layer unit 33 is emitted from the light-transmissive electrode side directly from the light-transmissive electrode side, or having been reflected by the reflective electrode. The light-transmissive electrode material, the reflective electrode material, and the like described above can be used as the materials of the light-transmissive electrode and the reflective electrode.

In the subpixel 3G1, in a case where, when energy is transferred from the blue fluorescent luminescent material in the blue fluorescent light-emitting layer 34B to the green fluorescent luminescent material in the green fluorescent light-emitting layer 34G, molecules of the blue fluorescent luminescent material and molecules of the green fluorescent luminescent material come into direct contact, it is possible that Dexter transfer between T₁ levels will arise and deactivation will occur as heat without light being emitted.

Accordingly, a blocking layer (not illustrated) may be provided between the blue fluorescent light-emitting layer 34B and the green fluorescent light-emitting layer 34G in the subpixel 3G1, the blocking layer lacking a luminescent material, and having a thickness less than or equal to the Förster radius so as to inhibit Dexter transfer from the blue fluorescent luminescent material in the blue fluorescent light-emitting layer 34B to the green fluorescent luminescent material in the green fluorescent light-emitting layer 34G.

The blocking layer has a thickness less than or equal to the Förster radius, and thus in the subpixel 3G1, Förster transfer from the blue fluorescent luminescent material to the green fluorescent luminescent material is not inhibited, but Dexter transfer is inhibited. Accordingly, providing the thin blocking layer, constituted by any desired material, between the blue fluorescent light-emitting layer 34B and the green fluorescent light-emitting layer 34G in the subpixel 3G1 makes it possible to improve the light emitting efficiency of the green fluorescent luminescent material in the subpixel 3G1.

The thickness of the blocking layer is equal to the opposing surface distance D_{BG}, and it is therefore necessary to set the thickness to be less than or equal to the Förster radius. To reliably ensure Förster transfer, the blocking layer is preferably formed as thin as possible. The thickness of the blocking layer is therefore preferably less than or equal to 10 nm, and more preferably less than or equal to 5 nm.

The blocking layer may be provided as a common layer for the subpixel 3B and the subpixel 3G1, or may be provided as a common layer for the subpixel 3G1 and the subpixel 3G2.

When the blocking layer is provided as a common layer for the subpixel 3B and the subpixel 3G1, the vapor deposition mask 70B or a dedicated vapor deposition mask having the same pattern as the vapor deposition mask 70B can be used to form the blocking layer, in the same manner as when forming the blue fluorescent light-emitting layer 34B.

Additionally, when the blocking layer is provided as a common layer for the subpixel 3G1 and the subpixel 3G2, the vapor deposition mask 70G or a dedicated vapor deposition mask having the same pattern as the vapor deposition mask 70G can be used to form the blocking layer, in the same manner as when forming the green fluorescent light-emitting layer 34G.

The separation layer 35 may be formed from a plurality of layers having different carrier transport properties.

Although a slitted mask will be unable to be used to form the separation layer 35, the separation layer 35 may be formed selectively in the subpixel 3G1. In other words, the separation layer 35 may be provided only between the red light-emitting layer 34R, and the green fluorescent light-emitting layer 34G or the blue fluorescent light-emitting layer 34B layered adjacent to the red light-emitting layer 34R, in the subpixel 3G1.

### Supplement

A manufacturing method for a display device (e.g., the organic EL display device 1) according to Aspect 1 of the disclosure is a manufacturing method for a display device, the display device including: a substrate (the TFT substrate 10, 10A) having a display region (the display region 1a) in which a plurality of pixels (the pixels 2) are arranged, each pixel including a first subpixel (e.g., the subpixel 3B), a second subpixel (e.g., the subpixel 3G1), a third subpixel (e.g., the subpixel 3G2), and a fourth subpixel (e.g., the subpixel 3R), wherein the first subpixel and the second subpixel are arranged in an alternating manner in a first direction (e.g., a row direction); the third subpixel and the fourth subpixel are arranged in an alternating manner in the first direction; a column constituted by the first subpixel and the second subpixel, and a column constituted by the third subpixel and the fourth subpixel, are arranged in an alternating manner in a second direction (e.g., the column direction) orthogonal to the first direction; in the first subpixel, a first fluorescent luminescent material emits light, and the light emitted from the first fluorescent luminescent material is emitted to the exterior; in the second subpixel and the third subpixel, a second fluorescent luminescent material emits light, and the light emitted from the second fluorescent luminescent material is emitted to the exterior; in the fourth subpixel, a third luminescent material emits light, and the light emitted from the third luminescent material is emitted to the exterior; the first fluorescent luminescent material emits light having a first peak wavelength; the second fluorescent luminescent material emits light having a second peak wavelength longer than the first peak wavelength; and the third luminescent material emits light having a third peak wavelength longer than the second peak wavelength; and an energy level (S₁ level) of the second fluorescent luminescent material in a minimum excited singlet state is lower than an energy level of the first fluorescent luminescent material in a minimum excited singlet state and higher than an energy level of the third luminescent material in a minimum excited singlet state, the method including: a function layer formation step of forming a plurality of function layers (e.g., the hole injection layer 31, the hole transport layer 32, the blue fluorescent light-emitting layer 34B, the green fluorescent light-emitting layer 34G, the red light-emitting layer 34R, the separation layer 35, the electron transport layer 36, the electron injection layer 37, the blocking layer, and the like) constituted by vapor deposition particles on the substrate by vapor-depositing vapor deposition particles corresponding to the respective function layers on the substrate through vapor deposition masks (e.g., the vapor deposition masks 70, 70R, 70G, and 70B) in which are formed a plurality of mask openings (e.g., the openings 71, 71R, 71G, and 71B) having predetermined opening patterns corresponding to the respective function layers, wherein the function layer formation step includes: a first light-emitting layer formation step of forming a first light-emitting layer containing the first fluorescent luminescent material (e.g., the blue fluorescent light-emitting layer 34B) in common for the first subpixel and the second subpixel; a second light-emitting layer formation step of forming a second light-emitting layer containing the second fluorescent luminescent material (e.g., the green fluorescent light-emitting layer 34G) in common for the second subpixel and the third subpixel; a third light-emitting layer formation step of forming a third light-emitting layer containing the third luminescent material (e.g., the red light-emitting layer 34R) in common for the second subpixel and the fourth subpixel; and a separation layer formation step of forming a separation layer (the separation layer 35) in the second subpixel so that in the second subpixel, the separation layer, which inhibits Förster-type energy transfer, is layered between the third light-emitting layer and the light-emitting layer, of the first light-emitting layer and the second light-emitting layer, that is located closer to the third light-emitting layer, and in the function layer formation step: the first light-emitting layer and the second light-emitting layer are formed so that in the second subpixel, a distance between opposing surfaces of the first light-emitting layer and the second light-emitting layer is less than or equal to the Förster radius; and in at least two light-emitting layer formation steps among the first light-emitting layer formation step, the second light-emitting layer formation step, and the third light-emitting layer formation step, the vapor deposition particles are linearly deposited on the substrate using, as the vapor deposition mask, a slitted mask including slit-shaped mask openings provided so that the mask openings span a plurality of the pixels.

As a manufacturing method for a display device according to Aspect 2 of the disclosure, in Aspect 1, the display device may have a PenTile pixel arrangement in which the second subpixel and the fourth subpixel are adjacent, and the third subpixel and the first subpixel are adjacent, in the second direction, and the first subpixel and the fourth subpixel are adjacent, and the second subpixel and the third subpixel are adjacent, in a third direction intersecting with the first direction and the second direction; in the first light-emitting layer formation step, the first fluorescent luminescent material may be linearly-deposited in a direction connecting the first subpixel and the second subpixel adjacent in the first direction; in the second light-emitting layer formation step, the second fluorescent luminescent material may be linearly-deposited in a direction connecting the second subpixel and the third subpixel adjacent in the third direction; and in the third light-emitting layer formation step, the third luminescent material may be linearly-deposited in a direction connecting the second subpixel and the fourth subpixel adjacent in the second direction.

As a manufacturing method for a display device according to Aspect 3 of the disclosure, in Aspect 2, in the at least two light-emitting layer formation steps, using a mask unit (50), which includes a slitted mask having a smaller area than the substrate as the slitted mask and a vapor deposition source (60) that emits vapor deposition particles (91), and in which the relative positions of the vapor deposition mask and the vapor deposition source are fixed, the vapor deposition particles may be linearly-deposited on the substrate through the slitted mask by moving at least one of the mask unit and the substrate relative to the other while scanning the substrate with the slitted mask and the substrate arranged opposing each other with a set gap provided therebetween; and in a light-emitting layer formation step, of the first to third light-emitting layer formation steps, that is not the light-emitting layer formation step carried out first, the linear deposition may be carried out after rotating at least one of the substrate and the slitted mask relative to the other within the same plane from the state in the previous light-emitting layer formation step.

As a manufacturing method for a display device according to Aspect 4 of the disclosure, in Aspect 3, the at least two light-emitting layer formation steps may include the second light-emitting layer formation step; the third direction may be an oblique direction (e.g., the diagonal line direction) forming a 45-degree angle with one side or an axis of the substrate; in the second light-emitting layer formation step, the substrate may be arranged so that a longer direction of the mask openings in the slitted mask is a direction parallel to the oblique direction; and at least one of the mask unit and the substrate may be moved relative to the other in the direction parallel to the oblique direction.

As a manufacturing method for a display device according to Aspect 5 of the disclosure, in Aspect 1, the display device may have an S-Stripe pixel arrangement in which the first subpixel and the fourth subpixel are adjacent, and the second subpixel and the third subpixel are adjacent, in the second direction; in the first light-emitting layer formation step, the first fluorescent luminescent material may be linearly-deposited in a direction connecting the first subpixel and the second subpixel adjacent in the first direction; in the second light-emitting layer formation step, the second fluorescent luminescent material may be linearly-deposited in a direction connecting the second subpixel and the third subpixel adjacent in the second direction; and in the third light-emitting layer formation step, the third luminescent material may be linearly-deposited in a direction connecting the second subpixel and the fourth subpixel adjacent in a third direction (the oblique direction) intersecting with both the first direction and the second direction.

As a manufacturing method for a display device according to Aspect 6 of the disclosure, in Aspect 5, in the at least two light-emitting layer formation steps, using a mask unit (50), which includes a slitted mask having a smaller area than the substrate as the slitted mask and a vapor deposition source (60) that emits vapor deposition particles (91), and in which the relative positions of the vapor deposition mask and the vapor deposition source are fixed, the vapor deposition particles may be linearly-deposited on the substrate through the slitted mask by moving at least one of the mask unit and the substrate relative to the other while scanning the substrate with the slitted mask and the substrate arranged opposing each other with a set gap provided therebetween; and in a light-emitting layer formation step, of the first to third light-emitting layer formation steps, that is not the light-emitting layer formation step carried out first, the linear deposition may be carried out after rotating at least one of the substrate and the slitted mask relative to the other within the same plane from the state in the previous light-emitting layer formation step.

As a manufacturing method for a display device according to Aspect 7 of the disclosure, in Aspect 6, the at least two light-emitting layer formation steps may include the third light-emitting layer formation step; the third direction may be an oblique direction (e.g., the diagonal line direction) forming a 45-degree angle with one side or an axis of the substrate; in the third light-emitting layer formation step, the substrate may be arranged so that a longer direction of the mask openings in the slitted mask is a direction parallel to the oblique direction; and at least one of the mask unit and the substrate may be moved relative to the other in the direction parallel to the oblique direction.

As a manufacturing method for a display device according to Aspect 8 of the disclosure, in any one of Aspects 1 to 7, in the separation layer formation step, the separation layer may be formed in common for the second subpixel and the fourth subpixel using a vapor deposition mask having the same opening pattern as the vapor deposition mask used to form the third light-emitting layer (e.g., the vapor deposition mask 70R, or a vapor deposition mask specifically for forming the separation layer, which has the same opening pattern as the vapor deposition mask 70R).

As a manufacturing method for a display device according to Aspect 9 of the disclosure, in Aspect 7, the slitted mask may be used as the vapor deposition mask in each of the first light-emitting layer formation step, the second light-emitting layer formation step, the third light-emitting layer formation step, and the separation layer formation step.

As a manufacturing method for a display device according to Aspect 10 of the disclosure, any one of Aspects 1 to 9 may further include: an anode electrode formation step of forming an anode electrode (e.g., the first electrode 21); and a cathode electrode formation step of forming a cathode electrode (e.g., the second electrode 23), wherein one of the anode electrode and the cathode electrode may include a reflective electrode (e.g., the reflective electrode 21a), and the other may be a light-transmissive electrode.

As a manufacturing method for a display device according to Aspect 11 of the disclosure, in Aspect 10, the function layer formation step may be carried out after the anode electrode formation step and before the cathode electrode formation step; and in the function layer formation step, the third light-emitting layer formation step, the separation layer formation step, the second light-emitting layer formation step, and the first light-emitting layer formation step may be carried out in that order, and a hole transporting material may be used for at least one of the material contained in the first light-emitting layer having the highest combination ratio and the material contained in the second light-emitting layer having the highest combination ratio.

As a manufacturing method for a display device according to Aspect 12 of the disclosure, in Aspect 10, the function layer formation step may be carried out after the anode electrode formation step and before the cathode electrode formation step; and in the function layer formation step, the third light-emitting layer formation step, the separation layer formation step, the first light-emitting layer formation step, and the second light-emitting layer formation step may be carried out in that order, and a hole transporting material may be used for at least one of the material contained in the first light-emitting layer having the highest combination ratio and the material contained in the second light-emitting layer having the highest combination ratio.

As a manufacturing method for a display device according to Aspect 13 of the disclosure, in Aspect 10, the function layer formation step may be carried out after the anode electrode formation step and before the cathode electrode formation step; and in the function layer formation step, the first light-emitting layer formation step, the second light-emitting layer formation step, the separation layer formation step, and the third light-emitting layer formation step may be carried out in that order, and an electron transporting material may be used for at least one of the material contained in the first light-emitting layer having the highest combination ratio and the material contained in the second light-emitting layer having the highest combination ratio.

As a manufacturing method for a display device according to Aspect 14 of the disclosure, in Aspect 10, the function layer formation step may be carried out after the anode electrode formation step and before the cathode electrode formation step; and in the function layer formation step, the second light-emitting layer formation step, the first light-emitting layer formation step, the separation layer formation step, and the third light-emitting layer formation step may be carried out in that order, and an electron transporting material may be used for at least one of the material contained in the first light-emitting layer having the highest combination ratio and the material contained in the second light-emitting layer having the highest combination ratio.

As a manufacturing method for a display device according to Aspect 15 of the disclosure, in any one of Aspects 1 to 14, in the separation layer formation step, the separation layer may be formed so that the separation layer has a thickness exceeding the Förster radius.

As a manufacturing method for a display device according to Aspect 16 of the disclosure, in any one of Aspects 1 to 15, in the first light-emitting layer formation step, the first light-emitting layer may be formed so that the thickness of the first light-emitting layer is less than or equal to 10 nm.

As a manufacturing method for a display device according to Aspect 17 of the disclosure, in any one of Aspects 1 to 16, in the first light-emitting layer formation step, a thermally activated delayed fluorescence material having an energy difference of less than or equal to 0.3 eV between a minimum excited singlet state and a minimum excited triplet state may be used for the first fluorescent luminescent material.

As a manufacturing method for a display device according to Aspect 18 of the disclosure, in any one of Aspects 1 to 17, in the second light-emitting layer formation step, a thermally activated delayed fluorescence material having an energy difference of less than or equal to 0.3 eV between a minimum excited singlet state and a minimum excited triplet state may be used for the second fluorescent luminescent material.

As a manufacturing method for a display device according to Aspect 19 of the disclosure, in any one of Aspects 1 to 18, the first subpixel may be a blue subpixel; the second subpixel may be a first green subpixel; the third subpixel may be a second green subpixel; the fourth subpixel may be a red subpixel; a fluorescent luminescent material that emits blue light may be used for the first fluorescent luminescent material; a fluorescent luminescent material that emits green light may be used for the second fluorescent luminescent material; and a luminescent material that emits red light may be used for the third luminescent material.

A display device (e.g., the organic EL display device 1) according Aspect 20 of the disclosure includes: a substrate (the TFT substrate 10, 10A) having a display region (the display region 1a) in which a plurality of pixels (the pixels 2) are arranged, each pixel including a first subpixel (e.g., the subpixel 3B), a second subpixel (e.g., the subpixel 3G1), a third subpixel (e.g., the subpixel 3G2), and a fourth subpixel (e.g., the subpixel 3R), wherein the first subpixel and the second subpixel are arranged in an alternating manner in a first direction (e.g., a row direction); the third subpixel and the fourth subpixel are arranged in an alternating manner in the first direction; a column constituted by the first subpixel and the second subpixel, and a column constituted by the third subpixel and the fourth subpixel, are arranged in an alternating manner in a second direction (e.g., the column direction) orthogonal to the first direction; a first light-emitting layer containing a first fluorescent luminescent material (e.g., the blue fluorescent light-emitting layer 34B) is provided in common for the first subpixel and the second subpixel; a second light-emitting layer containing a second fluorescent luminescent material (e.g., the green fluorescent light-emitting layer 34G) is provided in common for the second subpixel and the third subpixel; a third light-emitting layer containing a third luminescent material (e.g., the red light-emitting layer 34R) is provided in common for the second subpixel and the fourth subpixel; at least two light-emitting layers among the first light-emitting layer, the second light-emitting layer, and the third light-emitting layer include a light-emitting layer provided spanning a plurality of pixels; an energy level (S₁ level) of the second fluorescent luminescent material in a minimum excited singlet state is lower than an energy level of the first fluorescent luminescent material in a minimum excited singlet state and higher than an energy level of the third luminescent material in a minimum excited singlet state; in the second subpixel, a distance between opposing surfaces of the first light-emitting layer and the second light-emitting layer (e.g., the opposing surface distance D_{BG}) is less than or equal to a Förster radius, and a separation layer (the separation layer 35) that inhibits Förster-type energy transfer is layered between the third light-emitting layer and the light-emitting layer, of the first light-emitting layer and the second light-emitting layer, that is located closer to the third light-emitting layer; in the first subpixel, the first fluorescent luminescent material emits light, and the light emitted from the first fluorescent luminescent material is emitted to the exterior; in the second subpixel and the third subpixel, the second fluorescent luminescent material emits light, and the light emitted from the second fluorescent luminescent material is emitted to the exterior; in the fourth subpixel, the third luminescent material emits light, and the light emitted from the third luminescent material is emitted to the exterior; the first fluorescent luminescent material emits light having a first peak wavelength; the second fluorescent luminescent material emits light having a second peak wavelength longer than the first peak wavelength; and the third luminescent material emits light having a third peak wavelength longer than the second peak wavelength.

As a display device according to Aspect 21 of the disclosure, in Aspect 20, the device may further include: an anode electrode (e.g., the first electrode 21) and a cathode electrode (e.g., the second electrode 23), wherein one of the anode electrode and the cathode electrode may include a reflective electrode (e.g., the reflective electrode 21a), and the other may be a light-transmissive electrode; in each pixel, a plurality of function layers including the first light-emitting layer, the second light-emitting layer, the third light-emitting layer, and the separation layer (e.g., the hole injection layer 31, the hole transport layer 32, the blue fluorescent light-emitting layer 34B, the green fluorescent light-emitting layer 34G, the red light-emitting layer 34R, the separation layer 35, the blocking layer, the electron transport layer 36, and the electron injection layer 37) may be provided between the anode electrode and the cathode electrode; in the first subpixel, the light emitted from the first fluorescent luminescent material may be emitted through the light-transmissive electrode to the exterior, directly or having been reflected in multiple between the reflective electrode and the light-transmissive electrode in the first subpixel; in the second subpixel, the light emitted from the second fluorescent luminescent material may be emitted through the light-transmissive electrode to the exterior, directly or having been reflected in multiple between the reflective electrode and the light-transmissive electrode in the second subpixel; in the third subpixel, the light emitted from the second fluorescent luminescent material may be emitted through the light-transmissive electrode to the exterior, directly or having been reflected in multiple between the reflective electrode and the light-transmissive electrode in the third subpixel; and in the fourth subpixel, the light emitted from the third luminescent material may be emitted through the light-transmissive electrode to the exterior, directly or having been reflected in multiple between the reflective electrode and the light-transmissive electrode in the third subpixel.

The disclosure is not limited to the embodiments described above, and various modifications can be made within a scope not departing from the scope of the claims. Embodiments obtained by appropriately combining the technical approaches described in each of the different embodiments also fall within the technical scope of the disclosure. Moreover, novel technical features may be formed by combining the technical approaches disclosed in each of the embodiments.

### REFERENCE SIGNS LIST

1 Organic EL display device (display device)
1a Display region
2 Pixel
3, 3B, 3G1, 3G2, 3R Subpixel
4, 4B, 4G1, 4G2, 4R Light emitting region
10 TFT substrate (substrate)
11 Insulating substrate
12 TFT
13 Interlayer insulating film
13a Contact hole
14 Wiring line
15 Bank
15a Opening
20, 20B, 20G1, 20G2, 20R Organic EL element
21 First electrode (anode electrode)
21a Reflective electrode
21b Light-transmissive electrode
22 Organic EL layer
23 Second electrode (cathode electrode)
24 Protection layer
31 Hole injection layer (function layer)
32 Hole transport layer (function layer)
33 Light-emitting layer unit
34 Light-emitting layer (function layer)
34B Blue fluorescent light-emitting layer (function layer)
34G Green fluorescent light-emitting layer (function layer)
34R Red light-emitting layer (function layer)
35 Separation layer (function layer)
36 Electron transport layer (function layer)
37 Electron injection layer (function layer)
40 Sealing substrate
50 Mask unit
60 Vapor deposition source
61 Emission opening
80 Limiting plate unit
81 Limiting plate
82 Limiting plate opening
91 Vapor deposition particle
70B, 70R, 70G, 70 Vapor deposition mask
71B, 71R, 71G, 71 Opening (mask opening)
D_{BG}, D_{GR} Opposing surface distance

1: A manufacturing method for a display device, the display device comprising:
a substrate having a display region in which a plurality of pixels are arranged, each pixel including a first subpixel, a second subpixel, a third subpixel, and a fourth subpixel,
wherein the first subpixel and the second subpixel are arranged in an alternating manner in a first direction;
the third subpixel and the fourth subpixel are arranged in an alternating manner in the first direction;
a column constituted by the first subpixel and the second subpixel, and a column constituted by the third subpixel and the fourth subpixel, are arranged in an alternating manner in a second direction orthogonal to the first direction;
in the first subpixel, a first fluorescent luminescent material emits light, and the light emitted from the first fluorescent luminescent material is emitted to the exterior;
in the second subpixel and the third subpixel, a second fluorescent luminescent material emits light, and the light emitted from the second fluorescent luminescent material is emitted to the exterior;
in the fourth subpixel, a third luminescent material emits light, and the light emitted from the third luminescent material is emitted to the exterior;
the first fluorescent luminescent material emits light having a first peak wavelength;
the second fluorescent luminescent material emits light having a second peak wavelength longer than the first peak wavelength;
the third luminescent material emits light having a third peak wavelength longer than the second peak wavelength; and
an energy level of the second fluorescent luminescent material in a minimum excited singlet state is lower than an energy level of the first fluorescent luminescent material in a minimum excited singlet state and higher than an energy level of the third luminescent material in a minimum excited singlet state,
the method comprising:
a function layer formation step of forming a plurality of function layers constituted by vapor deposition particles on the substrate by vapor-depositing vapor deposition particles corresponding to the respective function layers on the substrate through vapor deposition masks in which are formed a plurality of mask openings having predetermined opening patterns corresponding to the respective function layers,
wherein the function layer formation step includes:
a first light-emitting layer formation step of forming a first light-emitting layer containing the first fluorescent luminescent material in common for the first subpixel and the second subpixel;
a second light-emitting layer formation step of forming a second light-emitting layer containing the second fluorescent luminescent material in common for the second subpixel and the third subpixel;
a third light-emitting layer formation step of forming a third light-emitting layer containing the third luminescent material in common for the second subpixel and the fourth subpixel; and
a separation layer formation step of forming a separation layer in the second subpixel so that in the second subpixel, the separation layer, which inhibits Förster-type energy transfer, is layered between the third light-emitting layer and the light-emitting layer, of the first light-emitting layer and the second light-emitting layer, that is located closer to the third light-emitting layer, and
in the function layer formation step:
the first light-emitting layer and the second light-emitting layer are formed so that in the second subpixel, a distance between opposing surfaces of the first light-emitting layer and the second light-emitting layer is less than or equal to the Förster radius; and
in at least two light-emitting layer formation steps among the first light-emitting layer formation step, the second light-emitting layer formation step, and the third light-emitting layer formation step, the vapor deposition particles are linearly deposited on the substrate using, as the vapor deposition mask, a slitted mask including slit-shaped mask openings provided so that the mask openings span a plurality of the pixels.

2: The manufacturing method for a display device according to claim 1,
wherein the display device has a PenTile pixel arrangement in which the second subpixel and the fourth subpixel are adjacent, and the third subpixel and the first subpixel are adjacent, in the second direction, and the first subpixel and the fourth subpixel are adjacent, and the second subpixel and the third subpixel are adjacent, in a third direction intersecting with both the first direction and the second direction;
in the first light-emitting layer formation step, the first fluorescent luminescent material is linearly-deposited in a direction connecting the first subpixel and the second subpixel adjacent in the first direction;
in the second light-emitting layer formation step, the second fluorescent luminescent material is linearly-deposited in a direction connecting the second subpixel and the third subpixel adjacent in the third direction; and
in the third light-emitting layer formation step, the third luminescent material is linearly-deposited in a direction connecting the second subpixel and the fourth subpixel adjacent in the second direction.

3: The manufacturing method for a display device according to claim 2,
wherein in the at least two light-emitting layer formation steps,
using a mask unit, which includes a slitted mask having a smaller area than the substrate as the slitted mask and a vapor deposition source that emits the vapor deposition particle, and in which the relative positions of the vapor deposition mask and the vapor deposition source are fixed, the vapor deposition particles are linearly-deposited on the substrate through the slitted mask by moving at least one of the mask unit and the substrate relative to the other while scanning the substrate with the slitted mask and the substrate arranged opposing each other with a set gap provided therebetween; and
in a light-emitting layer formation step, of the first to third light-emitting layer formation steps, that is not the light-emitting layer formation step carried out first, the linear deposition is carried out after rotating at least one of the substrate and the slitted mask relative to the other within the same plane from the state in the previous light-emitting layer formation step.

4: The manufacturing method for a display device according to claim 3,
wherein the at least two light-emitting layer formation steps include the second light-emitting layer formation step;
the third direction is an oblique direction forming a 45-degree angle with one side or an axis of the substrate;
in the second light-emitting layer formation step, the substrate is arranged so that a longer direction of the mask openings in the slitted mask is a direction parallel to the oblique direction; and
at least one of the mask unit and the substrate is moved relative to the other in the direction parallel to the oblique direction.

5: The manufacturing method for a display device according to claim 1,
wherein the display device has an S-Stripe pixel arrangement in which the first subpixel and the fourth subpixel are adjacent, and the second subpixel and the third subpixel are adjacent, in the second direction;
in the first light-emitting layer formation step, the first fluorescent luminescent material is linearly-deposited in a direction connecting the first subpixel and the second subpixel adjacent in the first direction;
in the second light-emitting layer formation step, the second fluorescent luminescent material is linearly-deposited in a direction connecting the second subpixel and the third subpixel adjacent in the second direction; and
in the third light-emitting layer formation step, the third luminescent material is linearly-deposited in a direction connecting the second subpixel and the fourth subpixel adjacent in a third direction intersecting with both the first direction and the second direction.

6: The manufacturing method for a display device according to claim 5,
wherein in the at least two light-emitting layer formation steps,
using a mask unit, which includes a slitted mask having a smaller area than the substrate as the slitted mask and a vapor deposition source that emits the vapor deposition particle, and in which the relative positions of the vapor deposition mask and the vapor deposition source are fixed, the vapor deposition particles are linearly-deposited on the substrate through the slitted mask by moving at least one of the mask unit and the substrate relative to the other while scanning the substrate with the slitted mask and the substrate arranged opposing each other with a set gap provided therebetween; and
in a light-emitting layer formation step, of the first to third light-emitting layer formation steps, that is not the light-emitting layer formation step carried out first, the linear deposition is carried out after rotating at least one of the substrate and the slitted mask relative to the other within the same plane from the state in the previous light-emitting layer formation step.

7: The manufacturing method for a display device according to claim 6,
wherein the at least two light-emitting layer formation steps include the third light-emitting layer formation step;
the third direction is an oblique direction forming a 45-degree angle with one side or an axis of the substrate;
in the third light-emitting layer formation step, the substrate is arranged so that a longer direction of the mask openings in the slitted mask is a direction parallel to the oblique direction; and
at least one of the mask unit and the substrate is moved relative to the other in the direction parallel to the oblique direction.

8: The manufacturing method for a display device according to claim 1,
wherein in the separation layer formation step, the separation layer is formed in common for the second subpixel and the fourth subpixel using a vapor deposition mask having the same opening pattern as the vapor deposition mask used to form the third light-emitting layer.

9: The manufacturing method for a display device according to claim 8,
wherein the slitted mask is used as the vapor deposition mask in each of the first light-emitting layer formation step, the second light-emitting layer formation step, the third light-emitting layer formation step, and the separation layer formation step.

10: The manufacturing method for a display device according to claim 1, further comprising:
an anode electrode formation step of forming an anode electrode; and
a cathode electrode formation step of forming a cathode electrode,
wherein one of the anode electrode and the cathode electrode includes a reflective electrode, and the other includes a light-transmissive electrode.

11: The manufacturing method for a display device according to claim 10,
wherein the function layer formation step is carried out after the anode electrode formation step and before the cathode electrode formation step; and
in the function layer formation step, the third light-emitting layer formation step, the separation layer formation step, the second light-emitting layer formation step, and the first light-emitting layer formation step are carried out in that order, and a hole transporting material is used for at least one of the material contained in the first light-emitting layer having the highest combination ratio and the material contained in the second light-emitting layer having the highest combination ratio.

12: The manufacturing method for a display device according to claim 10,
wherein the function layer formation step is carried out after the anode electrode formation step and before the cathode electrode formation step; and
in the function layer formation step, the third light-emitting layer formation step, the separation layer formation step, the first light-emitting layer formation step, and the second light-emitting layer formation step are carried out in that order, and a hole transporting material is used for at least one of the material contained in the first light-emitting layer having the highest combination ratio and the material contained in the second light-emitting layer having the highest combination ratio.

13: The manufacturing method for a display device according to claim 10,
wherein the function layer formation step is carried out after the anode electrode formation step and before the cathode electrode formation step; and
in the function layer formation step, the first light-emitting layer formation step, the second light-emitting layer formation step, the separation layer formation step, and the third light-emitting layer formation step are carried out in that order, and an electron transporting material is used for at least one of the material contained in the first light-emitting layer having the highest combination ratio and the material contained in the second light-emitting layer having the highest combination ratio.

14: The manufacturing method for a display device according to claim 10,
wherein the function layer formation step is carried out after the anode electrode formation step and before the cathode electrode formation step; and
in the function layer formation step, the second light-emitting layer formation step, the first light-emitting layer formation step, the separation layer formation step, and the third light-emitting layer formation step are carried out in that order, and an electron transporting material is used for at least one of the material contained in the first light-emitting layer having the highest combination ratio and the material contained in the second light-emitting layer having the highest combination ratio.

15: The manufacturing method for a display device according to claim 1,
wherein in the separation layer formation step, the separation layer is formed so that the separation layer has a thickness exceeding the Förster radius.

16: A display device comprising:
a substrate having a display region in which a plurality of pixels are arranged, each pixel including a first subpixel, a second subpixel, a third subpixel, and a fourth subpixel,
wherein the first subpixel and the second subpixel are arranged in an alternating manner in a first direction;
the third subpixel and the fourth subpixel are arranged in an alternating manner in the first direction;
a column constituted by the first subpixel and the second subpixel, and a column constituted by the third subpixel and the fourth subpixel, are arranged in an alternating manner in a second direction orthogonal to the first direction;
a first light-emitting layer containing a first fluorescent luminescent material is provided in common for the first subpixel and the second subpixel;
a second light-emitting layer containing a second fluorescent luminescent material is provided in common for the second subpixel and the third subpixel;
a third light-emitting layer containing a third luminescent material is provided in common for the second subpixel and the fourth subpixel;
at least two light-emitting layers among the first light-emitting layer, the second light-emitting layer, and the third light-emitting layer include a light-emitting layer provided spanning a plurality of pixels;
an energy level of the second fluorescent luminescent material in a minimum excited singlet state is lower than an energy level of the first fluorescent luminescent material in a minimum excited singlet state and higher than an energy level of the third luminescent material in a minimum excited singlet state;
in the second subpixel, a distance between opposing surfaces of the first light-emitting layer and the second light-emitting layer is less than or equal to a Förster radius, and a separation layer that inhibits Förster-type energy transfer is layered between the third light-emitting layer and the light-emitting layer, of the first light-emitting layer and the second light-emitting layer, that is located closer to the third light-emitting layer;
in the first subpixel, the first fluorescent luminescent material emits light, and the light emitted from the first fluorescent luminescent material is emitted to the exterior;
in the second subpixel and the third subpixel, the second fluorescent luminescent material emits light, and the light emitted from the second fluorescent luminescent material is emitted to the exterior;
in the fourth subpixel, the third luminescent material emits light, and the light emitted from the third luminescent material is emitted to the exterior;
the first fluorescent luminescent material emits light having a first peak wavelength;
the second fluorescent luminescent material emits light having a second peak wavelength longer than the first peak wavelength; and
the third luminescent material emits light having a third peak wavelength longer than the second peak wavelength.
